(19) United States
(12) Patent Application Publication
(10) Pub. No.: US 2018/0011406 A1
(43) Pub. Date: Jan. 11, 2018

(54) PATTERN FORMING METHOD, RESIST PATTERN, METHOD FOR MANUFACTURING ELECTRONIC DEVICE, AND COMPOSITION FOR FORMING UPPER LAYER FILM

(71) Applicant: FUJIFILM Corporation, Tokyo (JP)

(72) Inventors: Naoya HATAKEYAMA, Haibara-gun (JP); Naoki INOUE, Haibara-gun (JP); Naohiro TANGO, Hiabara-gun (JP); Michihiro SHIRAKAWA, Hiabara-gun (JP); Akiyoshi GOTO, Haibara-gun (JP)

(73) Assignee: FUJIFILM Corporation, Tokyo (JP)

(21) Appl. No.: 15/708,963

(22) Filed: Sep. 19, 2017

Related U.S. Application Data
(63) Continuation of application No. PCT/JP2016/056876, filed on Mar. 4, 2016.

(30) Foreign Application Priority Data
Mar. 27, 2015 (JP) 2015-066731

(51) Int. Cl. G03F 7/11; C08F 220/18; G03F 7/20; G03F 7/16; C08F 220/28; G03F 7/004; C09D 133/14; C09D 133/10; C09D 133/06; G03F 7/32; G03F 7/038

(52) U.S. Cl. CPC G03F 7/11; G03F 7/325; C08F 220/18; G03F 7/2006; G03F 7/168; G03F 7/162; G03F 7/038; G03F 7/0046; G03F 7/0045; C09D 133/14; C09D 133/10; C09D 133/066; G03F 7/2041; C08F 220/28; C08F 2220/1858; C08F 2220/185; C08F 2220/1891; C08F 2220/283

(57) ABSTRACT

A pattern forming method includes: applying an actinic ray-sensitive or radiation- sensitive resin composition onto a substrate to form a resist film; forming an upper layer film on the resist film, using a composition for forming an upper layer film; exposing the resist film having the upper layer film formed thereon; and developing the exposed resist film using a developer including an organic solvent to form a pattern. The composition for forming an upper layer film contains a resin having a repeating unit (a) with a ClogP value of 2.85 or more and a compound (b) with a ClogP of 1.30 or less, and the receding contact angle of the upper layer film with water is 70 degrees or more, a resist pattern formed by the pattern forming method, and a method for manufacturing an electronic device, including the pattern forming method.

### CROSS REFERENCE TO RELATED APPLICATION(S)

This is a continuation of International Application No. PCT/JP2016/056876 filed on Mar. 4, 2016, and claims priority from Japanese Patent Application No. 2015-066731 filed on Mar. 27, 2015, the entire disclosures of which are incorporated herein by reference.

### BACKGROUND OF THE INVENTION

### 1. Field of the Invention

The present invention relates to a pattern forming method, a resist pattern formed by the pattern forming method, a method for manufacturing an electronic device, including the pattern forming method, and an electronic device manufactured by the method for manufacturing an electronic device.

More specifically, the present invention relates to a pattern forming method which is used for a process for manufacturing a semiconductor such as an IC, the manufacture of a circuit board for a liquid crystal, a thermal head, or the like, and other lithographic processes for photofabrication, a resist pattern formed by the pattern forming method, a method for manufacturing an electronic device, including the pattern forming method, and an electronic device manufactured by the method for manufacturing an electronic device.

### 2. Description of the Related Art

In processes for manufacturing semiconductor devices such as an IC in the related art, microfabrication by means of lithography using various resist compositions has been carried out.

For example, JP2013-061647A describes “a method for forming an electronic device, including (a) providing a semiconductor base including one or more layers on which a pattern is formed; (b) forming a photoresist layer on the one or more layers on which a pattern is formed; (c) coating a photoresist topcoat composition on the photoresist layer, in which the topcoat composition includes a basic quencher, a polymer, and an organic solvent; (d) exposing the layer with chemical rays; and (e) developing the exposed film with an organic solvent developer”.

In addition, with regard to microfabrication by means of lithography using a photoresist topcoat composition, JP2013-061648A describes a photoresist topcoat composition including a polymer containing a specific monomer as a polymerization unit, an organic solvent, and a basic quencher.

### SUMMARY OF THE INVENTION

However, in a current situation, there is a demand for further improvements in performance such as focus latitude (DOF: Depth Of Focus) and exposure latitude (EL).

The present invention has been made taking consideration of the above aspects, and thus, has an object to provide a pattern forming method capable of achieving high degrees of DOF, EL, and watermark defect performance simultaneously, a resist pattern, a method for manufacturing an electronic device, and a composition for forming an upper layer film.

The present invention has the following configuration, whereby the objects of the present invention can be achieved.

[1] A pattern forming method comprising: a step a of applying an actinic ray-sensitive or radiation-sensitive resin composition onto a substrate to form a resist film;

a step b of forming an upper layer film on the resist film, using a composition for forming an upper layer film;

a step c of exposing the resist film having the upper layer film formed thereon; and

a step d of developing the exposed resist film using a developer including an organic solvent to form a pattern,

in which the composition for forming an upper layer film contains a resin having a repeating unit (a) with a ClogP value of 2.85 or more and a compound (b) with a ClogP of 1.30 or less, and

the receding contact angle of the upper layer film with water is 70 degrees or more.

[2] The pattern forming method as described in [1], in which the resin contained in the composition for forming an upper layer film is a resin having a repeating unit containing an alicyclic hydrocarbon group.

[3] The pattern forming method as described in [1] or [2], in which the resin contained in the composition for forming an upper layer film is a resin having a repeating unit containing an acid-decomposable group.

[4] The pattern forming method as described in any one of [1] to [3], in which the resin contained in the composition for forming an upper layer film is a resin having a repeating unit containing a fluorine atom.

[5] The pattern forming method as described in any one of [1] to [4], in which the content of the compound (b) is 20% by mass or less with respect to the solid content of the composition for forming an upper layer film.

[6] The pattern forming method as described in any one of [1] to [5], in which the compound (b) is a compound having an ether bond.

[7] The pattern forming method as described in any one of [1] to [6], in which the compound (b) is at least one of a basic compound or a base generator.

[8] The pattern forming method as described in any one of [1] to [7], in which the compound (b) is an amine compound.

[9] A resist pattern formed by the pattern forming method as described in any one of [1] to [8].

[10] A method for manufacturing an electronic device, comprising the pattern forming method as described in any one of [1] to [8].

[11] A composition for forming an upper layer film, comprising:

a resin having a repeating unit (a) with a ClogP value of 2.85 or more; and

a compound (b) with a ClogP of 1.30 or less,

in which the receding contact angle of the upper layer film formed with the composition for forming an upper layer film with water is 70 degrees or more.

According to the present invention, it is possible to provide a pattern forming method capable of achieving high degrees of DOF, EL, and watermark defect performance simultaneously, a resist pattern, a method for manufacturing an electronic device, and a composition for forming an upper layer film.

### DESCRIPTION OF THE PREFERRED EMBODIMENTS

Hereinafter, aspects for carrying out the present invention will be described.

Furthermore, in citations for a group (atomic group) in the present specification, a description not referring to substitution or non-substitution includes both a group having no substituent and a group having a substituent. For example, an “alkyl group” includes not only an alkyl group having no substituent (an unsubstituted alkyl group) but also an alkyl group having a substituent (a substituted alkyl group).

“Actinic ray” or “radiation” in the present specification means, for example, a bright line spectrum of a mercury lamp, far ultraviolet rays represented by an excimer laser, extreme ultraviolet rays (EUV light), X-rays, electron beams, or the like. In addition, in the present invention, light means actinic rays or radiation. Furthermore, unless otherwise specified, “exposure” in the present specification includes not only exposure by a bright line spectrum of a mercury lamp, far ultraviolet rays represented by an excimer laser, X-rays, EUV light, or the like, but also writing by particle rays such as electron beams and ion beams.

In the present specification, the resin (X) in the composition for forming an upper layer film, and the weight-average molecular weight (Mw), the number-average molecular weight (Mn), and the dispersity (Mw/Mn) of the resin in the resist composition are each defined as a value in terms of polystyrene by GPC measurement (solvent: tetrahydrofuran, flow amount (amount of a sample to be injected): 10 μl , column: TSK gel Multipore HXL-M (×4) manufactured by TOSOH Corporation, column temperature: 40° C., flow rate: 1.0 mL/min, detector: differential refractive index (RI) detector), using a GPC device (HLC-8120GPC manufactured by TOSOH Corporation).

The pattern forming method of the present invention includes a step a of applying an actinic ray-sensitive or radiation-sensitive resin composition onto a substrate to form a resist film, a step b of forming an upper layer film on the resist film, using a composition for forming an upper layer film, a step c of exposing the resist film having the upper layer film formed thereon, and a step d of developing the exposed resist film using a developer including an organic solvent to form a pattern, in which the composition for forming an upper layer film contains a resin having a repeating unit (a) with a ClogP value of 2.85 or more and a compound (b) with a ClogP of 1.30 or less, and the receding contact angle of the upper layer film with water is 70 degrees or more.

Thus, it is possible to achieve high degrees of DOF, EL, and watermark defect performance simultaneously. The reasons therefor are presumed as follows.

According to the pattern forming method of the present invention, first, the composition for forming an upper layer film contains a compound (b) with a ClogP of 1.30 or less, that is, a compound having high hydrophilicity. Moreover, the upper layer film contains a compound having high hydrophilicity. Here, an acid trapping agent such as a basic compound typically contained in a resist film is intended to be easily withdrawn into the upper layer film by a suction force or the like due to the above-mentioned compound having high hydrophilicity in the upper layer film. Thus, it is thought that the exposed area of the resist film is in the state where the acid is likely to suitably diffuse, and thus, DOF is excellent.

Furthermore, elimination products generated by a reaction using the acid as a catalyst in the exposed area of the resist film (typically the acid-decomposition reaction of a resin) tend to stay in the vicinity of the interface between the exposed area and the unexposed area in the form of being repelled on the upper layer film (that is, tend to hardly volatilize from the resist film due to the presence of the upper layer film). Here, typical examples of the elimination products include a compound having an unsaturated double bond, such as an olefin compound, and such the compound having an unsaturated double bond reacts with an acid generated from the exposed area. As a result, a behavior as if the acid does not diffuse is shown in the vicinity of the interface between the exposed area and the unexposed area.

In the present invention, the composition for forming an upper layer film contains a resin having a repeating unit (a) with a ClogP value of 2.85 or more, that is, a resin having high hydrophobicity. Moreover, the upper layer film contains a resin having high hydrophobicity. Thus, the compound having an unsaturated double bond as the elimination product is configured such that it is more easily bounced by the upper layer film (that is, configured such that the compound is less likely to volatilize from the resist film due to the presence of the upper layer film in the present invention). As a result, it is thought that the behavior in the vicinity of the interface between the exposed area and the unexposed area is more reliably expressed, and thus, EL is excellent.

Furthermore, in the upper layer film in the present invention, the compound (b) easily moves to the bottom portion of the upper layer film due to a phase separation of the resin having the repeating unit (a) and the compound (b). As a result, a large amount of the compound (b) is present in the surface on which the upper layer film is in contact with the resist film, and the acid trapping agent typically contained in the resist film is configured to be further withdrawn into the upper layer film by a suction force or the like by the above-mentioned compound (b) in the upper layer film. As a result, it is thought that DOF is more excellent for the above- mentioned reasons.

In addition, it is thought that in the present invention, the receding contact angle of the upper layer film with water is 70 degrees or more. Thus, it is thought that the followability of the immersion liquid upon the liquid immersion exposure is high, and the watermark defect performance is excellent.

Hereinafter, the pattern forming method of the present invention will be first described, and then the actinic ray-sensitive or radiation-sensitive resin composition (hereinafter also referred to as “the resist composition of the present invention”), and the composition for forming an upper layer film (hereinafter also referred to as a “topcoat composition”), each of which is used in the pattern forming method of the present invention, will be described.

[Pattern Forming Method]

The pattern forming method of the present invention is a pattern forming method including:

a step a of applying an actinic ray-sensitive or radiation-sensitive resin composition onto a substrate to form a resist film,

a step b of forming an upper layer film on the resist film, using a composition for forming an upper layer film,

a step c of exposing the resist film having the upper layer film formed thereon, and

a step d of developing the exposed resist film using a developer including an organic solvent to form a pattern,

in which the composition for forming an upper layer film contains a resin having a repeating unit (a) with a ClogP value of 2.85 or more and a compound (b) with a ClogP of 1.30 or less, and

the receding contact angle of the upper layer film with water is 70 degrees or more.

<Step a>

In the step a, the resist composition of the present invention is coated on a substrate to form a resist film (actinic ray-sensitive or radiation-sensitive film). The coating method is not particularly limited, and a spin coating method, a spray method, a roll coating method, a dip method, or the like, known in the related art, can be used, with the spin coating method being preferable.

After coating the resist composition of the present invention, the substrate may be heated (prebaked), as necessary. Thus, a film in which insoluble residual solvents have been removed can be uniformly formed. The temperature for prebake is not particularly limited, but is preferably 50° C. to 160° C., and more preferably 60° C. to 140° C.

The substrate on which the resist film is formed is not particularly limited, and it is possible to use a substrate generally used in a process for manufacturing a semiconductor such as an IC, a process for manufacturing a circuit board for a liquid crystal, a thermal head, or the like, and other lithographic processes of photofabrication, and examples thereof include inorganic substrates such as silicon, SiO₂, and SiN, and coating type inorganic substrates such as SOG.

Prior to forming the resist film, an antireflection film may be applied onto the substrate in advance.

As the antireflection film, any type of an inorganic film type such as titanium, titanium dioxide, titanium nitride, chromium oxide, carbon, and amorphous silicon, and an organic film type formed of a light absorber and a polymer material can be used. In addition, as the organic antireflection film, the commercially available organic antireflection film such as DUV-30 series or DUV-40 series manufactured by Brewer Science, Inc., AR-2, AR-3, or AR-5 manufactured by Shipley Company, L.L.C., or ARC series such as ARC29A manufactured by Nissan Chemical Industries, Ltd. can also be used.

<Step b>

In the step b, a composition (topcoat composition) for forming an upper layer film is coated on the resist film formed in the step a, and then heated (prebaked (PB)), if necessary, to form an upper layer film (hereinafter also referred to as a “topcoat”) on the resist film. As a result, high degrees of DOF, EL, and watermark defect performance can be achieved simultaneously, as described above.

For the reason that the effects of the present invention are more excellent, the temperature for prebaking in the step b (hereinafter also referred to as a “PB temperature”) is preferably 85° C. or higher, more preferably 110° C. or higher, still more preferably 120° C. or higher, and particularly preferably higher than 120° C.

The upper limit value of the PB temperature is not particularly limited, but is, for example, 200° C. or lower, preferably 170° C. or lower, more preferably 160° C. or lower, and still more preferably 150° C. or lower.

In a case where the exposure of the step c which will be described later is liquid immersion exposure, the topcoat is arranged between the resist film and the immersion liquid, and the resist film functions as a layer which is not brought into direct contact with the immersion liquid. In this case, preferred characteristics required for the topcoat (topcoat composition) are coating suitability onto the resist film, radiation, transparency, particularly to light at 193 nm, and poor solubility in an immersion liquid (preferably water). Further, it is preferable that the topcoat is not mixed with the resist film, and can be uniformly applied onto the surface of the resist film.

Moreover, in order to uniformly apply the topcoat composition onto the surface of the resist film while not dissolving the resist film, it is preferable that the topcoat composition contains a solvent in which the resist film is not dissolved. It is more preferable that as the solvent in which the resist film is not dissolved, a solvent of components other than an organic developer which will be described later. A method for applying the topcoat composition is not particularly limited, and a spin coating method, a spray method, a roll coating method, a dip method, or the like known in the related art can be used.

From the viewpoint of transparency at 193 nm, it is preferable that the topcoat composition contains a resin not having aromatics. Specifically, examples of the resin include a resin having at least one of a fluorine atom or a silicon atom, which will be described later, and a resin having a repeating unit having a CH₃ partial structure in the side chain moiety, but is not particularly limited as long as it is dissolved in a solvent in which the resist film is not dissolved.

The film thickness of the topcoat is not particularly limited, but from the viewpoint of transparency to an exposure light source, the topcoat with a thickness of usually 5 nm to 300 nm, preferably 10 nm to 300 nm, more preferably 20 nm to 200 nm, and still more preferably 30 nm to 100 nm is formed.

After forming the topcoat, the substrate is heated, as necessary.

From the viewpoint of resolution, it is preferable that the refractive index of the topcoat is close to that of the resist film.

The topcoat is preferably insoluble in an immersion liquid, and more preferably insoluble in water.

From the viewpoint of the followability of the immersion liquid, the receding contact angle of the topcoat with water is 70 degrees or more as described above, and more preferably 80 to 100 degrees.

Here, the receding contact angle with water in the present specification refers to a receding contact angle at a temperature of 23° C. and a relative humidity of 45%.

The receding contact angle of the topcoat with water can be set within the range by appropriately adjusting the contents of the respective components with the total solid content of the composition for forming an upper layer film, in particular, the content of the resin having a repeating unit (a) with a ClogP value of 2.85 or more, the content of the compound (b) with a ClogP of 1.30 or less, or the like.

In the liquid immersion exposure, in a view that the immersion liquid needs to move on a wafer following the movement of an exposure head that is scanning the wafer at a high speed and forming an exposure pattern, the contact angle of the immersion liquid with respect to the resist film in a dynamic state is important, and in order to obtain better resist performance, the immersion liquid preferably has a receding contact angle in the above range.

In a case where the topcoat is peeled, an organic developer which will be described later may be used, and another release agent may also be used. As the release agent, a solvent hardly permeating the resist film is preferable. In a view that the peeling of the topcoat can be carried out simultaneously with the development of the resist film, the topcoat is preferably peelable with an organic developer. The organic developer used for peeling is not particularly limited as long as it makes it possible to dissolve and remove a less exposed area of the resist film. The organic developer can be selected from developers including a polar solvent such as a ketone-based solvent, an ester-based solvent, an alcohol-based solvent, an amide-based solvent, and an ether-based solvent, and a hydrocarbon-based solvent, which will be described later. A developer including a ketone-based solvent, an ester-based solvent, an alcohol-based solvent, or an ether-based solvent is preferable, a developer including an ester-based solvent is more preferable, and a developer including butyl acetate is still more preferable.

From the viewpoint of peeling with an organic developer, the dissolution rate of the topcoat in the organic developer is preferably 1 to 300 nm/sec, and more preferably 10 to 100 nm/sec.

Here, the dissolution rate of a topcoat in the organic developer refers to a film thickness decreasing rate in a case where the topcoat is exposed to a developer after film formation, and is a rate in a case where dipping in a butyl acetate solution at 23° C. in the present invention.

An effect of reducing development defects after developing a resist film is accomplished by setting the dissolution rate of a topcoat in the organic developer to 1 nm/sec or more, and preferably 10 nm/sec or more. Further, an effect that the line edge roughness of a pattern after the development of the resist film is improved is accomplished by the influence of reduction in the exposure unevenness during liquid immersion exposure by setting the dissolution rate to 300 nm/sec or less, and preferably 100 nm/sec or less.

The topcoat may also be removed using other known developers, for example, an aqueous alkali solution. Specific examples of the usable aqueous alkali solution include an aqueous tetramethylammonium hydroxide solution.

A step of applying a pre-wetting solvent on the resist film may be included between the step a and the step b. Thus, the coatability of the topcoat composition is improved, and thus, saving liquefaction can be achieved.

The pre-wetting solvent is not particularly limited as long as it has a small solubility for the resist film, but a pre-wetting solvent for a topcoat, containing at least one compound selected from an alcohol-based solvent, a fluorine-based solvent, an ether-based solvent, a hydrocarbon-based solvent, or an ester-based solvent can be used.

From the viewpoint of coatability, the alcohol-based solvent is preferably a monohydric alcohol, and more preferably a monohydric alcohol having 4 to 8 carbon atoms. As the monohydric alcohol having 4 to 8 carbon atoms, a linear, branched, or cyclic alcohol may be used, but a linear or branched alcohol is preferable. As such an alcohol-based solvent, for example, alcohols such as 1-butanol, 2-butanol, 3-methyl-1-butanol, 4-methyl-1-pentanol, 4-methyl-2-pentanol, isobutyl alcohol, tert-butyl alcohol, 1-pentanol, 2-pentanol, 1-hexanol, 1-heptanol, 1-octanol, 2-hexanol, 2-heptanol, 2-octanol, 3-hexanol, 3-heptanol, 3-octanol, and 4-octanol; glycols such as ethylene glycol, propylene glycol, diethylene glycol, and triethylene glycol; glycol ethers such as ethylene glycol monomethyl ether, propylene glycol monomethyl ether, diethylene glycol monomethyl ether, triethylene glycol monoethyl ether, and methoxymethylbutanol; or the like can be used. Among those, alcohol and glycol ether are preferable, and 1-butanol, 1-hexanol, 1-pentanol, 3-methyl-1-butanol, 4-methyl-1-pentanol, 4-methyl-2-pentanol, and propylene glycol monomethyl ether are more preferable.

Examples of the ether-based solvent include dipropyl ether, diisopropyl ether, butylmethyl ether, butylethyl ether, butylpropyl ether, dibutyl ether, diisobutyl ether, tert-butylmethyl ether, tert-butylethyl ether, tert-butylpropyl ether, di-tert-butyl ether, dipentyl ether, diisoamyl ether, cyclopentylmethyl ether, cyclohexylmethyl ether, cyclopentylethyl ether, cyclohexylethyl ether, cyclopentylpropyl ether, cyclopentyl-2-propyl ether, cyclohexylpropyl ether, cyclohexyl-2-propyl ether, cyclopentylbutyl ether, cyclopentyl-tert-butyl ether, cyclohexylbutyl ether, and cyclohexyl-tert-butyl ether.

Examples of the fluorine-based solvent include 2,2,3,3,4,4-hexafluoro-l-butanol, 2,2,3,3,4,4,5,5-octafluoro-1-pentanol, 2,2,3,3,4,4,5,5,6,6-decafluoro-1-hexanol, 2,2,3,3,4,4-hexafluoro-1,5-pentanediol, 2,2,3,3,4,4,5,5-octafluoro-1,6-hexanediol, 2,2,3,3,4,4,5,5,6,6,7,7-dodecafluoro-1,8-octanediol, 2-fluoroanisole, 2,3-difluoroanisole, perfluorohexane, perfluoroheptane, perfluoro-2-pentanone, perfluoro-2-butyltetrahydrofuran, perfluorotetrahydrofuran, perfluorotributylamine, and perfluorotetrapentylamine. Among these, a fluorinated alcohol and a fluorinated hydrocarbon-based solvent can be suitably used.

Examples of the hydrocarbon-based solvent include aromatic hydrocarbon-based solvents such as toluene, xylene, and anisole; and aliphatic hydrocarbon-based solvents such as n-heptane, n-nonane, n-octane, n-decane, 2-methylheptane, 3-methylheptane, 3,3-dimethylhexane, and 2,3,4-trimethylpentane.

Examples of the ester-based solvent include methyl acetate, ethyl acetate, isopropyl acetate, butyl acetate (n-butyl acetate), pentyl acetate, hexyl acetate, isoamyl acetate, butyl propionate (n-butyl propionate), butyl butyrate, isobutyl butyrate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, methyl folinate, ethyl formate, butyl formate, propyl formate, ethyl lactate, butyl lactate, propyl lactate, methyl 2-hydroxyisobutyrate, isobutyl isobutyrate, and butyl propionate.

These solvents are used singly or as a mixture of a plurality thereof. By mixing a solvent other than the above-mentioned solvents, the solubility in the resist film, the solubility of the resin in the topcoat composition, the elution characteristics from the resist film, or the like can be appropriately adjusted.

<Step c>

The exposure in the step c can be carried out by a generally known method, and for example, a resist film having a topcoat formed thereon is irradiated with actinic rays or radiation through a predetermined mask. Here, the resist film is preferably irradiated with actinic rays or radiation through an immersion liquid, but are not limited thereto. The exposure dose can be appropriately set, but is usually 1 to 100 ml/cm².

The wavelength of the light source used in the exposure device in the present invention is not particularly limited, but light at a wavelength of 250 nm or less is preferably used, and examples of include KrF excimer laser light (248 nm), ArF excimer laser light (193 nm), F₂ excimer laser light (157 nm), EUV light (13.5 nm), and electron beams. Among these, ArF excimer laser light (193 nm) is preferably used.

in a case of carrying out liquid immersion exposure, before the exposure and/or after the exposure, the surface of the film may be washed with a water-based chemical before carrying out the heating which will be described later.

The immersion liquid is preferably a liquid which is transparent to exposure wavelength and has a minimum temperature coefficient of a refractive index so as to minimize the distortion of an optical image projected on the film. In particular, in a case where the exposure light source is an ArF excimer laser light (wavelength; 193 nm), water is preferably used in terms of easy availability and easy handling, in addition to the above-mentioned viewpoints.

In a case of using water, an additive (liquid) that decreases the surface tension of water while increasing the interfacial activity may be added at a slight proportion. It is preferable that this additive does not dissolve the resist film on a substrate, and has a negligible effect on the optical coat at the undersurface of a lens element. Water to be used is preferably distilled water. Further, pure water which has been subjected to filtration through an ion exchange filter or the like may also be used. Thus, it is possible to suppress the distortion of an optical image projected on the resist film by the incorporation of impurities.

Furthermore, in a view of further improving the refractive index, a medium having a refractive index of 1.5 or more can also be used. This medium may be an aqueous solution or an organic solvent.

The pattern forming method of the present invention may also have the step c (exposing step) carried out plural times. In the case, exposure to be carried out plural times may use the same light source or different light sources, but for the first exposure, ArF excimer laser light (wavelength; 193 nm) is preferably used.

After the exposure, it is preferable to perform heating (also referred to as baking or PEB) and development (preferably further rinsing). Thus, a good pattern can be obtained. The temperature for PEB is not particularly limited as long as a good resist pattern is obtained, and is usually 40° C. to 160° C. PEB may be carried out once or plural times.

<Step d>

In the step d, a resist pattern (typically a negative type resist pattern) is formed by carrying out development using a developer including an organic solvent. The step d is preferably a step of removing soluble areas of the resist film simultaneously.

Examples of the developer containing an organic solvent (hereinafter also referred to as an organic developer), which is used in the step d, include developers containing a polar solvent such as a ketone-based solvent, an ester-based solvent, an alcohol-based solvent, an amide-based solvent, and an ether-based solvent, and a hydrocarbon-based solvent.

Examples of the ketone-based solvent include 1-octanone, 2-octanone, 1-nonanone, 2-nonanone, acetone, 2-heptanone, 4-heptanone, 1-hexanone, 2-hexanone, diisobutyl ketone, cyclohexanone, methylcyclohexanone, phenylacetone, methyl ethyl ketone, methyl isobutyl ketone, acetylacetone, acetonylacetone, ionone, diacetonyl alcohol, acetyl carbinol, acetophenone, methyl naphthyl ketone, isophorone, and propylene carbonate.

Examples of the ester-based solvent include methyl acetate, ethyl acetate, isopropyl acetate, butyl acetate (n-butyl acetate), pentyl acetate, hexyl acetate, isoamyl acetate, butyl propionate (n-butyl propionate), butyl butyrate, isobutyl butyrate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, methyl formate, ethyl formate, butyl formate, propyl formate, ethyl lactate, butyl lactate, propyl lactate, and methyl 2-hydroxyisobutyrate.

Examples of the alcohol-based solvent include alcohols such as methyl alcohol, ethyl alcohol, n-propyl alcohol, isopropyl alcohol, n-butyl alcohol, sec-butyl alcohol, tert-butyl alcohol, isobutyl alcohol, n-hexyl alcohol, n-heptyl alcohol, n-octyl alcohol, and n-decanol; glycol-based solvents such as ethylene glycol, propylene glycol, diethylene glycol, and triethylene glycol; and glycol ether-based solvents such as ethylene glycol monomethyl ether, propylene glycol monomethyl ether, diethylene glycol monomethyl ether, triethylene glycol monoethyl ether, and methoxymethylbutanol.

Examples of the ether-based solvent include, in addition to the glycol ether-based solvents above, dioxane, and tetrahydrofuran.

Examples of the amide-based solvent which can be used include N-methyl-2-pyrrolidone, N,N-dimethylacetamide, N,N-dimethylformamide, hexamethylphosphoric triamide, and 1,3-dimethyl-2-imidazolidinone.

Examples of the hydrocarbon-based solvent include aromatic hydrocarbon-based solvents such as toluene and xylene, and aliphatic hydrocarbon-based solvents such as pentane, hexane, octane, and decane.

A plurality of these solvents may be mixed, or the solvent may be used by being mixed with a solvent other than those described above or with water. However, in order to sufficiently bring out the effects of the present invention, the moisture content in the entire developer is preferably less than 10% by mass, and it is more preferable that the developer contains substantially no water.

That is, the amount of the organic solvent to be used in the organic developer is preferably from 90% by mass to 100% by mass, and more preferably from 95% by mass to 100% by mass, with respect to the total amount of the developer.

Among these, as the organic developer, a developer containing at least one organic solvent selected from the group consisting of a ketone-based solvent, an ester-based solvent, an alcohol-based solvent, an amide-based solvent, and an ether-based solvent is preferable, a developer including a ketone-based solvent or an ester-based solvent is more preferable, and a developer including butyl acetate, butyl propionate, or 2-heptanone is still more preferable.

The vapor pressure of the organic developer is preferably 5 kPa or less, more preferably 3 kPa or less, and still more preferably 2 kPa or less, at 20° C. By setting the vapor pressure of the organic developer to 5 kPa or less, the evaporation of the developer on a substrate or in a development cup is suppressed, and the temperature evenness within a wafer plane is improved, whereby the dimensional evenness within a wafer plane is enhanced.

Specific examples of the solvent having a vapor pressure of 5 kPa or less (2 kPa or less) include the solvents described in paragraph [0165] of JP2014-71304A.

An appropriate amount of a surfactant may be added to the organic developer, as necessary.

The surfactant is not particularly limited, and for example, an ionic or nonionic, fluorine-based and/or silicon-based surfactant can be used. Examples of such a fluorine-based and/or silicon-based surfactant include surfactants described in JP1987-36663A (JP-S62-36663A), JP1986-226746A (JP-S61-226746A), JP1986-226745A (JP-S61-226745A), JP1987-170950A (JP-S62-170950A), JP1988-34540A (JP-S63-34540A), JP 1995-230165A (JP-H07-230165A), JP1996-62834A (JP-H08-62834A), JP1997-54432A (JP-H09-54432A), JP1997-5988A (JP-H09-5988A), and U.S. Pat. No.5,405,720A, U.S. Pat. No. 5,360,692A, U.S. Pat. No. 5,529,881A, U.S. Pat. No. 5,296,330A, U.S. Pat. No. 5,436,098A, U.S. Pat. No. 5,576,143A, U.S. Pat. No. 5,294,511A, and U.S. Pat. No. 5,824,451A, with the nonionic surfactant being preferable. The nonionic surfactant is not particularly limited, but the fluorine-based surfactant or the silicon-based surfactant is more preferably used.

The amount of the surfactant to be used is usually 0.001% to 5% by mass, preferably 0.005% to 2% by mass, and more preferably 0.01% to 0.5% by mass, with respect to the total amount of the developer.

The organic developer may also include a basic compound. Specific and preferred examples of the basic compound which can be included in the organic developer used in the present invention include those which will be described later as the basic compounds which can be included in the resist composition.

Examples of the developing method include a method in which a substrate is immersed in a tank filled with a developer for a certain period of time (a dip method), a method in which a developer is heaped up to the surface of a substrate by surface tension and developed by stopping for a certain period of time (a paddle method), a method in which a developer is sprayed on the surface of a substrate (a spray method), and a method in which a developer is continuously discharged on a substrate spun at a constant rate while scanning a developer discharging nozzle at a constant rate (a dynamic dispense method).

In addition, after the step of carrying out development using a developer including an organic solvent, a step of stopping the development while replacing the solvent with another solvent may also be included.

A washing step using a rinsing liquid may be included after the step of carrying out development using a developer including an organic solvent.

The rinsing liquid is not particularly limited as long as it does not dissolve the resist pattern, and a solution including a general organic solvent can be used. As the rinsing liquid, for example, a rinsing liquid containing at least one organic solvent selected from a hydrocarbon-based solvent, a ketone-based solvent, an ester-based solvent, an alcohol-based solvent, an amide-based solvent, and an ether-based solvent, described above as the organic solvent included in the organic developer is preferably used. More preferably, a step of carrying out washing using a rinsing liquid containing at least one organic solvent selected from a hydrocarbon-based solvent, a ketone-based solvent, an ester-based solvent, an alcohol-based solvent, and an amide-based solvent is carried out. Still more preferably, a step of carrying out washing using a rinsing liquid containing a hydrocarbon-based solvent, an alcohol-based solvent, or an ester-based solvent is carried out. Particularly preferably, a step of carrying out washing using a rinsing liquid containing a monohydric alcohol is carried out.

Here, examples of the monohydric alcohol used in the rinsing step include linear, branched, or cyclic monohydric alcohols, and specifically, 1-butanol, 2-butanol, 3-methyl-1-butanol, 3-methyl-2-butanol, tert-butyl alcohol, 1-pentanol, 2-pentanol, 3-methyl-2-pentanol, 4-methyl-2-pentanol, 1-hexanol, 2-hexanol, 3-hexanol, 4-methyl-2-hexanol, 5-methyl-2-hexanol, 1-heptanol, 2-heptanol, 3-heptanol, 4-methyl-2-heptanol, 5-methyl-2-heptanol, 1-octanol, 2-octanol, 3-octanol, 4-octanol, 4-methyl-2-octanol, 5-methyl-2-octanol, 6-methyl-2-octanol, 2-nonanol, 4-methyl-2-nonanol, 5-methyl-2-nonanol, 6-methyl-2-nonanol, 7-methyl-2-nonanol, 2-decanol, or the like can be used, with 1-hexanol, 2-hexanol, 1-pentanol, 3-methyl-1-butanol, or 4-methyl-2-heptanol being preferable.

Furthermore, examples of the hydrocarbon-based solvent used in the rinsing step include aromatic hydrocarbon-based solvents such as toluene and xylene; and aliphatic hydrocarbon-based solvents such as pentane, hexane, octane, and decane (n-decane).

In a case where an ester-based solvent is used as the rinsing liquid, a glycol ether-based solvent may be used, in addition to the ester-based solvent (one kind, or two or more kinds). As a specific example thereof in this case, an ester-based solvent (preferably butyl acetate) may be used as a main component, and a glycol ether-based solvent (preferably propylene glycol monomethyl ether (PGME)) may be used as a side component. Thus, residue defects are suppressed.

The respective components in plural numbers may be mixed, or the components may be mixed with an organic solvent other than the above solvents, and used.

The moisture content of the rinsing liquid is preferably 10% by mass or less, more preferably 5% by mass or less, and particularly preferably 3% by mass or less. By setting the moisture content to 10% by mass or less, good development characteristics can be obtained.

The vapor pressure of the rinsing liquid is preferably 0.05 to 5 kPa, more preferably 0.1 to 5 kPa, and still more preferably 0.12 to 3 kPa, at 20° C. By setting the vapor pressure of the rinsing liquid to a range from 0.05 to 5 kPa, the temperature evenness within a wafer plane is improved, and further, the dimensional evenness within a wafer plane is enhanced by inhibition of swelling due to the permeation of the rinsing liquid.

The rinsing liquid can also be used after adding an appropriate amount of a surfactant thereto.

In the rinsing step, the wafer which has been subjected to development using a developer including an organic solvent is subjected to a washing treatment using the rinsing liquid including the organic solvent. A method for the washing treatment is not particularly limited, and for example, a method in which a rinsing liquid is continuously discharged on a substrate rotated at a constant rate (a spin coating method), a method in which a substrate is immersed in a tank filled with a rinsing liquid for a certain period of time (a dip method), a method in which a rinsing liquid is sprayed onto a substrate surface (a spray method), or the like, can be applied. Among these, a method in which a washing treatment is carried out using the spin coating method, and a substrate is rotated at a rotation speed of 2,000 rpm to 4,000 rpm after washing, and then the rinsing liquid is removed from the substrate, is preferable. Further, it is preferable that a heating step (post-baking) is included after the rinsing step. The residual developer and the rinsing liquid between and inside the patterns are removed by the baking. The heating step after the rinsing step is carried out at typically 40° C. to 160° C., and preferably at 70° C. to 95° C., and typically for 10 seconds to 3 minutes, and preferably for 30 seconds to 90 seconds.

Moreover, in the pattern forming method of the present invention, development using an alkali developer may also be carried out after the development using an organic developer. A portion having weak exposure intensity is removed by development using an organic solvent, and a portion having strong exposure intensity is also removed by carrying out development using an alkali developer. Since pattern formation is carried out without dissolving only a region having intermediate exposure intensity by a multiple development process in which such development is carried out plural times in this manner, a finer pattern than usual can be formed (the same mechanism as that in paragraph [0077] of JP2008-292975A).

As the alkali developer, for example, alkali aqueous solutions of inorganic alkali such as sodium hydroxide, potassium hydroxide, sodium carbonate, sodium silicate, sodium metasilicate, and aqueous ammonia, primary amines such as ethylamine and n-propylamine, secondary amines such as diethylamine and di-n-butylamine, tertiary amines such as triethylamine and methyldiethylamine, alcoholamines such as dimethyl ethanolamine and triethanolamine, quaternary ammonium salts such as tetramethylammonium hydroxide and tetraethylammonium hydroxide; and cyclic amines such as pyrrole and piperidine, or the like can be used. Among these, an aqueous tetraethylammonium hydroxide solution is preferably used.

Moreover, an appropriate amount of alcohols or a surfactant can also be added to the alkali developer and used.

The alkali concentration of the alkali developer is usually 0.01% to 20% by mass.

The pH of the alkali developer is usually 10.0 to 15.0.

The time for carrying out development using an alkali developer is usually 10 to 300 seconds.

The alkali concentration (and the pH) of the alkali developer and the developing time can be appropriately adjusted depending on the patterns formed.

Washing may be carried out using a rinsing liquid after the development using an alkali developer, and as the rinsing liquid, pure water is used, or an appropriate amount of a surfactant may be added thereto before the use.

Furthermore, after the developing treatment or the rinsing treatment, a treatment for removing the developer or rinsing liquid adhering on the pattern by a supercritical fluid may be carried out.

In addition, a heating treatment can be carried out in order to remove moisture content remaining in the pattern after the rinsing treatment or the treatment using a supercritical fluid.

A method for improving the surface roughness of the pattern may also be applied to the pattern formed by the method of the present invention. Examples of the method for improving the surface roughness of the pattern include a method for treating a resist pattern by plasma of a hydrogen-containing gas disclosed in WO2014/002808A1. In addition, known methods as described in JP2004-235468A, US2010/0020297A, JP2009-19969A, Proc. of SPIE Vol. 8328 83280N-1 “EUV Resist Curing Technique for LWR Reduction and Etch Selectivity Enhancement” can also be applied.

The pattern forming method of the present invention can also be used in formation of a guide pattern (see, for example, ACS Nano Vol. 4 No. 8 Pages 4815-4823) in Directed Self-Assembly (DSA).

Furthermore, the resist pattern formed by the method can be used as a core material (core) in the spacer process disclosed in, for example, JP1991-270227A (JP-H03-270227A) and JP2013-164509A.

[Actinic Ray-Sensitive or Radiation-Sensitive Resin Composition]

Next, the actinic ray-sensitive or radiation-sensitive resin composition (hereinafter also conveniently referred to as “the resist composition of the present invention”) used in the pattern forming method of the present invention will be described.

(A) Resin

The resist composition of the present invention typically contains a resin capable of decreasing the solubility in a developer including an organic solvent due to an increase in the polarity by the action of an acid.

The resin capable of decreasing the solubility in a developer including an organic solvent due to an increase in the polarity by the action of an acid (hereinafter also referred to as a “resin (A)”) is preferably a resin (hereinafter also referred to as an “acid-decomposable resin”) having a group (hereinafter also referred to as an “acid-decomposable group”) capable of decomposing by the action of an acid to generate a polar group at either the main chain or the side chain of the resin, or at both the main chain and the side chain.

Furthermore, the resin (A) is more preferably a resin having an alicyclic hydrocarbon structure which is monocyclic or polycyclic (hereinafter also referred to as an “alicyclic hydrocarbon-based acid-decomposable resin”). It is thought that the resin having an alicyclic hydrocarbon structure which is monocyclic or polycyclic has high hydrophobicity and has improved developability in a case of developing an area of the resist film having a weak light irradiation intensity by an organic developer.

The resist composition of the present invention, which contains the resin (A), can be suitably used in a case of irradiation with ArF excimer laser light.

Typical examples of the polar group included in the acid-decomposable group include acid groups, specifically a group having a phenolic hydroxyl group, a carboxylic acid group, a fluorinated alcohol group, a sulfonic acid group, a sulfonamido group, a sulfonylimido group, an (alkylsulfonyl)(alkylcarbonyl)methylene group, an (alkylsulfonyl)(alkylcarbonyl)imido group, a bis(alkylcarbonyl)methylene group, a bis(alkylcarbonyl)imido group, a bis(alkylsulfonyl)methylene group, a bis(alkylsulfonyl)imido group, a tris(alkylcarbonyl)methylene group, and a tris(alkylsulfonyl)methylene group.

Preferred examples of the polar group include a carboxylic acid group, a fluorinated alcohol group (preferably hexafluoroisopropanol), and a sulfonic acid group.

A preferred group capable of decomposing by an acid (acid-decomposable group) is a group obtained by substituting a hydrogen atom of these polar groups with a group that leaves with an acid.

Examples of the group (acid-leaving group) that leaves by an acid include—C(R₃₆)(R₃₇)(R₃₈), —C(R₃₆)(R₃₇)(OR₃₉), and —C(R₀₁)(R₀₂)(OR₃₉).

In the formulae, R₃₆ to R₃₉ each independently represent an alkyl group, a cycloalkyl group, an aryl group, an aralkyl group, or an alkenyl group. R₃₆ and R₃₇ may be bonded to each other to form a ring.

R₀₁ and R₀₂ each independently represent a hydrogen atom, an alkyl group, a cycloalkyl group, an aryl group, an aralkyl group, or an alkenyl group.

As the acid-decomposable group, a cumyl ester group, an enol ester group, an acetal ester group, a tertiary alkyl ester group, and the like are preferable, and a tertiary alkyl ester group is more preferable.

The resin (A) is preferably a resin containing at least one selected from the group consisting of repeating units having partial structures represented by General Formulae (pI) to (pV), and a repeating unit represented by General Formula (II-AB).

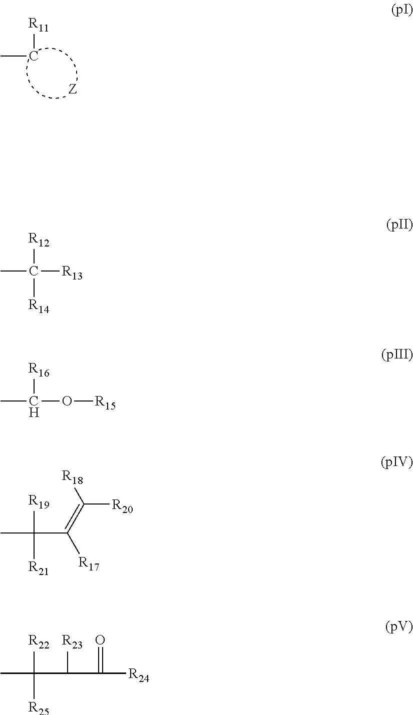

In General Formulae (pI) to (pV),

R₁₁ represents a methyl group, an ethyl group, an n-propyl group, an isopropyl group, an n-butyl group, an isobutyl group, or a sec-butyl group, and Z represents an atomic group which is necessary for forming a cycloalkyl group together with carbon atoms.

R₁₂ to R₁₆ each independently represent a linear or branched alkyl group or cycloalkyl group, having 1 to 4 carbon atoms, provided that at least one of R₁₂, . . . , or R₁₄, or any one of R₁₅ and R₁₆ is a cycloalkyl group.

R₁₇ to R₂₁ each independently represent a hydrogen atom, or a linear or branched alkyl group or cycloalkyl group, having 1 to 4 carbon atoms, provided that at least one of R₁₇, . . . , or R₂₁ is a cycloalkyl group. Further, any one of R₁₉ and R₂₁ is a linear or branched alkyl group or cycloalkyl group, having 1 to 4 carbon atoms.

R₂₂ to R₂₅ each independently represent a hydrogen atom, or a linear or branched alkyl group or cycloalkyl group, having 1 to 4 carbon atoms, provided that at least one of R₂₂, . . . , or R₂₅ is a cycloalkyl group. Further, R₂₃ and R₂₄ may be bonded to each other to form a ring.

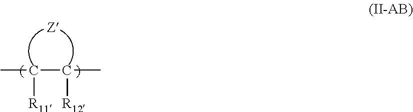

In General Formula (II-AB),

R₁₁′ and R₁₂′ each independently represent a hydrogen atom, a cyano group, a halogen atom, or an alkyl group.

Z′ represents an atomic group for forming an alicyclic structure, which contains two carbon atoms bonded to each other (C—C).

Furthermore, it is more preferable that General Formula (II-AB) is General Formula (II-AB1) or (II-AB2).

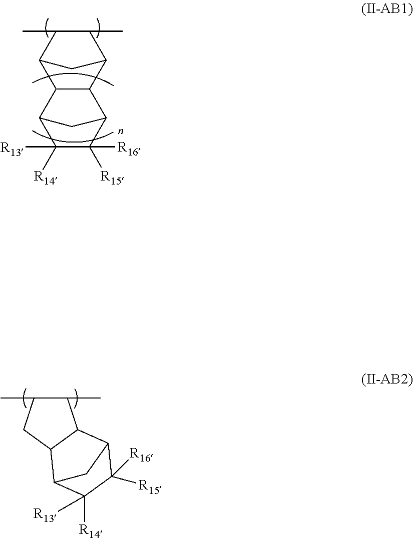

In Formulae (II-ABI) and (II-AB2),

R₁₃′ to R₁₆′ each independently represent a hydrogen atom, a halogen atom, a cyano group, —COOH, —COORS, a group capable of decomposing by the action of an acid, —C(═O)—X-A′-R₁₇′, an alkyl group, or a cycloalkyl group, provided that at least two of R₁₃′, . . . , or R₁₆′ may be bonded to each other to form a ring.

Here, R₅ represents an alkyl group, a cycloalkyl group, or a group having a lactone structure.

X represents an oxygen atom, a sulfur atom, —NH—, —NHSO₂—, or —NHSO₂NH—.

A′ represents a single bond or a divalent linking group.

R₁₇′ represents —COOH, —COOR₅, —CN, a hydroxyl group, an alkoxy group, —CO—NH—R₆, —CO—NH—SO₂—R₆, or a group having a lactone structure.

R₆ represents an alkyl group or a cycloalkyl group.

n represents 0 or 1.

In General Formulae (pI) to (pV), the alkyl group in each of R₁₁ to R₂₅ is a linear or branched alkyl group having 1 to 4 carbon atoms.

The cycloalkyl group in each of R₁₁ to R₂₅ or the cycloalkyl group formed by Z together with carbon atoms may be monocyclic or polycyclic. Specific examples thereof include a group having 5 or more carbon atoms and having a monocyclo, bicyclo, tricyclo, or tetracyclo structure. These cycloalkyl groups preferably have 6 to 30 carbon atoms, and particularly preferably 7 to 25 carbon atoms. These cycloalkyl groups may have a substituent.

Preferred examples of the cycloalkyl group include an adamantyl group, a noradamantyl group, a decalin residue, a tricyclodecanyl group, a tetracyclododecanyl group, a norbornyl group, cedrol group, a cyclopentyl group, a cyclohexyl group, a cycloheptyl group, a cyclooctyl group, a cyclodecanyl group, and a cyclododecanyl group. More preferred examples thereof include an adamantyl group, a norbornyl group, a cyclohexyl group, a cyclopentyl group, a tetracyclododecanyl group, and a tricyclodecanyl group.

Examples of a substituent which may further be included in these alkyl groups and cycloalkyl groups include an alkyl group (having 1 to 4 carbon atoms), a halogen atom, a hydroxyl group, an alkoxy group (having 1 to 4 carbon atoms), a carboxyl group, and an alkoxycarbonyl group (having 2 to 6 carbon atoms). Examples of the substituent which may further be included in the alkyl group, the alkoxy group, the alkoxycarbonyl group, or the like include a hydroxyl group, a halogen atom, and an alkoxy group.

The structures represented by General Formulae (pI) to (pV) in the resin can be used for the protection of the polar group. Examples of the polar group include various groups which are well-known in the technical field.

Specific examples of the structure include a structure in which a hydrogen atom in a carboxylic acid group, a sulfonic acid group, a phenol group, or a thiol group is substituted with a structure represented by any one of General Formulae (pI) to (pV), with a structure in which a hydrogen atom in a carboxylic acid group or a sulfonic acid group is substituted with a structure represented by any one of General Formulae (pI) to (pV) being preferable.

As the repeating unit having a polar group protected with the structure represented by any one of General Formulae (pI) to (pV), a repeating unit represented by General Formula (pA) is preferable.

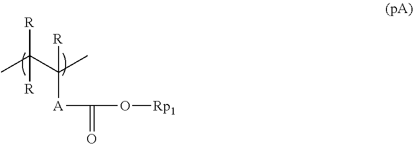

Here, R represents a hydrogen atom, a halogen atom, or a linear or branched alkyl group having 1 to 4 carbon atoms, and a plurality of R′s may be the same as or different from each other.

A is a single bond, or one group or a combination of two or more groups selected from the group consisting of an alkylene group, an ether group, a thioether group, a carbonyl group, an ester group, an amido group, a sulfonamido group, a urethane group, or a urea group, with a single bond being preferable.

Rₚ₁ is a group of any one of Formulae (pI) to (pV).

The repeating unit represented by General Formula (pA) is particularly preferably a repeating unit derived from 2-alkyl-2-adamantyl (meth)acrylate or dialkyl(1-adamantyl)methyl (meth)acrylate.

Specific examples of the repeating unit represented by General Formula (pA) are shown below, but the present invention is not limited thereto.

(in the formulae, Rx represents H, CH₃, or CH₂OH; and Rxa and Rxb each represent an alkyl croup having 1 to 4 carbon atoms)

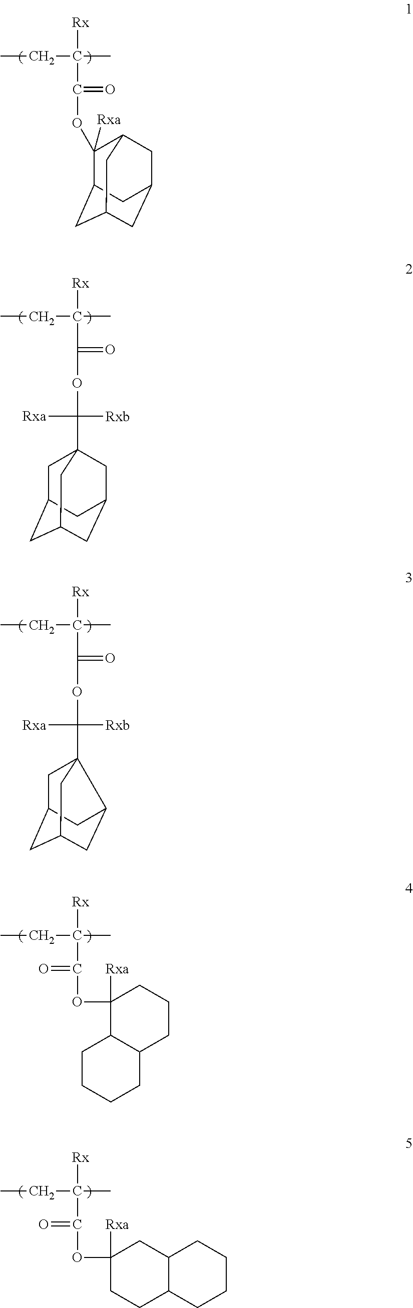

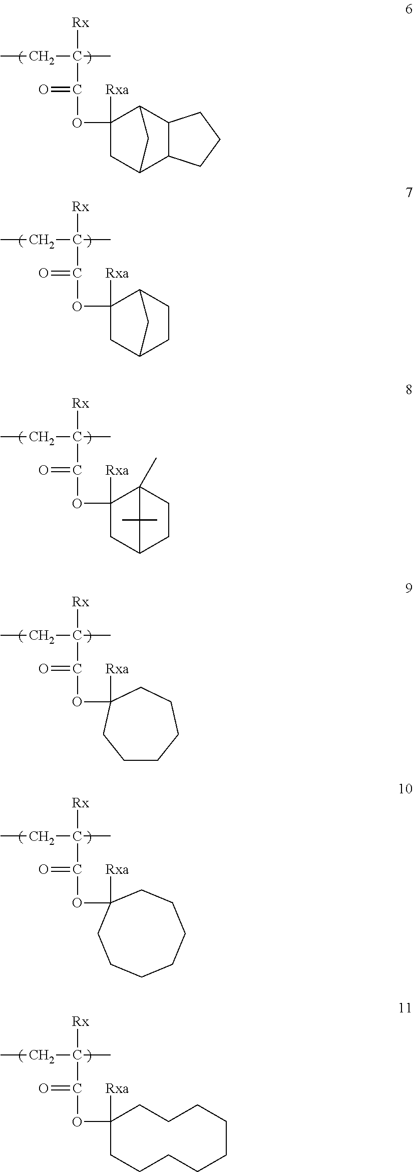

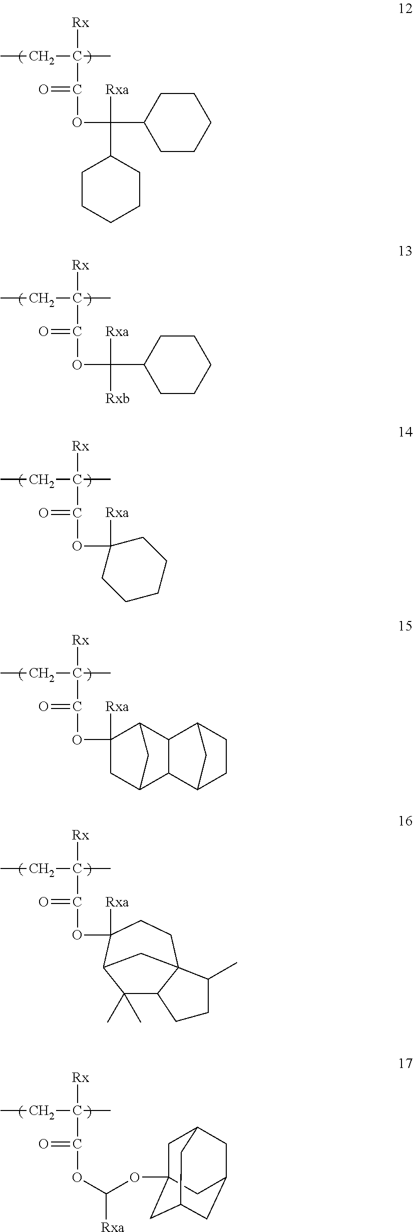

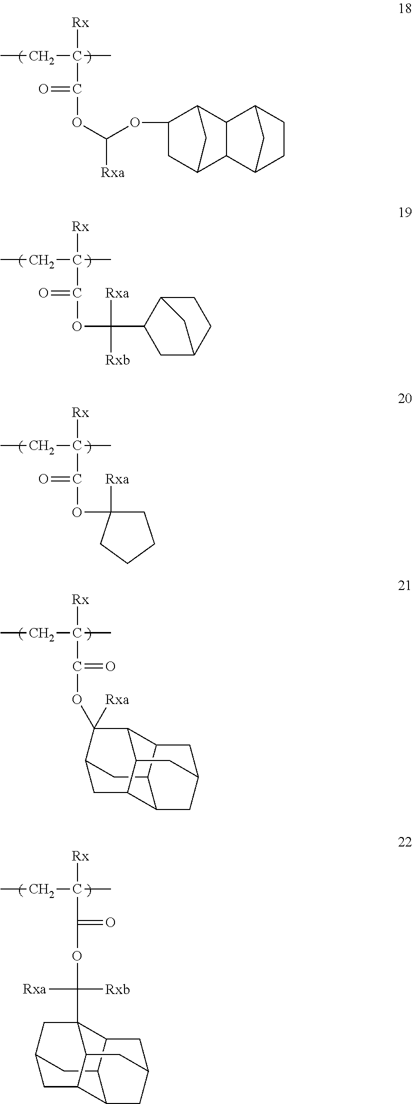

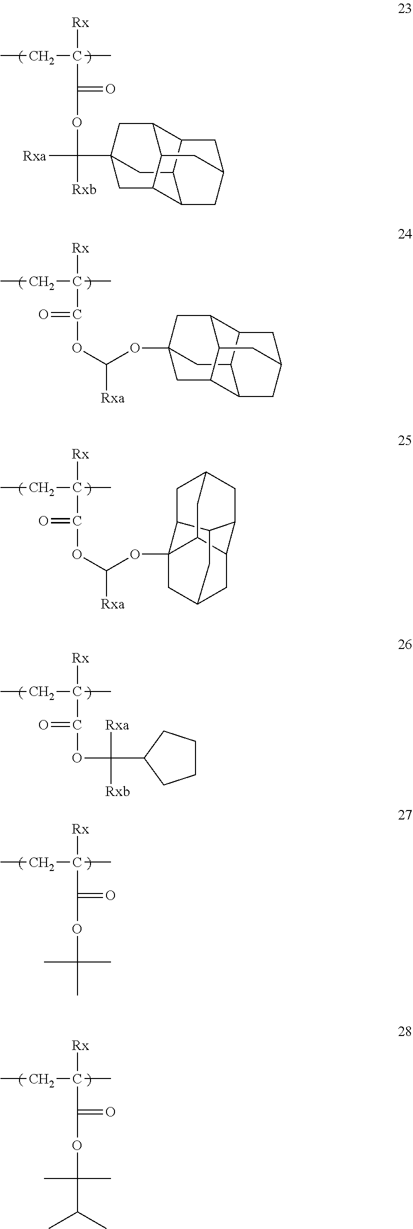

In General Formula (II-AB), examples of the halogen atoms in R₁₁′ and R₁₂′ include a chlorine atom, a bromine atom, a fluorine atom, and an iodine atom.

Examples of the alkyl group in each of R₁₁′ and R₁₂′ include a linear or branched alkyl group having 1 to 10 carbon atoms.

The atomic group for forming the alicyclic structure of Z′ is an atomic group that forms a repeating unit of an alicyclic hydrocarbon, which may have a substituent, in the resin. Above all, an atomic group for forming a crosslinked alicyclic structure that forms a crosslinked alicyclic hydrocarbon repeating unit is preferable.

Examples of the skeleton of the alicyclic hydrocarbon thus formed include the same ones as the alicyclic hydrocarbon groups represented by each of R₁₂ to R₂₅ in General Formulae (pI) to (pV).

The skeleton of the alicyclic hydrocarbon may have a substituent. Examples of the substituent include R₁₃′ to R₁₆′ in General Formula (II-AB1) or (II-AB2).

In the resin (A), the group capable of decomposing by the action of an acid is included in at least one repeating unit of a repeating unit having a partial structure represented by any one of General Formulae (pI) to (pV), a repeating unit represented by General Formula (II-AB), or a repeating unit of a copolymerizable component which will be described later. It is preferable that the group capable of decomposing by the action of an acid is included in a repeating unit having a partial structure represented by any one of General Formulae (pI) to (pV).

It is preferable that the resin (A) contains a lactone group. As the lactone group, any group having a lactone structure may be used, but the group is preferably a group containing a 5- to 7-membered ring lactone structure, and more preferably, a 5- to 7-membered ring lactone structure to which another ring structure is fused in the form of forming a bicyclo structure or a Spiro structure. The resin (A) still more preferably has a repeating unit having a group having a lactone structure represented by any one of General Formulae (LC1-1) to (LC1-16). Further, the group having a lactone structure may be bonded directly to the main chain. The lactone structures are preferably a group represented by any one of General Formulae (LC1-1), (LC1-4), (LC1-5), (LC1-6), (LC1-13), and (LC1-14). By using the specific lactone structures, line edge roughness is improved, and thus, development defects are relieved.

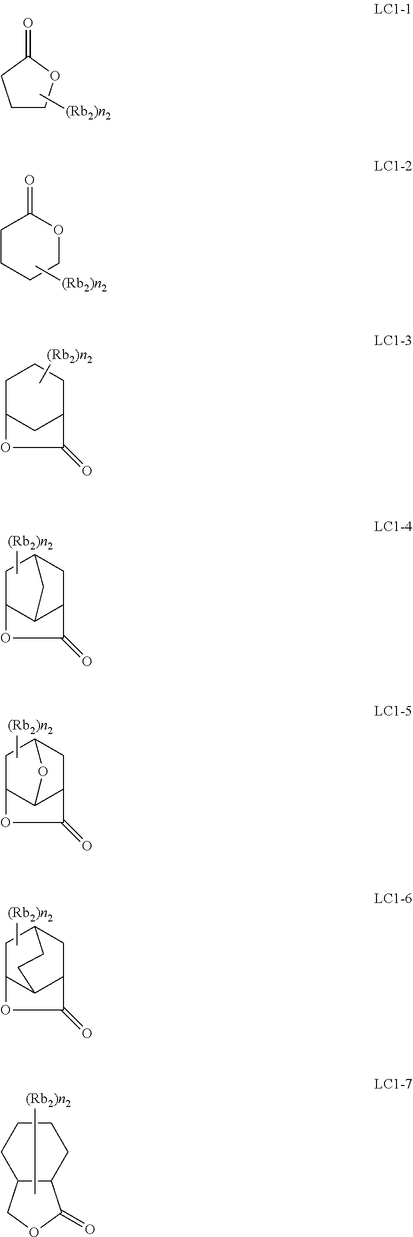

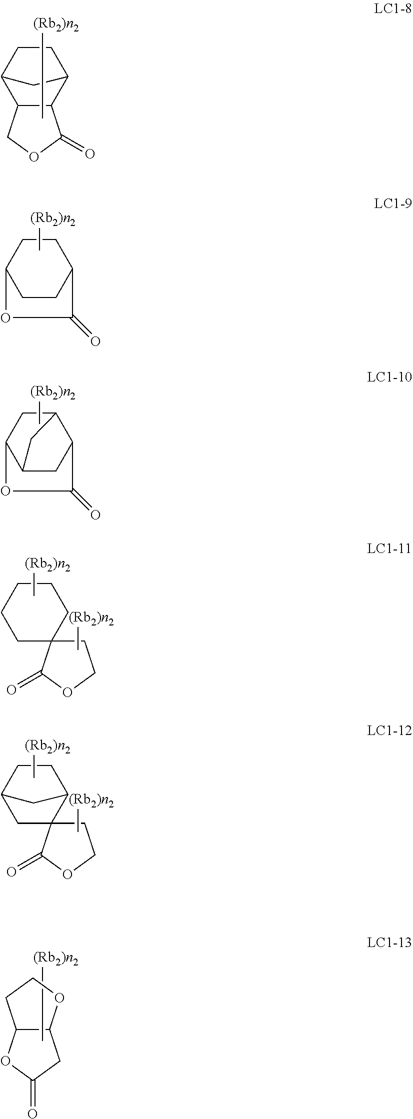

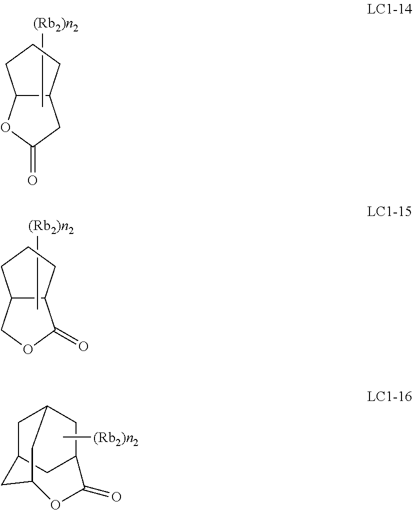

The lactone structure moiety may or may not have a substituent (Rb₂). Preferred examples of the substituent (Rb₂) include an alkyl group having 1 to 8 carbon atoms, a cycloalkyl group having 4 to 7 carbon atoms, an alkoxy group having 1 to 8 carbon atoms, an alkoxycarbonyl group having 1 to 8 carbon atoms, a carboxyl group, a halogen atom, a hydroxyl group, a cyano group, and an acid-decomposable group. nz represents an integer of 0 to 4. When n₂ is 2 or more, Rb₂'s which are present in plural numbers may be the same as or different from each other, and further, Rb₂'s which are present in plural numbers may be bonded to each other to form a ring.

Examples of the repeating unit having a group having a lactone structure, represented by any one of General Formulae (LC1-1) to (LC1-16), include those in which at least one of R₁₃′, . . . , or R₁₆′ in General Formula (II-AB1) or (II-AB2) has a group represented by any one of General Formulae (LC1-1) to (LC1-16) (for example, R₅ of —COOR₅ represents a group represented by any one of General Formulae (LC1-1) to (LC1-16)), or a repeating unit represented by General Formula (AI).

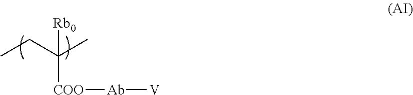

In General Formula (AI),

R_{b0} represents a hydrogen atom, a halogen atom, or an alkyl group having 1 to 4 carbon atoms.

Preferred examples of the substituent which the alkyl group of R_{b0} may have include a hydroxyl group and a halogen atom.

Examples of the halogen atom of R_{b0} include a fluorine atom, a chlorine atom, a bromine atom, and an iodine atom.

R_{b0} is preferably a hydrogen atom or a methyl group.

A_{b} represents a single bond, an alkylene group, a divalent linking group having a monocyclic or polycyclic alicyclic hydrocarbon structure, an ether group, an ester group, a carbonyl group, or a divalent group formed by combination thereof. A_{b} is preferably a single bond or a linking group represented by -Ab₁-CO₂—. Ab₁ is a linear or branched alkylene group or a monocyclic or polycyclic cycloalkylene group, and preferably a methylene group, an ethylene group, a cyclohexylene group, an adamantylene group, or a norbornylene group.

V represents a group represented by any one of General Formulae (LC₁-1) to (LC1-6).

The repeating unit having a lactone structure usually has an optical isomer, and any optical isomer may be used. Further, one kind of optical isomer may be used alone or a plurality of optical isomers may be mixed and used. In the case of mainly using one kind of optical isomer, the optical purity (ee) thereof is preferably 90 or more, and more preferably 95 or more.

Specific examples of the repeating unit having a group having a lactone structure are shown below, but the present invention is not limited thereto.

(in the formulae, Rx represents H, CH₃, CH₂OH, or CF₃)

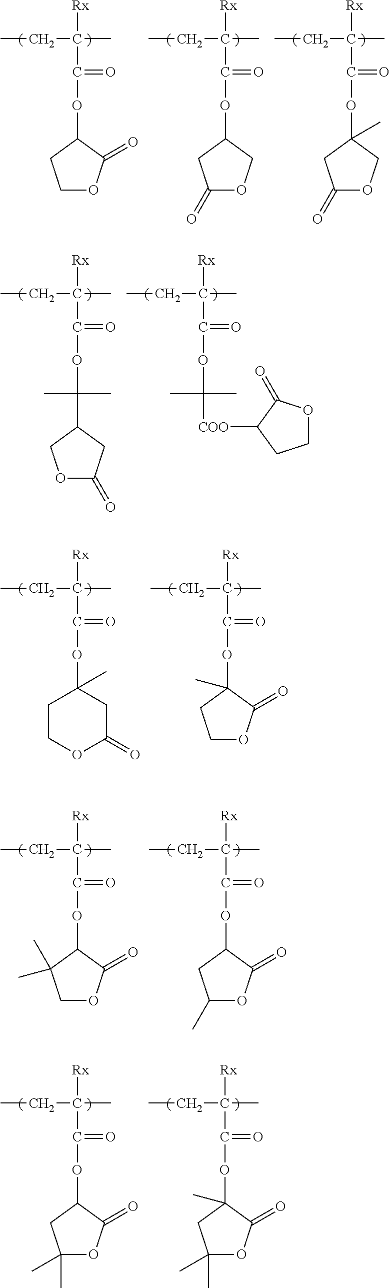

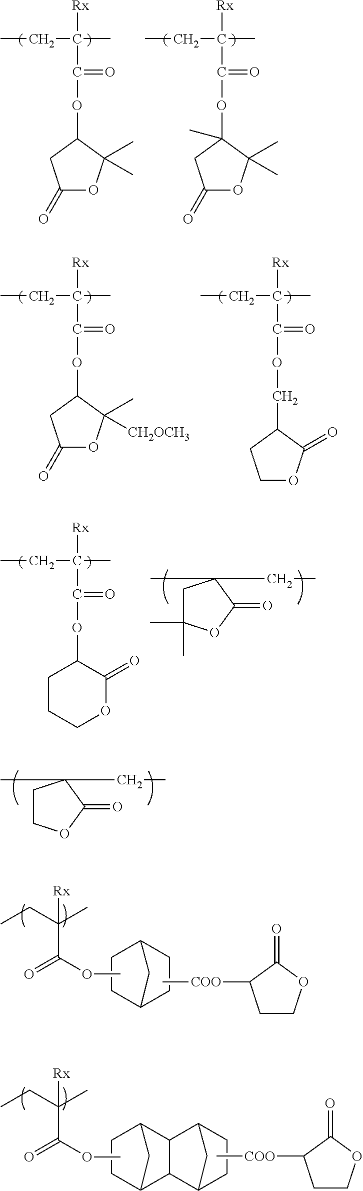

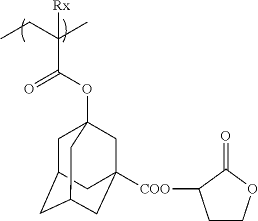

(in the formulae, Rx represents H, CH₃, CH₂OH, or CF₃)

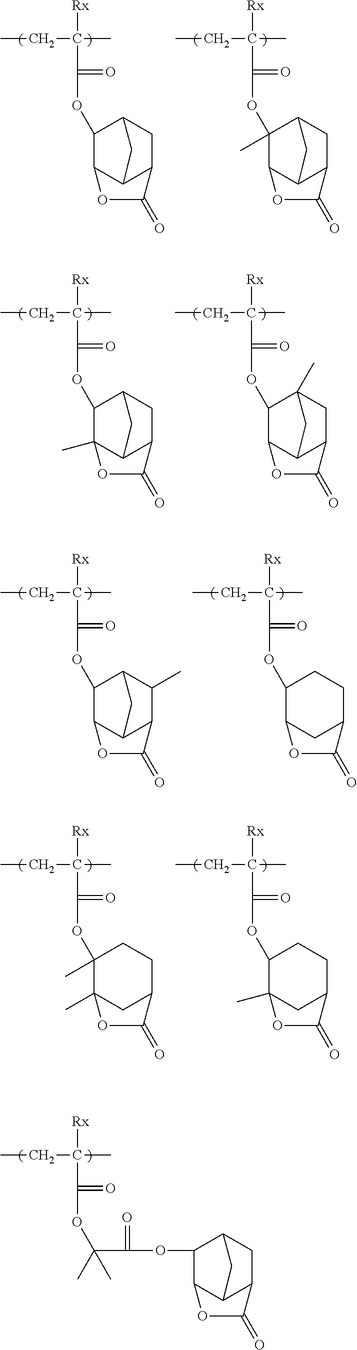

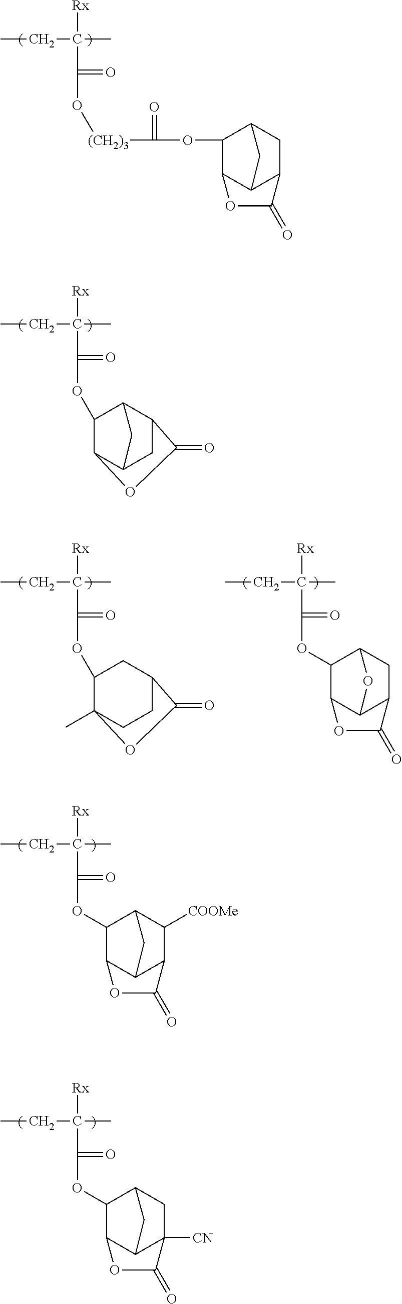

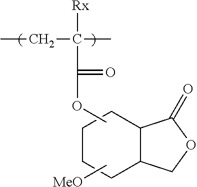

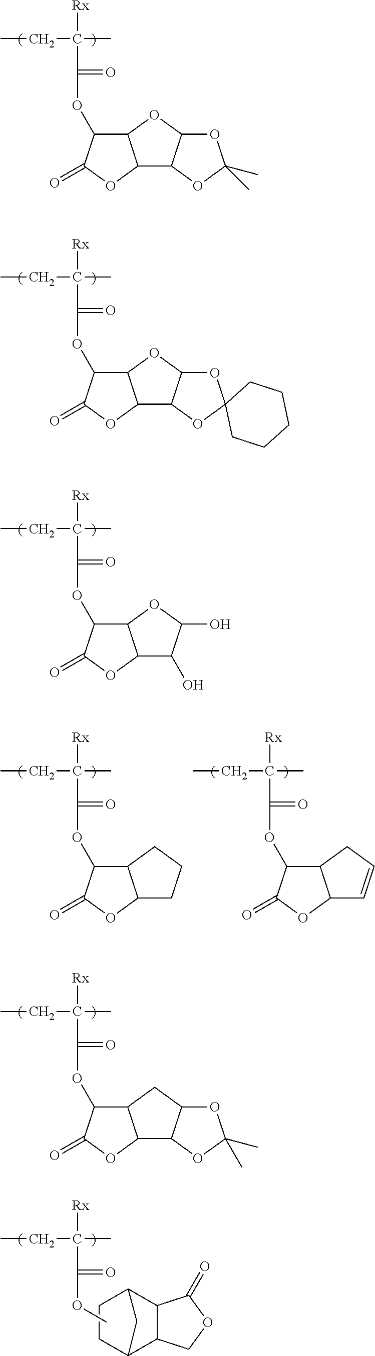

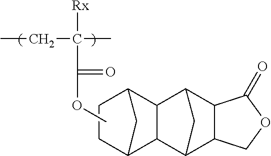

(in the formulae, Rx represents H, CH₃, CH₂OH, or CF₃)

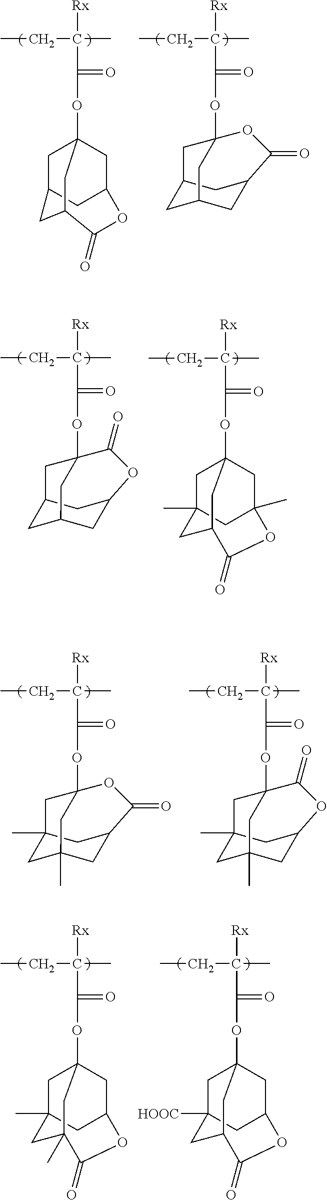

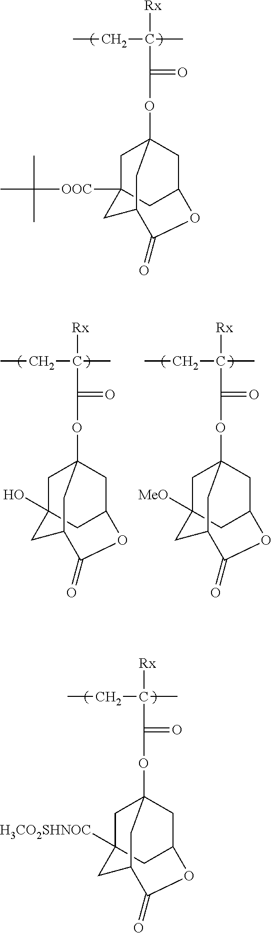

The resin (A) preferably has a repeating unit containing an organic group having a polar group, in particular, a repeating unit having an alicyclic hydrocarbon structure substituted with a polar group. Thus, the substrate adhesiveness and the developer affinity are improved. As the alicyclic hydrocarbon structure of the alicyclic hydrocarbon structure substituted with a polar group, an adamantyl group, a diamantyl group, or a norbornane group is preferable. As the polar group, a hydroxyl group or a cyano group is preferable.

As the alicyclic hydrocarbon structure substituted with a polar group, partial structures represented by General Formulae (VIIa) to (VIId) are preferable.

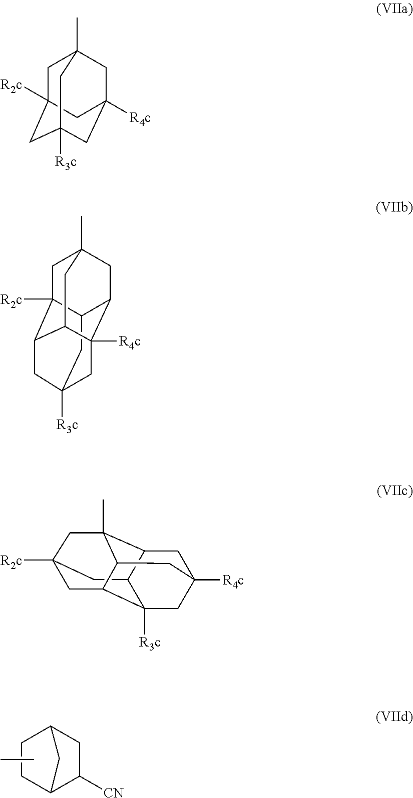

In General Formulae (VIIa) to (VIIc),

R_{2c} to R_{4c} each independently represent a hydrogen atom, a hydroxyl group, or a cyano group, provided that at least one of R_{2c}, . . . , or R_{4c} represents a hydroxyl group or a cyano group. It is preferable that one or two of R_{2c} to R_{4c} are hydroxyl group(s) and the remainders are hydrogen atoms.

In General Formula (VIIa), it is more preferable that two of R_{2c} to R_{4c} are hydroxyl groups and the remainders are hydrogen atoms.

Examples of the repeating unit having a group represented by General Formulae (VIIa) to (VIId) include those in which at least one of R₁₃′, . . . , or R₁₆′ in General Formula (II-AB1) or (II-AB2) has a group represented by General Formula (VII) (for example, R₅ of —COOR₅ represents a group represented by any one of General Formulae (VIIa) to (VIId)), and repeating units represented by General Formulae (AIIa) to (AIId).

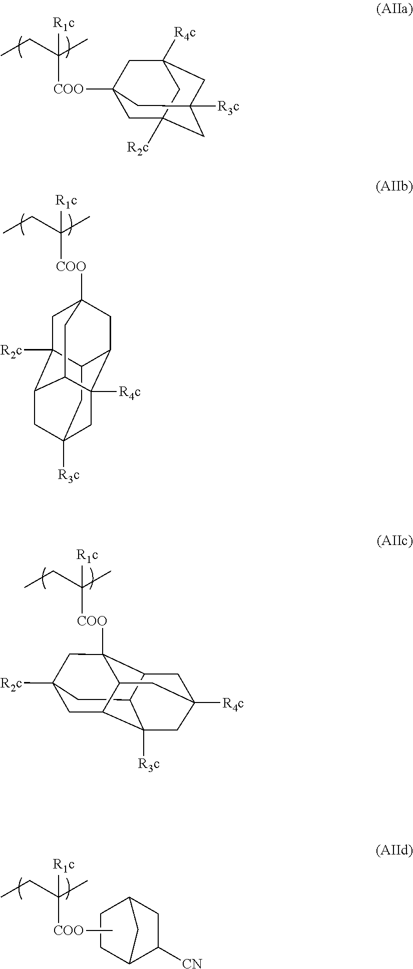

In General Formulae (AIIa) to (AIId),

R_{1c} represents a hydrogen atom, a methyl group, a trifluoromethyl group, or a hydroxymethyl group.

R_{2c} to R_{4c} have the same definitions as R_{2c} to R_{4c} in General Formulae (VIIa) to (VIIc).

Specific examples of the repeating unit having a structure represented by any one of General Formulae (AIIa) to (AIId) will be shown below, but the present invention is not limited thereto.

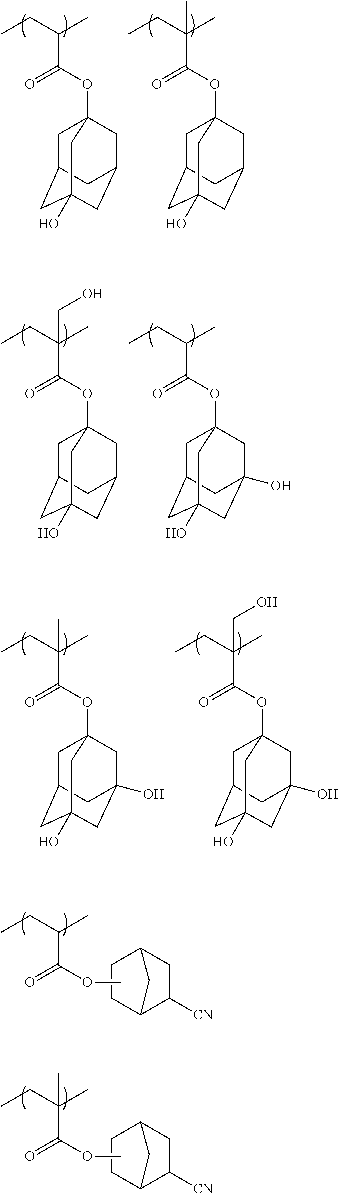

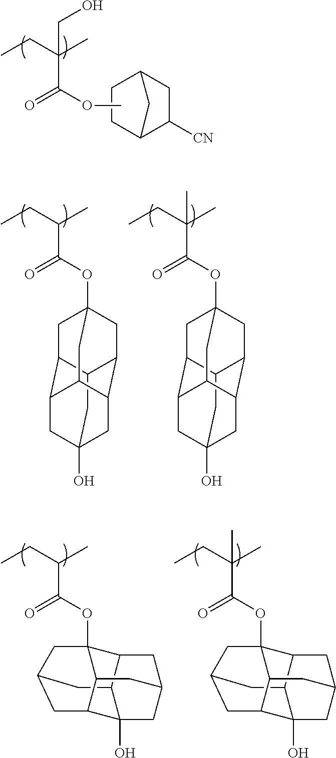

The resin (A) may also have a repeating unit further having an alicyclic hydrocarbon structure and not exhibiting acid-decomposability Thus, it is possible to reduce elution of the low molecular components from the resist film to the immersion liquid upon liquid immersion exposure. Examples of such a repeating unit include 1-adamantyl (meth)acrylate, tricyclodecanyl (meth)acrylate, and cyclohexyl (meth)acrylate.

In the resin (A), the molar ratio of the contents of the respective repeating units is appropriately set.

The content of the repeating unit containing an acid-decomposable group in the resin (A) is preferably 10% to 60% by mole, more preferably 20% to 50% by mole, and still more preferably 25% to 40% by mole, with respect to all the repeating units.

The content of the repeating unit having the partial structures represented by General Formulae (pI) to (pV) in the resin (A) is preferably 20% to 70% by mole, more preferably 20% to 50% by mole, and still more preferably 25% to 40% by mole, with respect to all the repeating units.

The content of the repeating unit represented by General Formula (II-AB) in the resin (A) is preferably 10% to 60% by mole, more preferably 15% to 55% by mole, and still more preferably 20% to 50% by mole, with respect to all the repeating units.

The content of the repeating unit having a lactone group in the resin (A) is preferably 10% to 70% by mole, more preferably 20% to 60% by mole, and still more preferably 25% to 40% by mole, with respect to all the repeating units.

The content of the repeating unit having an organic group with a polar group in the resin (A) is preferably 1% to 40% by mole, more preferably 5% to 30% by mole, and still more preferably 5% to 20% by mole, with respect to all the repeating units.

When the resist composition of the present invention is to be used for ArF exposure, from the viewpoint of the transparency to the ArF light, it is preferable that the resin (A) is free of an aromatic group.

As the resin (A), resins in which all of the repeating units are constituted with (meth)acrylate-based repeating units are preferable. In this case, any one of a resin in which all of the repeating units are methacrylate-based repeating units, a resin in which all of the repeating units are acrylate-based repeating units, and a resin in which all of the repeating units are mixtures of methacrylate-based repeating units acrylate-based repeating units can be used, and the proportion of the acrylate-based repeating units is preferably 50% by mole or less with respect to all the repeating units.

The weight-average molecular weight of the resin (A) is a value in terms of polystyrene, measured by means of a gel permeation chromatography (GPC) method, and is preferably 1,000 to 200,000, more preferably 1,000 to 20,000, and still more preferably 1,000 to 15,000. By setting the weight-average molecular weight to 1,000 to 200,000, the heat resistance and the dry etching resistance can be prevented from being deteriorated, and the film forming properties can be prevented from being deteriorated due to deteriorated developability or increased viscosity.

The dispersity (molecular weight distribution) which is in a range of usually 1 to 5, preferably 1 to 3, more preferably 1.2 to 3.0, and particularly preferably 1.2 to 2.0 is used. As the dispersity is smaller, the resolution and the resist shape are excellent, the side wall of the resist pattern is smooth, and the roughness is excellent.

The blend amount of the resin (A) in the entire resist composition of the present invention is preferably 50% to 99.9% by mass, and more preferably 60% to 99.0% by mass, with respect to the total solid content.

Incidentally, in the present invention, the resin (A) may be used singly or in combination of plural kinds thereof.

It is preferable that the resin (A), preferably the resist composition of the present invention, contains neither a fluorine atom nor a silicon atom from the viewpoint of the compatibility with a topcoat composition.

(B) Compound That Generates Acid upon Irradiation with Actinic Rays or Radiation

The resist composition of the present invention typically contains a compound that generates an acid upon irradiation with actinic rays or radiation (also referred to as a “photoacid generator” or a “compound (B)”). As the compound (B), a compound that generates an organic acid upon irradiation with actinic rays or radiation is preferable.

The compound (B) that generates an acid upon irradiation with actinic rays or radiation may be in a form of a low molecular compound or in a form introduced into a part of a polymer. Further, a combination of the form of a low molecular compound and the form introduced into a part of a polymer may also be used.

In a case where the compound (B) that generates an acid upon irradiation with actinic rays or radiation is in the form of a low molecular compound, the molecular weight is preferably 3,000 or less, more preferably 2,000 or less, and still more preferably 1,000 or less.

In a case where the compound (B) that generates an acid upon irradiation with actinic rays or radiation is in the form introduced into a part of a polymer, it may be introduced into a part of the above-mentioned acid-decomposable resin or into a resin other than the acid-decomposable resin.

In the present invention, it is preferable that the compound (B) that generates an acid upon irradiation with actinic rays or radiation is in the form of a low molecular compound.

As such a photoacid generator, a compound may be appropriately selected from known compounds that generate an acid upon irradiation with actinic rays or radiation, which are used in a photoinitiator for cationic photopolymerization, a photoinitiator for radical photopolymerization, a photodecoloring agent for coloring agents, a photodiscoloring agent, a microresist, or the like, and a mixture thereof, and used.

Examples of the compound include a diazonium salt, a phosphonium salt, a sulfonium salt, an iodonium salt, imidosulfonate, oxime sulfonate, diazodisulfone, disulfone, and o-nitrobenzyl sulfonate.

In addition, as a compound in which a group or compound that generates an acid upon irradiation with actinic rays or radiation is introduced into the main or side chain of the polymer, for example, the compounds described in U.S. Pat. No. 3,849,137A, GE3914407A, JP1988-26653A (JP-S63-26653A), JP1980-164824A (JP-S55-164824A), JP1987-69263A (JP-S62-69263A), JP1988-146038A (JP-S63-146038A), JP1988-163452A (JP-S63-163452A), JP1987-153853A (JP-S62-153853A), JP1988-146029A (JP-S63-146029A), and the like can be used.

In addition, the compounds that generate an acid by light described in U.S. Pat. No. 3,779,778A, EP126712B, and the like can also be used.

Examples of the preferred compounds that decompose upon irradiation with actinic rays or radiation to generate an acid include compounds represented by General Formulae (ZI), (ZII), and (ZIII).

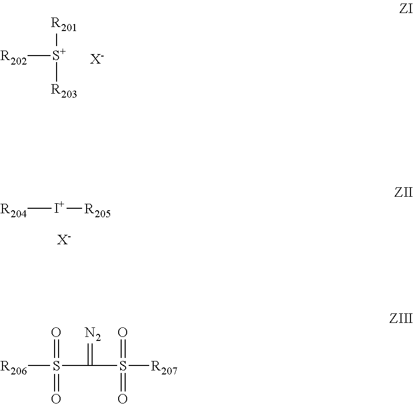

In General Formula (ZI), R₂₀₁, R₂₀₂, and R₂₀₃ each independently represent an organic group.

X⁻ represents a non-nucleophilic anion, and preferred examples thereof include a sulfonate anion, a carboxylate anion, a bis(alkylsulfonyl)amido anion, a tris(alkylsulfonyl)methide anion, BF₄⁻, PF₆⁻, and SbF₆⁻, with an organic anion containing a carbon atom being preferable.

Preferred examples of the organic anion include organic anions represented by the following formulae.

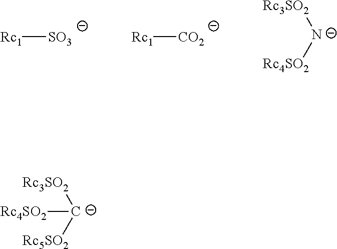

In the formulae,

Rc₁ represents an organic group.

Examples of the organic group in Rc₁ include those having 1 to 30 carbon atoms, and preferably an alkyl group which may be substituted, an aryl group, or a group formed by linking these plural groups through a linking group such as a single bond, —O—, —CO₂—, —S—, —SO₃— and —SO₂N(Rd₁)—. Rd₁ represents a hydrogen atom or an alkyl group.

Rc₃, Rc₄, and Rc₅ each independently represent an organic group. Preferred examples of the organic group in Rc3, Rc4, or Rc₅ include the same groups as the preferred organic groups in Rc₁, with a perfluoroalkyl group having 1 to 4 carbon atoms being most preferable.

Rc₃ and Rc₄ may be bonded to each other to form a ring. Examples of the group formed by the bonding of Rc₃ and Rc₄ include an alkylene group and an arylene group. A preferred example thereof is a perfluoroalkylene group having 2 to 4 carbon atoms.

The organic group of each of R₁, and Rc₃ to Rc₅ is particularly preferably an alkyl group having a fluorine atom or a fluoroalkyl group substituted at the 1-position, or a phenyl group substituted with a fluorine atom or a fluoroalkyl group. By having a fluorine atom or a fluoroalkyl group, the acidity of the avenerated acid generated upon irradiation with light increases, and thus, the sensitivity is improved. Further, by the bonding of Rc₃ and Rc₄ to form a ring, the acidity of the generated acid generated upon irradiation with light increases, and thus, the sensitivity is improved.

The number of carbon atoms of the organic group as each of R₂₀₁, R₂₀₂, and R₂₀₃ is generally 1 to 30, and preferably 1 to 20.

Furthermore, two members out of R₂₀₁ to R₂₀₃ may be bonded to each other to form a ring structure, and may include an oxygen atom, a sulfur atom, an ester bond, an amide bond, or a carbonyl group within the ring. Examples of the group formed by the bonding of two members out of R₂₀₁ to R²⁰³ include alkylene groups (for example, a butylene group and a pentylene group).

Moreover, the compound may be a compound having a plurality of structures represented by General Formula (ZI). For example, it may be a compound having a structure in which at least one of R₂₀₁, . . . , or R₂₀₃ in the compound represented by General Formula (ZI) is bonded to at least one of R₂₀₁, . . . , or R₂₀₃ of one compound represented by General Formula (ZI).

In General Formulae (ZII) and (ZIII),

R₂₀₄ to R₂₀₇ each independently represent an aryl group, an alkyl group, or a cycloalkyl group.

As the aryl group of each of R₂₀₄ to R₂₀₇, a phenyl group or a naphthyl group is preferable, and a phenyl group is more preferable.

The alkyl group as each of R₂₀₄ to R₂₀₇ may be linear or branched, and preferred examples thereof include linear or branched alkyl groups having 1 to 10 carbon atoms (for example, a methyl group, an ethyl group, a propyl group, a butyl group, and a pentyl group).

Examples of the cycloalkyl group as each of R₂₀₄ to R₂₀₇ include cycloalkyl groups having 3 to 10 carbon atoms (for example, a cyclopentyl group, a cyclohexyl group, and a norbornyl group).

R₂₀₄ to R₂₀₇ may have a substituent. Examples of the substituent that R₂₀₄ to R₂₀₇ may have include an alkyl group (for example, having 1 to 15 carbon atoms), a cycloalkyl group (for example, having 3 to 15 carbon atoms), an aryl group (for example, having 6 to 15 carbon atoms), an alkoxy group (for example, having 1 to 15 carbon atoms), a halogen atom, a hydroxyl group, and a phenylthio group.

X⁻ represents a non-nucleophilic anion, and examples thereof include the same ones as the non-nucleophilic anion of X⁻ in General Formula (ZI).

Preferred examples of the compound that generates an acid upon irradiation with actinic rays or radiation further include compounds represented by General Formulae (ZIV), (ZV), and (ZVI).

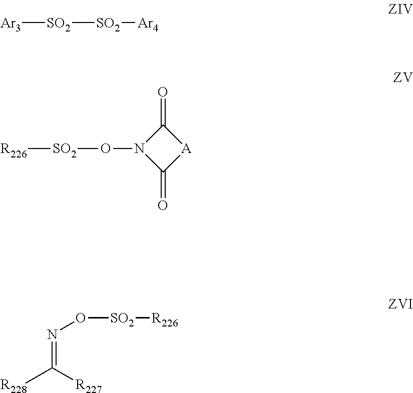

In General Formulae (ZIV) to (ZVI),

Ar₃ and Ar₄ each independently represent an aryl group.

R₂₂₆ represents an alkyl group or an aryl group.

R₂₂₇ and R₂₂₈ each independently represent an alkyl group, an aryl group or electron-withdrawing group. R₂₂₇ is preferably an aryl group.

R₂₂₈ is preferably an electron-withdrawing group, and more preferably a cyano group or a fluoroalkyl group.

A represents an alkylene group, an alkenylene group, or an arylene group.

As the compound that generates an acid upon irradiation with actinic rays or radiation, compounds represented by General Formulae (ZI) to (ZIII) are preferable.

The compound (B) is preferably a compound that generates aliphatic sulfonic acid having a fluorine atom or benzenesulfonic acid having a fluorine atom upon irradiation with actinic rays or radiation.

The compound (B) preferably has a triphenylsulfonium structure.

The compound (B) is preferably a triphenylsulfonium salt compound having an alkyl group or cycloalkyl group, having a cationic moiety not substituted with fluorine.

Specific examples of the compound that generates an acid upon irradiation with actinic rays or radiation include the compounds described in paragraphs [0194] to [0199] of JP2008-309878A, but the present invention is not limited thereto.

The photoacid generators may be used singly or in combination of two or more kinds thereof. When using two or more kinds of the photoacid generators, it is preferable to combine compounds that generate two different organic acids having a total number of atoms excluding hydrogen atoms of 2 or more.

The content of the photoacid generator is preferably 0.1% to 20% by mass, more preferably 0.5% to 17% by mass, and still more preferably 1% to 15% by mass, with respect to the total solid content of the resist composition.

(C) Solvent

Examples of the solvent which can be used in a case where the respective components are dissolved to prepare a resist composition include organic solvents such as alkylene glycol monoalkyl ether carboxylate, alkylene glycol monoalkyl ether, alkyl lactate ester, alkyl alkoxypropionate, a cyclic lactone having 4 to 10 carbon atoms, a monoketone compound having 4 to 10 carbon atoms, which may have a ring, alkylene carbonate, alkyl alkoxyacetate, and alkyl pyruvate.

Preferred examples of the alkylene glycol monoalkyl ether carboxylate include propylene glycol monomethyl ether acetate, propylene glycol monoethyl ether acetate, propylene glycol monopropyl ether acetate, propylene glycol monobutyl ether acetate, propylene glycol monomethyl ether propionate, propylene glycol monoethyl ether propionate, ethylene glycol monomethyl ether acetate, and ethylene glycol monoethyl ether acetate.

Preferred examples of the alkylene glycol monoalkyl ether include propylene glycol monomethyl ether, propylene glycol monoethyl ether, propylene glycol monopropyl ether, propylene glycol monobutyl ether, ethylene glycol monomethyl ether, and ethylene glycol monoethyl ether.

Preferred examples of the alkyl lactate ester include methyl lactate, ethyl lactate, propyl lactate, and butyl lactate.

Preferred examples of the alkyl alkoxypropionate include ethyl 3-ethoxypropionate, methyl 3-methoxypropionate, methyl 3-ethoxypropionate, and ethyl 3-methoxypropionate.

Preferred examples of the cyclic lactone having 4 to 10 carbon atoms include β-propiolactone, β-butyrolactone, γ-butyrolactone, α-methyl-γ-butyrolactone, β-methyl-γ-butyrolactone, γ-valerolactone, γ-caprolactone, γ-octanoic lactone, and α-hydroxy-γ-butyrolactone.

Preferred examples of the monoketone compound having 4 to 10 carbon atoms, which may contain a ring, include 2-butanone, 3-methylbutanone, pinacolone, 2-pentanone, 3-pentanone, 3-methyl-2-pentanone, 4-methyl-2-pentanone, 2-methyl-3-pentanone, 4,4-dimethyl-2-pentanone, 2,4-dimethyl-3-pentanone, 2,2,4,4-tetramethyl-3-pentanone, 2-hexanone, 3-hexanone, 5-methyl-3-hexanone, 2-heptanone, 3-heptanone, 4-heptanone, 2-methyl-3-heptanone, 5-methyl-3-heptanone, 2,6-dimethyl-4-heptanone, 2-octanone, 3-octanone, 2-nonanone, 3-nonanone, 5-nonanone, 2-decanone, 3-decanone, 4-decanone, 5-hexen-2-one, 3-penten-2-one, cyclopentanone, 2-methylcyclopentanone, 3-methylcyclopentanone, 2,2-dimethylcyclopentanone, 2,4,4-trimethylcyclopentanone, cyclohexanone, 3-methylcyclohexanone, 4-methylcyclohexanone, 4-ethylcyclohexanone, 2,2-dimethylcyclohexanone, 2,6-dimethylcyclohexanone, 2,2,6-trimethylcyclohexanone, cycloheptanone, 2-methylcycloheptanone, and 3-methylcycloheptanone.

Preferred examples of the alkylene carbonate include propylene carbonate, vinylene carbonate, ethylene carbonate, and butylene carbonate.

Preferred examples of the alkyl alkoxyracetate include 2-methoxyethyl acetate, 2-ethoxyethyl acetate, 2-(2-ethoxyethoxy)ethyl acetate, 3-methoxy-3-methylbutyl acetate, and 1-methoxy-2-propyl acetate.

Preferred examples of the alkyl pyruvate include methyl pyruvate, ethyl pyruvate, and propyl pyruvate.

Examples of the solvent that can be preferably used include solvents having a boiling point of 130° C. or higher under the conditions of noiinal temperature and normal pressure. Specific examples thereof include cyclopentanone, γ-butyrolactone, cyclohexanone, ethyl lactate, ethylene glycol monoethyl ether acetate, propylene glycol monomethyl ether acetate, ethyl 3-ethoxypropionate, ethyl pyruvate, 2-ethoxyethyl acetate, 2-(2-ethoxyethoxy)ethyl acetate, and propylene carbonate.

In the present invention, the solvents may be used singly or in combination of two or more kinds thereof.

In the present invention, a mixed solvent obtained by mixing a solvent containing a hydroxyl group in its structure with a solvent not containing a hydroxyl group in its structure may be used as the organic solvent.

Examples of the solvent containing a hydroxyl group include ethylene glycol, ethylene glycol monomethyl ether, ethylene glycol monoethyl ether, propylene glycol, propylene glycol monomethyl ether, propylene glycol monoethyl ether, and ethyl lactate, and among these, propylene glycol monomethyl ether and ethyl lactate are particularly preferable.

Examples of the solvent not containing a hydroxyl group include propylene glycol monomethyl ether acetate, ethylethoxypropionate, 2-heptanone, γ-butyrolactone, cyclohexanone, butyl acetate, N-methylpyrrolidone, N,N-dimethylacetamide, and dimethylsulfoxide, and among these, propylene glycol monomethyl ether acetate, ethylethoxypropionate, 2-heptanone, γ-butyrolactone, cyclohexanone, and butyl acetate are particularly preferable, and propylene glycol monomethyl ether acetate, ethylethoxypropionate, and 2-heptanone are most preferable.

The mixing ratio (mass ratio) of the solvent containing a hydroxyl group to the solvent not containing a hydroxyl group is 1/99 to 99/1, preferably 10/90 to 90/10, and more preferably 20/80 to 60/40. A mixed solvent including the solvent not containing a hydroxyl group in the amount of 50% by mass or more is particularly preferable from the viewpoint of coating evenness.

The solvent is preferably a mixed solvent of two or more kinds of solvents containing propylene glycol monomethyl ether acetate.

(D) Hydrophobic Resin

The resist composition of the present invention may contain a hydrophobic resin (D). As the hydrophobic resin, for example, a resin (X) which will be described later, which can be contained in a topcoat composition, can be suitably used. Further, other suitable examples of the hydrophobic resin include “[4] Hydrophobic Resin (D)” described in paragraphs [0389] to [0474] of JP2014-149409A.

The weight-average molecular weight of the hydrophobic resin (D) in terms of standard polystyrene is preferably 1,000 to 100,000, more preferably 1,000 to 50,000, and still more preferably 2,000 to 15,000.

Furthermore, the hydrophobic resin (D) may be used singly or in combination of plural kinds thereof.

The content of the hydrophobic resin (D) in the composition is preferably 0.01% to 10% by mass, more preferably 0.05% to 8% by mass, and still more preferably 0.1% to 7% by mass, with respect to the total solid content of the resist composition of the present invention.

(E) Basic Compound

The resist composition of the present invention preferably contains a basic compound (E) in order to reduce a change in performance over time from exposure to heating.

Preferred examples of the basic compound include compounds having structures represented by Formulae (A) to (E).

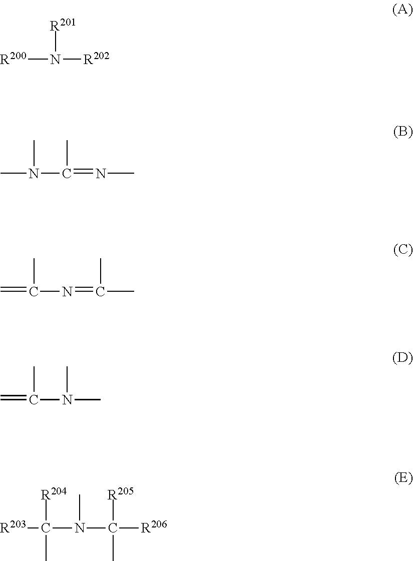

In General Formulae (A) to (E),

R²⁰⁰, R²⁰¹, and R²⁰² may be the same as or different from each other, represent a hydrogen atom, an alkyl group (preferably having 1 to 20 carbon atoms), a cycloalkyl group (preferably having 3 to 20 carbon atoms), or an aryl group (having 6 to 20 carbon atoms), in which R²⁰¹ and R²⁰² may be bonded to each other to form a ring.

With respect to the alkyl group, as the alkyl group having a substituent, an aminoalkyl group having 1 to 20 carbon atoms, a hydroxyalkyl group having 1 to 20 carbon atoms, or a cyanoalkyl group having 1 to 20 carbon atoms is preferable.

R²⁰³, R²⁰⁴, R²⁰⁵, and R²⁰⁶ may be the same as or different from each other, and each represent an alkyl group having 1 to 20 carbon atoms.

The alkyl group in General Formulae (A) to (E) is more preferably unsubstituted.

Preferred examples of the compound include guanidine, aminopyrrolidine, pyrazole, pyrazoline, piperazine, aminomorpholine, aminoalkylmorpholine and piperidine. More preferred examples of the compound include a compound having an imidazole structure, a diazabicyclo structure, an onium hydroxide structure, an onium carboxylate structure, a trialkylamine structure, an aniline structure or a pyridine structure; an alkylamine derivative having a hydroxyl group and/or an ether bond; and an aniline derivative having a hydroxyl group and/or an ether bond.

Examples of the compound having an imidazole structure include imidazole, 2,4,5-triphenylimidazole, and benzimidazole. Examples of the compound having a diazabicyclo structure include 1,4-diazabicyclo[2,2,2]octane, 1,5-diazabicyclo[4,3,0]non-5-ene, and 1,8-diazabicyclo[5,4,0]undec-7-ene. Examples of the compound having an onium hydroxide structure include triarylsulfonium hydroxide, phenacylsulfonium hydroxide, and sulfonium hydroxide having a 2-oxoalkyl group, specifically triphenylsulfonium hydroxide, tris(t-butylphenyl)sulfonium hydroxide, bis(t-butylphenyl)iodonium hydroxide, phenacylthiophenium hydroxide and 2-oxopropylthiophenium hydroxide. The compound having an onium carboxylate structure is fowled by carboxylation of an anionic moiety of a compound having an onium hydroxide structure, and examples thereof include acetate, adamantane-1-carboxylate, and perfluoroalkyl carboxylate. Examples of the compound having a trialkylamine structure include tri(n-butyl)amine and tri(n-octyl)amine. Examples of the compound having an aniline structure include 2,6-diisopropylaniline, N,N-dimethylaniline, N,N-dibutylaniline, and N,N-dihexylaniline. Examples of the alkylamine derivative having a hydroxyl group and/or an ether bond include ethanolamine, diethanolamine, triethanolamine, and tris(methoxyethoxyethyl)amine. Examples of the aniline derivative having a hydroxyl group and/or an ether bond include N,N-bis(hydroxyethyl)aniline.

Furthermore, as the basic compound, ones described as a basic compound, which may be contained in a composition (topcoat composition) for forming an upper layer film which will be described later can be suitably used.

These basic compounds may be used singly or in combination of two or more kinds thereof.

The amount of the basic compound to be used is usually 0.001% to 10% by mass, and preferably 0.01% to 5% by mass, with respect to the solid content of the resist composition of the present invention.

The ratio between the photoacid generator to the basic compound to be used in the resist composition is preferably the photoacid generator/basic compound (molar ratio)=2.5 to 300. That is, the molar ratio is preferably 2.5 or more in view of sensitivity and resolution, and is preferably 300 or less in view of suppressing the reduction in resolution due to thickening of the resist pattern with aging after exposure until the heat treatment. The photoacid generator/basic compound (molar ratio) is more preferably 5.0 to 200, and still more preferably 7.0 to 150.

(F) Surfactant

The resist composition of the present invention preferably further contains a surfactant (F), and more preferably contains either one or two or more of fluorine- and/or silicon-based surfactants (a fluorine-based surfactant, a silicon-based surfactant, or a surfactant containing both a fluorine atom and a silicon atom).

By incorporating the surfactant (F) into the resist composition of the present invention, it becomes possible to form a resist pattern having reduced adhesiveness and development defects with good sensitivity and resolution at the time of using an exposure light source of 250 nm or less, and particularly 220 nm or less.

Examples of the fluorine- and/or silicon-based surfactants include the surfactants described in JP1987-36663A (JP-S62-36663A), JP1986-226746A (JP-S61-226746A), JP1986-226745A (JP-S61-226745A), JP1987-170950A (JP-S62-170950A), JP1988-34540A (JP-S63-34540A), JP1995-230165A (JP-H07-230165A), JP1996-62834A (JP-H08-62834A), JP1997-54432A (JP-H09-54432A), JP1997-5988A (JP-H09-5988A), JP2002-277862A, U.S. Pat. No. 5,405,720A, U.S. Pat. No. 5,360,692A, U.S. Pat. No. 5,529,881A, U.S. Pat. No. 5,296,330A, U.S. Pat. No. 5,4360,98A, U.S. Pat. No. 5,576,143A, U.S. Pat. No. 5,294,511A, and U.S. Pat. No. 5,824,451A, and the following commercially available surfactants may be used as they are.

Examples of the commercially available surfactants that can be used include fluorine-based surfactants or silicon-based surfactants such as EFTOP EF301 and EF303 (manufactured by Shin-Akita Kasei K. K.); FLORAD FC430, 431, and 4430 (manufactured by Sumitomo 3M Inc.); MEGAFACE F171, F173, F176, F189, F113, F110, F177, F120, and R₀₈ (manufactured by DIC Corp.); SURFLON S-382, SC 101, 102, 103, 104, 105, and 106 (manufactured by Asahi Glass Co., Ltd.); TROYSOL S-366 (manufactured by Troy Chemical Industries); GF-300 and GF-150 (manufactured by Toagosei Chemical Industry Co., Ltd.); SURFLON S-393 (manufactured by Seimi Chemical Co., Ltd.); EFTOP EF121, EF122A, EF122B, RF122C, EF125M, EF135M, EF351, 352, EF801, EF802, and EF601 (manufactured by JEMCO Inc.); PF636, PF656, PF6320, and PF6520 (manufactured by OMNOVA Solutions Inc.); and FIX-204G, 208G, 218G, 230G, 204D, 208D, 212D, 218D, and 222D (manufactured by NEOS COMPANY LIMITED). In addition, Polysiloxane Polymer KP-341 (manufactured by Shin-Etsu Chemical Co., Ltd.) can also be used as the silicon-based surfactant.

Furthermore, in addition to those known surfactants as described above, a surfactant using a polymer having a fluoroaliphatic group derived from a fluoroaliphatic compound which is produced by a telomerization method (also referred to as a telomer method) or an oligomerization method (also referred to as an oligomer method), can be used as the surfactant. The fluoroaliphatic compound can be synthesized in accordance with the method described in JP2002-90991A.

As the polymer having a fluoroaliphatic group, copolymer of monomers having fluoroaliphatic groups and (poly(oxyalkylene)) acrylate and/or (poly(oxyalkylene)) methacrylate are preferable, and they may be distributed at random or may be block copolymerized. Further, examples of the poly(oxyalkylene) group include a poly(oxyethylene) group, a poly(oxypropylene) group, and a poly(oxybutylene) group. Incidentally, the polymers may be units having alkylenes different in chain length in the same chain length, such as a poly(block combination of oxyethylene, oxypropylene, and oxybutylene), and poly(block combination of oxyethylene and oxypropylene). In addition, the copolymers of monomers having fluoroaliphatic groups and (poly(oxyalkylene)) acrylate (or methacrylate) may not be only binary copolymers but also ternary or higher copolymers obtained by copolymerization of monomers having different two or more kinds of fluoroaliphatic groups or different two or more kinds of (poly(oxyalkylene)) acrylates (or methacrylates) or the like at the same time.

Examples of the commercially available surfactant include MEGAFACE F178, F-470, F-473, F-475, F-476, and F-472 (manufactured by DIC Corp.); a copolymer of an acrylate (or methacrylate) having a C₆F₁₃ group with a (poly(oxyalkylene)) acrylate (or methacrylate); and a copolymer of an acrylate (or methacrylate) having a C₃F₇ group with a (poly(oxyethylene)) acrylate (or methacrylate) and a (poly(oxypropylene)) acrylate (or methacrylate).

Moreover, in the present invention, surfactants other than fluorine- and/or silicon-based surfactants can also be used. Specific examples thereof include nonionic surfactants, for example, polyoxyethylene alkyl ethers such as polyoxyethylene lauryl ether, polyoxyethylene stearyl ether, polyoxyethylene cetyl ether, and polyoxyethylene oleyl ether, polyoxyethylene alkylallyl ethers such as polyoxyethylene octylphenol ether and polyoxyethylene nonyiphenol ether, polyoxyethylene/polyoxypropylene block copolymers, sorbitan fatty acid esters such as sorbitan monolaurate, sorbitan monopalmitate, sorbitan monostearate, sorbitan monooleate, sorbitan trioleate, and sorbitan tristearate, and polyoxyethylene sorbitan fatty acid esters such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate.

These surfactants may be used singly or in combination of some kinds thereof.

The amount of the surfactant (F) to be used is preferably 0.01% to 10% by mass, and more preferably 0.1% to 5% by mass, with respect to the total amount (excluding the solvent) of the resist composition.

(G) Onium Carboxylate Salt

The resist composition of the present invention may contain an onium carboxylate salt (G). Examples of the onium carboxylate salt include a sulfonium carboxylate salt, an iodonium carboxylate salt, and an ammonium carboxylate salt. In particular, as the onium carboxylate salt (G), an iodonium salt and a sulfonium salt are preferable. Further, it is preferable that the carboxylate residue of the onium carboxylate salt (G) does not contain an aromatic group and a carbon-carbon double bond. As a particularly preferred anionic moiety, a linear, branched, or cyclic (monocyclic or polycyclic) alkylcarboxylate anion having 1 to 30 carbon atoms is preferable. Further, a carboxylate anion in which a part or all of the alkyl groups are substituted with fluorine is more preferable. An oxygen atom may be contained in the alkyl chain, by which the transparency to the lights of 220 nm or less is ensured, thus, sensitivity and resolving power are enhanced, and density dependency and exposure margin are improved.

Examples of the fluorine-substituted carboxylate anion include anions of fluoroacetic acid, difluoroacetic acid, trifluoroacetic acid, pentafluoropropionic acid, heptafluorobutyric acid, nonafluoropentanoic acid, perfluorododecanoic acid, perfluorotridecanoic acid, perfluorocyclohexanecarboxylic acid, and 2,2-bistrifluoromethylpropionic acid.

These onium carboxylate salts (G) can be synthesized by reacting sulfonium hydroxide, iodonium hydroxide, or ammonium hydroxide and carboxylic acid with silver oxide in an appropriate solvent.

The content of the onium carboxylate salt (G) in the composition is generally 0.1% to 20% by mass, preferably 0.5% to 10% by mass, and more preferably 1% to 7% by mass, with respect to the total solid contents of the resist composition.

(H) Other Additives

The resist composition of the present invention can further contain a dye, a plasticizer, a light sensitizer, a light absorbent, an alkali-soluble resin, a dissolution inhibitor, a compound that promotes solubility in a developer (for example, a phenol compound with a molecular weight of 1,000 or less, an alicyclic or aliphatic compound having a carboxyl group), and the like, as desired.

Such a phenol compound having a molecular weight of 1,000 or less may be easily synthesized by those skilled in the art with reference to the method described in, for example, JP1992-122938A (JP-H04-122938A), JP 1990-28531A (JP-H02-28531A), U.S. Pat. No. 4,916,210A, EP219294B, and the like.

Specific examples of the alicyclic or aliphatic compound having a carboxyl group include, but not limited to, a carboxylic acid derivative having a steroid structure such as a cholic acid, deoxycholic acid or lithocholic acid, an adamantane carboxylic acid derivative, adamantane dicarboxylic acid, cyclohexane carboxylic acid, and cyclohexane dicarboxylic acid.

The concentration of the solid contents of the resist composition is usually 1.0% to 10% by mass, preferably 2.0% to 5.7% by mass, and more preferably 2.0% to 5.3% by mass. By setting the concentration of the solid contents to these ranges, it is possible to uniformly apply the resist solution onto a substrate and additionally, it is possible to form a resist pattern having excellent line width roughness. The reason is not clear; however, it is considered that, by setting the concentration of the solid contents to 10% by mass or less, and preferably 5.7% by mass or less, the aggregation of materials, particularly the photoacid generator, in the resist solution is suppressed, and as a result, it is possible to form a uniform resist film.

The concentration of the solid contents is the weight percentage of the weight of the resist components excluding the solvent with respect to the total weight of the resist composition.

The resist composition in the present invention is used by dissolving the components in a predetermined organic solvent, preferably a mixed solvent, filtering the solution through a filter, and then applying the solution onto a predetermined support (substrate). The filter for use in the filtration is preferably a polytetrafluoroethylene-, polyethylene-, or nylon-made filter having a pore size of 0.1 μm or less, more preferably 0.05 μm or less, and still more preferably 0.03 μm or less. For the filtration with a filter, circular filtration may be carried out as in, for example, JP2002-62667A, or may be carried out by connecting a plurality of kinds of filters in series or in parallel. Further, the composition may be filtered in plural times. In addition, the composition may be subjected to a deaeration treatment or the like before and after filtration through a filter.

[Composition (Topcoat Composition) for Forming Upper Layer Film]

Next, a composition (topcoat composition) for forming an upper layer film, for forming an upper layer film (topcoat), which is used in the pattern forming method of the present invention will be described.

In a case of carrying out liquid immersion exposure in the pattern forming method of the present invention, by forming a topcoat, it is possible to expect effects of preventing an immersion liquid from being in direct contact with a resist film, suppressing the resist performance from being deteriorated by permeation of the immersion liquid into a resist film and elution of the resist film components into the immersion liquid, and further, preventing an exposure device lens from being contaminated by elution of the elution components into the immersion liquid.

The present invention further relates to a composition for forming an upper layer film, containing a resin having a repeating unit (a) with a ClogP value of 2.85 or more and a compound (b) with a ClogP of 1.30 or less, in which the receding contact angle of the upper layer film formed with the composition for forming an upper layer film with water is 70 degrees or more.

The topcoat composition used in the pattern forming method of the present invention is preferably a composition including the resin (X) which will be described later, and a solvent, in order to uniformly form the topcoat on the resist film.

<Solvent>

In order to form a good pattern while not dissolving the resist film, it is preferable that the topcoat composition in the present invention contains a solvent in which the resist film is not dissolved, and it is more preferable that a solvent with components different from an organic developer is used.

Further, from the viewpoint of the prevention of elution into an immersion liquid, low solubility in an immersion liquid is preferred, and low solubility in water is more preferable. In the present specification, “having low solubility in an immersion liquid” means insolubility in an immersion liquid. Similarly, “having low solubility in water” means insolubility in water. Further, from the viewpoints of volatility and coatability, the boiling point of the solvent is preferably 90° C. to 200° C.

The description of “having low solubility in an immersion liquid” indicates that in an example of the solubility in water, when a topcoat composition is coated on a silicon wafer and dried to form a film, and then the film is immersed in pure water at 23° C. for 10 minutes, the decrease rate in the film thickness after drying is within 3% of the initial film thickness (typically 50 nm).

In the present invention, from the viewpoint of uniformly applying the topcoat, a solvent having a concentration of the solid contents of preferably 0.01% to 20% by mass, more preferably 0.1% to 15% by mass, and most preferably 1% to 10% by mass is used.

The solvent that can be used is not particularly limited as long as it can dissolve the resin (X) which will be described later and does not dissolve the resist film, but suitable examples thereof include an alcohol-based solvent, an ether-based solvent, an ester-based solvent, a fluorine-based solvent, and a hydrocarbon-based solvent, with a non-fluorinated alcohol-based solvent being more preferably used. Thus, the non-dissolving property for the resist film is further enhanced and in a case where the topcoat composition is coated on the resist film, a topcoat can be more uniformly formed without dissolving the resist film. The viscosity of the solvent is preferably 5 centipoises (cP) or less, more preferably 3 cP or less, still more preferably 2 cP or less, and particularly preferably 1 cP or less. Further, centipoises can be converted into pascal seconds according to the following formula: 1,000 cP=1Pa·s.

From the viewpoint of coatability, the alcohol-based solvent is preferably a monohydric alcohol, and more preferably a monohydric alcohol having 4 to 8 carbon atoms. As the monohydric alcohol having 4 to 8 carbon atoms, a linear, branched, or cyclic alcohol may be used, but a linear or branched alcohol is preferable. As such an alcohol-based solvent, for example, alcohols such as 1-butanol, 2-butanol, 3-methyl-1-butanol, 4-methyl-1-pentanol, 4-methyl-2-pentanol, isobutyl alcohol, tert-butyl alcohol, 1-pentanol, 2-pentanol, 1-hexanol, 1-heptanol, 1-octanol, 2-hexanol, 2-heptanol, 2-octanol, 3-hexanol, 3-heptanol, 3-octanol, and 4-octanol; glycols such as ethylene glycol, propylene glycol, diethylene glycol, and triethylene glycol; glycol ethers such as ethylene glycol monomethyl ether, propylene glycol monomethyl ether, diethylene glycol monomethyl ether, triethylene glycol monoethyl ether, and methoxymethylbutanol; or the like can be used. Among those, alcohol and glycol ether are preferable, and 1 -butanol, 1-hexanol, 1-pentanol, 3-methyl-1-butanol, 4-methyl-1-pentanol, 4-methyl-2-pentanol, and propylene glycol monomethyl ether are more preferable.

Examples of the ether-based solvent include, in addition to the glycol ether-based solvents, dioxane, tetrahydrofuran, isoamyl ether, and diisoamyl ether. Among the ether-based solvents, an ether-based solvent having a branched structure is preferable.

Examples of the ester-based solvent include methyl acetate, ethyl acetate, isopropyl acetate, butyl acetate (n-butyl acetate), pentyl acetate, hexyl acetate, isoamyl acetate, butyl propionate (n-butyl propionate), butyl butyrate, isobutyl butyrate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, methyl formate, ethyl formate, butyl formate, propyl formate, ethyl lactate, butyl lactate, propyl lactate, methyl 2-hydroxyisobutyrate, isobutyl isobutyrate, and butyl propionate. Among the ester-based solvents, an ester-based solvent having a branched structure is preferable.

Examples of the fluorine-based solvent include 2,2,3,3,4,4-hexafluoro-1-butanol, 2,2,3,3,4,4,5,5-octafluoro-l-pentanol, 2,2,3,3,4,4,5,5,6,6-decafluoro-1-hexanol, 2,2,3,3,4,4-hexafluoro-1,5-pentanediol, 2,2,3,3,4,4,5,5-octafluoro-1,6-hexanediol, 2,2,3,3,4,4,5,5,6,6,7,7-dodecafluoro-1,8-octanediol, 2-fluoroanisole, 2,3-difluoroanisole, perfluorohexane, perfluoroheptane, perfluoro-2-pentanone, perfluoro-2-butyltetrahydrofuran, perfluorotetrahydrofuran, perfluorotributylamine, and perfluorotetrapentylamine. Among these, a fluorinated alcohol and a fluorinated hydrocarbon-based solvent can be suitably used.

Examples of the hydrocarbon-based solvent include aromatic hydrocarbon-based solvents such as toluene, xylene, and anisole; and aliphatic hydrocarbon-based solvents such as n-heptane, n-nonane, n-octane, n-decane, 2-methylheptane, 3-methylheptane, 3,3-dimethylhexane, and 2,3,4-trimethylpemane.

These solvents are used singly or as a mixture of a plurality thereof.

In a case of mixing a solvent other than the above-mentioned solvents, the mixing ratio is usually 0% to 30% by mass, preferably 0% to 20% by mass, and still more preferably 0% to 10% by mass, with respect to the total amount of the solvent of the topcoat composition. By mixing a solvent other than the above-mentioned solvents, the solubility for the resist film, the solubility of the resin in the topcoat composition, the elution characteristics from the resist film, or the like can be appropriately adjusted.

<Resin (X)>

The resin (X) in the topcoat composition is preferably transparent to the exposure light source to be used since the light reaches the resist film through the topcoat upon exposure. In a case where the resin (X) is used for ArF liquid immersion exposure, it is preferable that the resin does not have an aromatic group in view of transparency to ArF light.

The resin (X) preferably has any one or more of a “fluorine atom,” a “silicon atom,” or a “CH₃ partial structure which is contained in a side chain moiety of a resin”, and preferably has two or more of the atom or structure. The resin (X) is preferably a water-insoluble resin (hydrophobic resin).

In a case where the resin (X) contains a fluorine atom and/or a silicon atom, the fluorine atom and/or the silicon atom may be contained in the main chain or substituted in the side chain of the resin (X).

In a case where the resin (X) contains a fluorine atom, it is preferably a resin which contains an alkyl group having a fluorine atom, a cycloalkyl group having a fluorine atom, or an aryl group having a fluorine atom, as a partial structure having a fluorine atom.

The alkyl group having a fluorine atom (preferably having 1 to 10 carbon atoms, and more preferably having I to 4 carbon atoms) is a linear or branched alkyl group in which at least one hydrogen atom is substituted with a fluorine atom, and may further have another substituent.

The cycloalkyl group having a fluorine atom is a monocyclic or polycyclic cycloalkyl group in which at least one hydrogen atom is substituted with a fluorine atom, and they may further have another substituent.

The aryl group having a fluorine atom is an aryl group in which at least one hydrogen atom is substituted with a fluorine atom, such as a phenyl group and a naphthyl group, and they may further have another substituent.

Specific examples of the alkyl group having a fluorine atom, the cycloalkyl group having a fluorine atom, and the aryl group having a fluorine atom are shown below, but the present invention is not limited thereto.

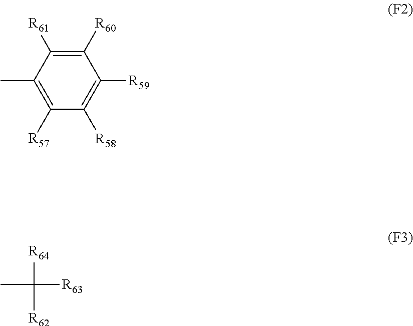

In General Formulae (F2) to (F3),

R₅₇ to R₆₄ each independently represent a hydrogen atom, a fluorine atom, or an alkyl group, provided that at least one of R₅₇, . . . , or R₆₁ or of R₆₂, . . . , or R₆₄ is a fluorine atom or an alkyl group (preferably having 1 to 4 carbon atoms) in which at least one hydrogen atom is substituted for by a fluorine atom. It is preferable that all of R₅₇ to R₆₁ are a fluorine atom. Each of R₆₂ and R₆₃ is preferably an alkyl group (preferably having 1 to 4 carbon atoms) in which at least one hydrogen atom is substituted with a fluorine atom, and more preferably a perfluoroalkyl group having 1 to 4 carbon atoms. R₆₂ and R₆₃ may be linked to each other to form a ring.

Specific examples of the group represented by General Formula (F2) include a p-fluorophenyl g group, a pentafluorophenyl group, and a 3,5-di(trifluoromethyl)phenyl group.

Specific examples of the group represented by General Formula (F3) include a trifluoroethyl group, a pentafluoropropyl group, a pentafluoroethyl group, a heptafluorobutyl group, a hexafluoroisopropyl group, a heptafluoroisopropyl group, a hexafluoro(2-methyl)isopropyl group, a nonafluorobutyl group, an octafluoroisobutyl group, a nonafluorohexyl group, a nonafluoro-t-butyl group, a perfluoroisopentyl group, a perfluorooctyl group, a perfluoro(trimethyl)hexyl group, a 2,2,3,3-tetrafluorocyclobutyl group, and a perfluorocyclohexyl group. A hexafluoroisopropyl group, a heptafluoroisopropyl group, a hexafluoro(2-methyl)isopropyl group, an octafluoroisobutyl group, a nonafluoro-t-butyl group, or a perfluoroisopentyl group is preferable, and a hexafluoroisopropyl group or a heptafluoroisopropyl group is more preferable.

In a case where the resin (X) has a silicon atom, it is preferably a resin having an alkylsilyl structure (preferably a trialkylsilyl group) or a cyclic siloxane structure as a partial structure having a silicon atom.

Specific examples of the alkylsilyl structure or the cyclic siloxane structure include groups represented by General Formulae (CS-1) to (CS-3).

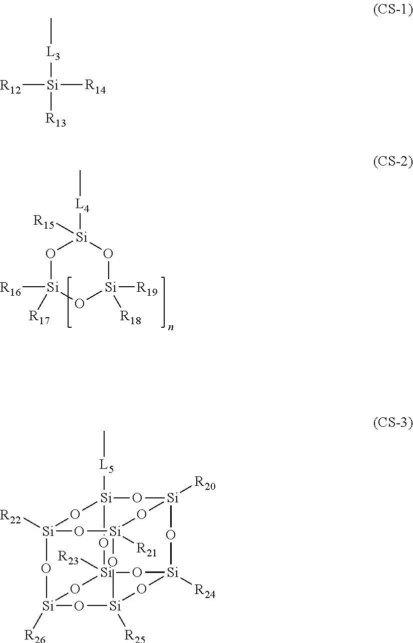

In General Formulae (CS-1) to (CS-3),

R₁₂ to R₂₆ each independently represent a linear or branched alkyl group (preferably having 1 to 20 carbon atoms) or a cycloalkyl group (preferably having 3 to 20 carbon atoms).

L₃ to L₅ each represent a single bond or a divalent linking group. The divalent linking group is a single group or a combination of two or more groups, selected from the group consisting of an alkylene group, a phenylene group, an ether group, a thioether group, a carbonyl group, an ester group, an amide group, a urethane group, and a urea group.

n represents an integer of 1 to 5.

Examples of the resin (X) include a resin having at least one selected from the group of the repeating units represented by General Formulae (C-I) to (C-V).

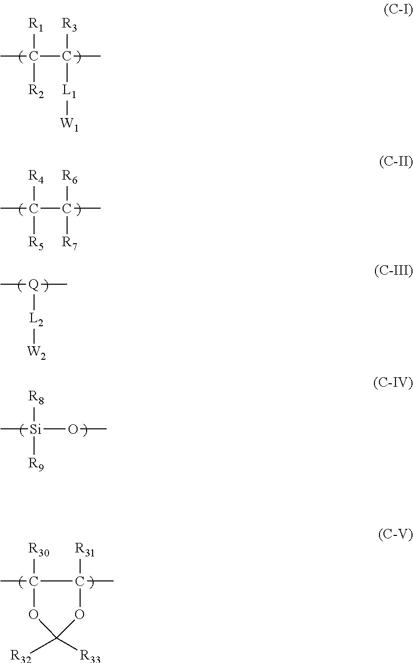

In General Formulae (C-I) to (C-V),

R₁ to R₃ each independently represent a hydrogen atom, a fluorine atom, a linear or branched alkyl group having 1 to 4 carbon atoms, or a linear or branched fluorinated alkyl group having 1 to 4 carbon atoms.

W₁ and W₂ each represent an organic group having at least one of a fluorine atom or a silicon atom.

R₄ to R₇ each independently represent a hydrogen atom, a fluorine atom, a linear or branched alkyl group having 1 to 4 carbon atoms, or a linear or branched fluorinated alkyl group having 1 to 4 carbon atoms, provided that at least one of R₄, . . . , or R₇ represents a fluorine atom. R₄ and R_{5,} or R₆ and R₇ may be combined to form a ring.

R₈ represents a hydrogen atom or a linear or branched alkyl group having 1 to 4 carbon atoms.

R₉ represents a linear or branched alkyl group having 1 to 4 carbon atoms or a linear or branched fluorinated alkyl group having 1 to 4 carbon atoms.

L₁ and L₂ each represent a single bond or a divalent linking group, which are the same as L₃ to L₅.

Q represents a monocyclic or polycyclic aliphatic group. That is, it represents an atomic group containing two carbon atoms (C—C) bonded to each other for forming an alicyclic structure.

R₃₀ and R₃₁ each independently represent a hydrogen atom or a fluorine atom. R₃₂ and R₃₃ each independently represent an alkyl group, a cycloalkyl group, a fluorinated alkyl group, or a fluorinated cycloalkyl group.

It is to be noted that the repeating unit represented by General Formula (C-V) has at least one fluorine atom in at least one of R₃₀, R₃₁, R₃₂, or R₃₃.

The resin (X) preferably has a repeating unit represented by General Formula (C-I), and more preferably a repeating unit represented by any of General Formulae (C-Ia) to (C-Id).

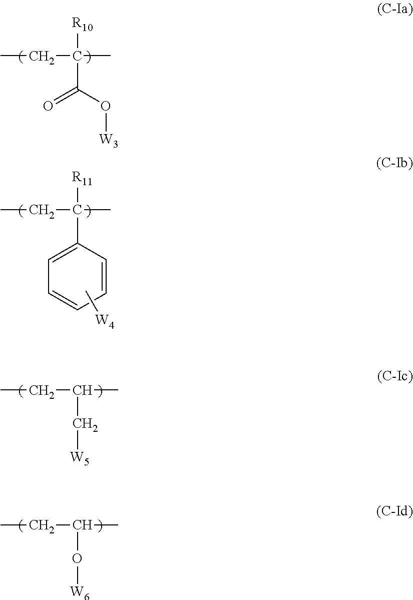

In General Formulae (C-Ia) to (C-Id),

R₁₀ and R₁₁ each represents a hydrogen atom, a fluorine atom, a linear or branched alkyl group having 1 to 4 carbon atoms, or a linear or branched fluorinated alkyl group having 1 to 4 carbon atoms.

W₃ to W₆ are each an organic group having one or more of at least one of a fluorine atom or a silicon atom.

When W₃ to W₆ are each an organic group having a fluorine atom, they are each preferably a fluorinated, linear or branched alkyl group or cycloalkyl group having 1 to 20 carbon atoms, or a linear, branched, or cyclic fluorinated alkyl ether group having 1 to 20 carbon atoms.

Examples of the fluorinated alkyl group represented by each of W₃ to W₆ include a trifluoroethyl group, a pentafluoropropyl group, a hexafluoroisopropyl group, a hexafluoro(2-methyl)pisopropyl group, a heptafluorobutyl group, a heptafluoroisopropyl group, an octafluoroisobutyl group, a nonafluorohexyl group, a nonafluoro-t-butyl group, a perfluoroisopentyl group, a perfluorooctyl group, and a perfluoro(trimethyl)hexyl group.

When W₃ to W₆ are each an organic group having a silicon atom, an alkylsilyl structure or a cyclic siloxane structure is preferable. Specific examples thereof include groups represented by General Formulae (CS-1) to (CS-3).

Specific examples of the repeating unit represented by General Formula (C-I) are shown below, but are not limited thereto. X represents a hydrogen atom, —CH₃, —F, or —CF₃.

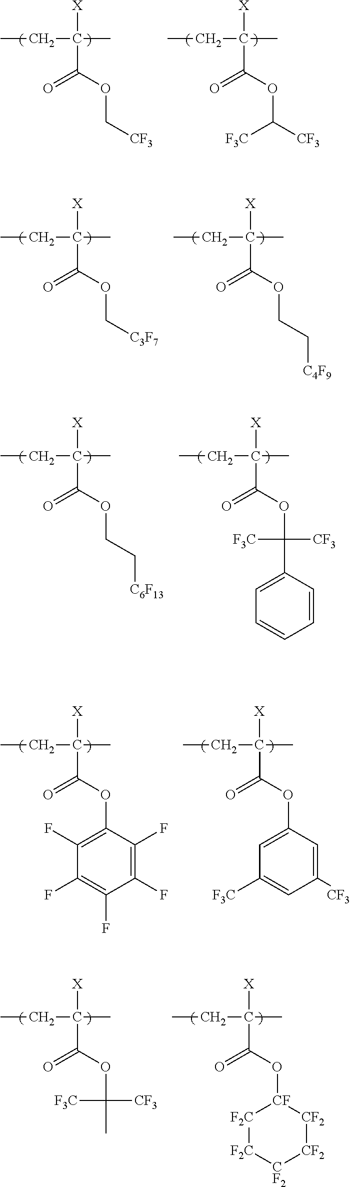

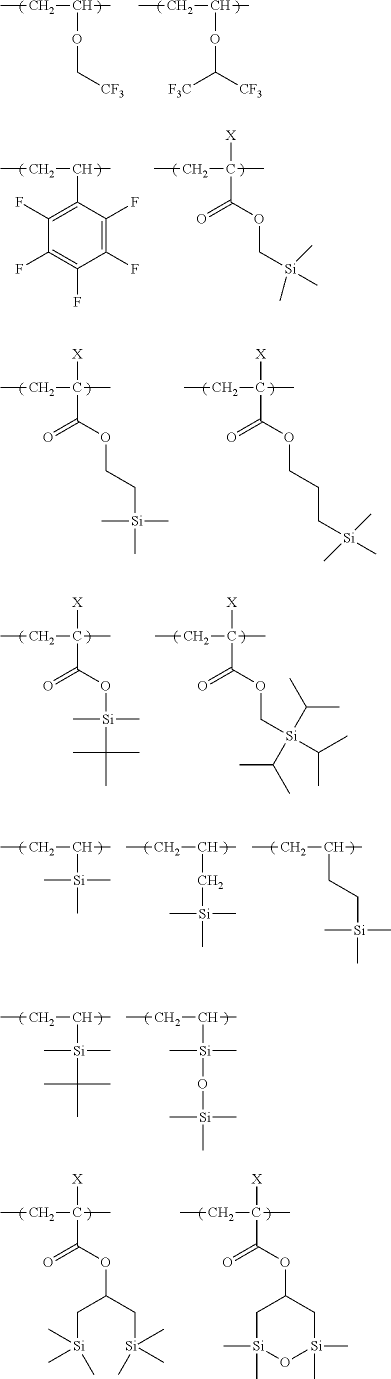

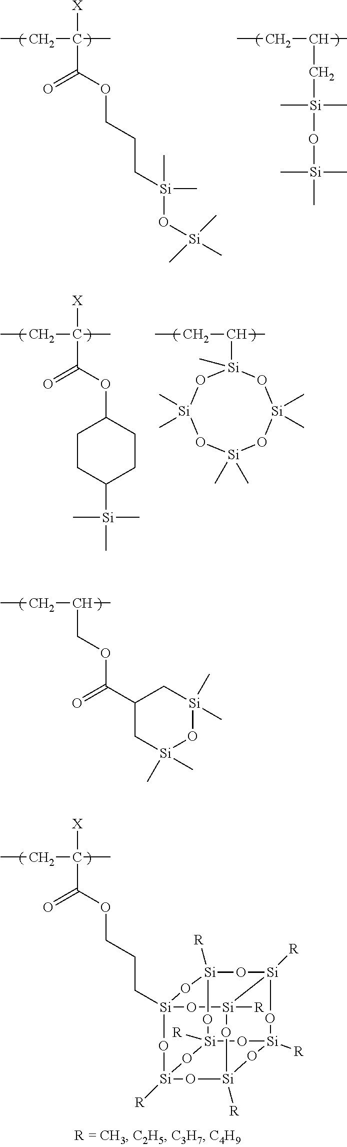

Furthermore, it is also preferable that the resin (X) includes a CH₃ partial structure in the side chain moiety, as described above.

Here, the CH₃ partial structure (hereinafter also simply referred to as a “side chain CH₃ partial structure”) contained in the side chain moiety in the resin (X) includes a CH₃ partial structure contained in an ethyl group, a propyl group, or the like.

On the other hand, a methyl group bonded directly to the main chain of the resin (X) (for example, an a-methyl group in the repeating unit having a methacrylic acid structure) makes only a small contribution of uneven distribution to the surface of the resin (X) due to the effect of the main chain, and it is therefore not included in the CH₃ partial structure in the present invention.

More specifically, in a case where the resin (X) contains a repeating unit derived from a monomer having a polymerizable moiety with a carbon-carbon double bond, such as a repeating unit represented by General Formula (M), and in addition, R₁₁ to R₁₄ are CH₃ “themselves”, such CH₃ is not included in the CH₃ partial structure contained in the side chain moiety in the present invention.

On the other hand, a CH₃ partial structure which is present via a certain atom from a C—C main chain corresponds to the CH₃ partial structure in the present invention. For example, in a case where R₁₁ is an ethyl group (CH₂CH₃), the resin (X) has “one” CH₃ partial structure in the present invention.

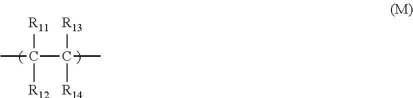

In General Formula (M),

R₁₁ to R₁₄ each independently represent a side chain moiety.

Examples of R₁₁ to R₁₄ in the side chain moiety include a hydrogen atom and a monovalent organic group.

Examples of the monovalent organic group for R₁₁ to R₁₄ include an alkyl group, a cycloalkyl group, an aryl group, an alkyloxycarbonyl group, a cycloalkyloxycarbonyl group, an aryloxycarbonyl group, an alkylaminocarbonyl group, a cycloalkylaminocarbonyl group, and an arylaminocarbonyl group, each of which may further have a substituent.

The resin (X) is preferably a resin including a repeating unit having the CH₃ partial structure in the side chain moiety thereof, and more preferably has, as such a repeating unit, at least one repeating unit (x) of the repeating units represented by General Formula (II) or a repeating unit represented by General Formula (III).

Hereinafter, the repeating unit represented by General Formula (II) will be described in detail.

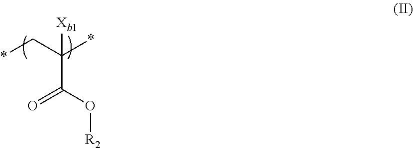

In General Formula (II), X_{b1} represents a hydrogen atom, an alkyl group, a cyano group, or a halogen atom, and R, represents an organic group having one or more CH₃ partial structures stable to an acid. Here, the organic group stable to an acid is, more specifically, preferably an organic group not containing the “group capable of decomposing by the action of an acid to produce a polar group” described in the resin (A).

The alkyl group of X_{b1} is preferably an alkyl group having 1 to 4 carbon atoms, and examples thereof include a methyl group, an ethyl group, a propyl group, a hydroxymethyl group, and a trifluoromethyl group, with the methyl group being preferable.

X_{b1} is preferably a hydrogen atom or a methyl group.

Examples of R₂ include an alkyl group, a cycloalkyl group, an alkenyl group, a cycloalkenyl group, an aryl group, and an aralkyl group, each of which has one or more CH₃ partial structures. The cycloalkyl group, the alkenyl group, the cycloalkenyl group, the aryl group, and the aralkyl group may further have an alkyl group as a substituent.

R₂ is preferably an alkyl group or an alkyl-substituted cycloalkyl group, which has one or more CH₃ partial structures.

The number of the CH₃ partial structures contained in the organic group which has one or more CH₃ partial structures and is stable against an acid as R₂ is preferably from 2 to 10, and more preferably from 2 to 8.

The alkyl group having one or more CH₃ partial structures in R₂ is preferably a branched alkyl group having 3 to 20 carbon atoms. Specific preferred examples of the alkyl group include an isopropyl group, an isobutyl group, a 3-pentyl group, a 2-methyl-3-butyl group, a 3-hexyl group, a 2-methyl-3-pentyl group, a 3-methyl-4-hexyl group, a 3,5-dimethyl-4-pentyl group, an isooctyl group, a 2,4,4-trimethylpentyl group, a 2-ethylhexyl group, a 2,6-dimethylheptyl group, a 1,5-dimethyl-3-heptyl group, and a 2,3,5,7-tetramethyl-4-heptyl group, and the alkyl group is more preferably an isobutyl group, a t-butyl group, a 2-methyl-3-butyl group, a 2-methyl-3-pentyl group, a 3-methyl-4-hexyl group, a 3.5-dimethyl-4-pentyl group, a 2,4,4-trimethylpentyl group, a 2-ethylhexyl group, a 2,6-dimethylheptyl group, a 1,5-dimethyl- 3-heptyl group, or a 2,3,5,7-tetramethyl-4-heptyl group.

The cycloalkyl group having one or more CH₃ partial structures in R₂ may be monocyclic or polycyclic. Specific examples thereof include groups having a monocyclo, bicyclo, tricyclo, or tetracyclo structure having 5 or more carbon atoms. The number of carbon atoms is preferably 6 to 30, and particularly preferably 7 to 25. Preferred examples of the cycloalkyl group include an adamantyl group, a noradamantyl group, a decalin residue, a tricyclodecanyl group, a tetracyclododecanyl group, a norbornyl group, cedrol group, a cyclopentyl group, a cyclohexyl group, a cycloheptyl group, a cyclooctyl group, a cyclodecanyl group, and a cyclododecanyl group, and the cycloalkyl group is more preferably an adamantyl group, a norbornyl group, a cyclohexyl group, a cyclopentyl group, a tetracyclododecanyl group, or a tricyclodecanyl group, and even more preferably a norbornyl group, a cyclopentyl group, or a cyclohexyl group.

The alkenyl group having one or more CH₃ partial structures in R₂ is preferably a linear or branched alkenyl group having 1 to 20 carbon atoms, and more preferably a branched alkenyl group.

The aryl group having one or more CH₃ partial structures in R₂ is preferably an aryl group having 6 to 20 carbon atoms, and examples thereof include a phenyl group and a naphthyl group, and the aryl group is preferably a phenyl group.

The aralkyl group having one or more CH₃ partial structures in R₂ is preferably an aralkyl group having 7 to 12 carbon atoms, and examples thereof include a benzyl group, a phenethyl group, and a naphthylmethyl group.

Specific examples of the hydrocarbon group having two or more CH₃ partial structures in R₂ include an isopropyl group, an isobutyl group, a t-butyl group, a 3-pentyl group, a 2-methyl-3-butyl group, a 3-hexyl group, a 2,3-dimethyl-2-butyl group, a 2-methyl-3-pentyl group, a 3-methyl-4-hexyl group, a 3,5-dimethyl-4-pentyl group, an isooctyl group, a 2,4,4-trimethylpentyl group, a 2-ethylhexyl group, a 2,6-dimethylheptyl group, a 1,5-dimethyl-3-heptyl group, a 2,3,5,7-tetramethyl-4-heptyl group, a 3,5-dimethylcyclohexyl group, a 4-isopropylcyclohexyl group, a 4-t-butylcyclohexyl group, and an isobornyl group. The hydrocarbon group is more preferably an isobutyl group, a t-butyl group, a 2-methyl-3-butyl group, a 2,3-dimethyl-2-butyl group, a 2-methyl-3-pentyl group, a 3-methyl-4-hexyl group, a 3,5-dimethyl-4-pentyl group, a 2,4,4-trimethylpentyl group, a 2-ethylhexyl group, a 2,6-dimethylheptyl group, a 1,5-dimethyl-3-heptyl group, a 2,3,5,7-tetramethyl-4-heptyl group, a 3,5-dimethylcyclohexyl group, a 3,5-ditert-butylcyclohexyl group, a 4-isopropylcyclohexyl group, a 4-t-butylcyclohexyl group, or an isobornyl group.

Specific preferred examples of the repeating unit represented by General Formula (II) are shown below, but the present invention is not limited thereto.

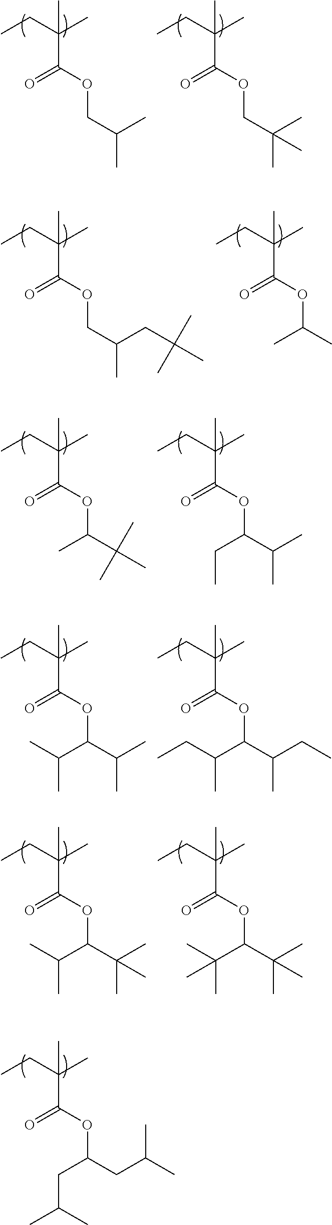

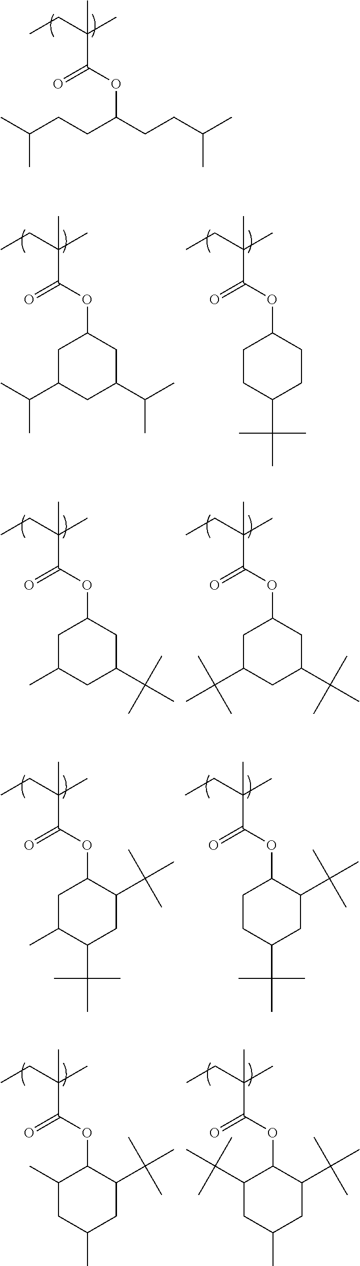

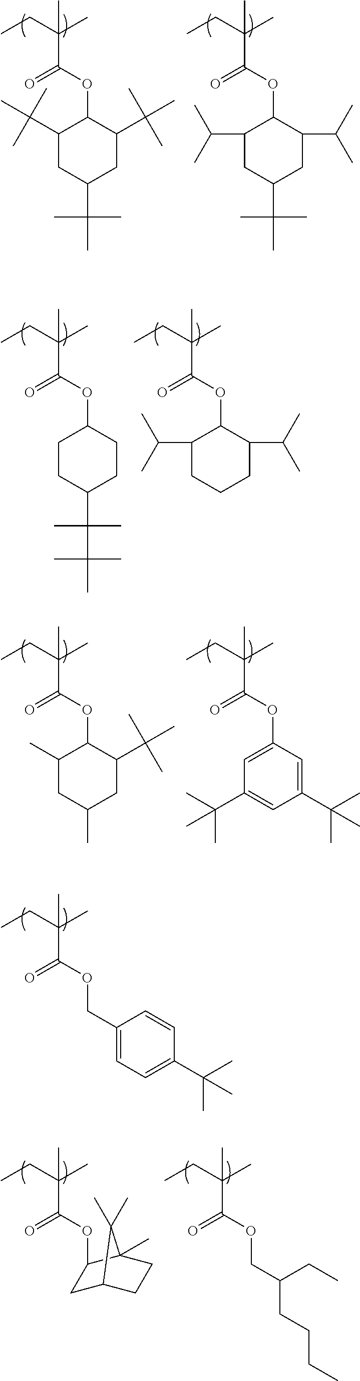

The repeating unit represented by General Formula (II) is preferably a repeating unit which is stable against an acid (non-acid-decomposable), and specifically, it is preferably a repeating unit not having a group capable of decomposing by the action of an acid to generate a polar group.

Hereinafter, the repeating unit represented by General Formula (III) will be described in detail.

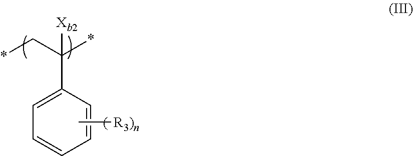

In General Formula (III), X_{b2} represents a hydrogen atom, an alkyl group, a cyano group, or a halogen atom, R₃ represents an organic group having one or more CH₃ partial structures, which is stable against an acid, and n represents an integer of 1 to 5.

The alkyl group of X_{b2} is preferably an alkyl group having 1 to 4 carbon atoms, and examples thereof include a methyl group, an ethyl group, a propyl group, a hydroxymethyl group, and a trifluoromethyl group, but a hydrogen atom is preferable.

X_{b2} is preferably a hydrogen atom.

Since R₃ is an organic group which is stable against an acid, more specifically, R₃ is preferably an organic group which does not a group capable of decomposing by the action of an acid, described above with regard to the resin (A), to generate a polar group.

Examples of R₃ include an alkyl group having one or more CH₃ partial structures.

The number of the CH₃ partial structures contained in the organic group which has one or more CH₃ partial structures and is stable against an acid as R₃ is preferably from 1 to 10, more preferably from 1 to 8, and still more preferably from 1 to 4.

The alkyl group having one or more CH₃ partial structures in R₃ is preferably a branched alkyl group having 3 to 20 carbon atoms. Specific preferred examples of the alkyl group include an isopropyl group, an isobutyl group, a 3-pentyl group, a 2-methyl-3-butyl group, a 3-hexyl group, a 2-methyl-3-pentyl group, a 3-methyl-4-hexyl group, a 3,5-dimethyl-4-pentyl group, an isooctyl group, a 2,4,4-trimethylpentyl group, a 2-ethylhexyl group, a 2,6-dimethylheptyl group, a 1,5-dimethyl-3-heptyl group, and a 2,3,5,7-tetramethyl-4-heptyl group. The alkyl group is more preferably an isobutyl group, a t-butyl group, a 2-methyl-3-butyl group, a 2-methyl-3-pentyl group, a 3-methyl-4-hexyl group, a 3,5-dimethyl-4-pentyl group, a 2,4,4-trimethylpentyl group, a 2-ethylhexyl group, a 2,6-dimethylheptyl group, a 1,5-dimethyl-3-heptyl group, or a 2,3,5,7-tetramethyl-4-heptyl group.

Specific examples of the alkyl group having two or more CH₃ partial structures in R₃ include an isopropyl group, an isobutyl group, a t-butyl group, a 3-pentyl group, a 2,3-dimethylbutyl group, a 2-methyl-3-butyl group, a 3-hexyl group, a 2-methyl-3-pentyl group, a 3-methyl-4-hexyl group, a 3,5-dimethyl-4-pentyl group, an isooctyl group, a 2,4,4-trimethylpentyl group, a 2-ethylhexyl group, a 2,6-dimethylheptyl group, a 1,5-dimethyl-3-heptyl group, and a 2,3,5,7-tetramethyl-4-heptyl group. The alkyl group is more preferably one having 5 to 20 carbon atoms, and is more preferably an isopropyl group, a t-butyl group, a 2-methyl-3-butyl group, a 2-methyl-3-pentyl group, a 3-methyl-4-hexyl group, a 3,5-dimethyl-4-pentyl group, a 2,4,4-trimethylpentyl group, a 2-ethylhexyl group, a 1,5-dimethyl-3-heptyl group, a 2,3,5,7-tetramethyl-4-heptyl group, or a 2,6-dimethylheptyl group.

n represents an integer of 1 to 5, preferably an integer of 1 to 3, and more preferably 1 or 2.

Specific preferred examples of the repeating unit represented by General Formula (III) are shown below, but the present invention is not limited thereto.

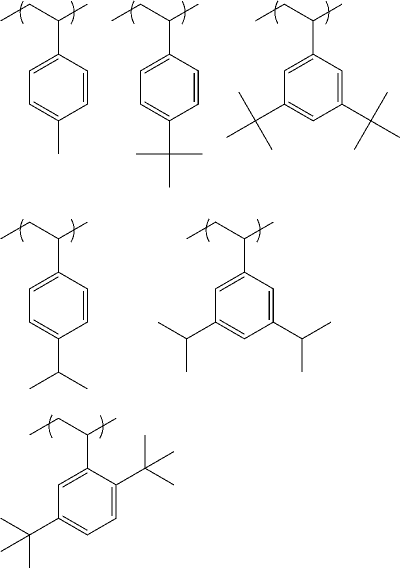

The repeating unit represented by General Formula (III) is preferably a repeating unit which is stable against an acid (non-acid-decomposable), and specifically, it is preferably a repeating unit which does not have a group capable of decomposing by the action of an acid to generate a polar group.

In a case where the resin (X) includes a CH₃ partial structure in the side chain moiety, and in particular, in a case where the resin (X) has neither a fluorine atom nor a silicon atom, the content of at least one repeating unit (x) of the repeating unit represented by General Formula (II) or the repeating unit represented by General Formula (III) is preferably 90% by mole or more, and more preferably 95% by mole or more, with respect to all the repeating units of the resin (X).

In order to adjust the solubility in an organic developer, the resin (X) may have a repeating unit represented by General Formula (Ia).

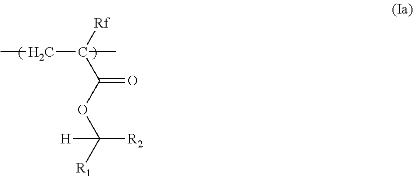

In General Formula (Ia),

Rf represents a fluorine atom or an alkyl group in which at least one hydrogen atom is substituted with a fluorine atom.

R₁ represents an alkyl group.

R₂ represents a hydrogen atom or an alkyl group.

In General Formula (Ia), the alkyl group in which at least one hydrogen atom of Rf is substituted with a fluorine atom is preferably one having 1 to 3 carbon atoms, and more preferably a trifluoromethyl group.

The alkyl group of R₁ is preferably a linear or branched alkyl group having 3 to 10 carbon atoms, and more preferably a branched alkyl group having 3 to 10 carbon atoms.

R₂ is preferably a linear or branched alkyl group having 1 to 10 carbon atoms, and more preferably a linear or branched alkyl group having 3 to 10 carbon atoms.

Specific examples of the repeating unit represented by General Formula (Ia) are shown below, but the present invention is not limited thereto.

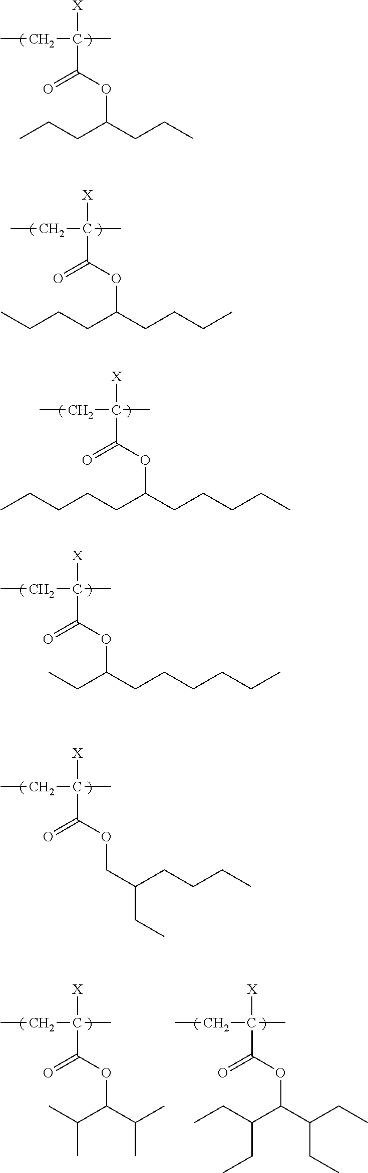

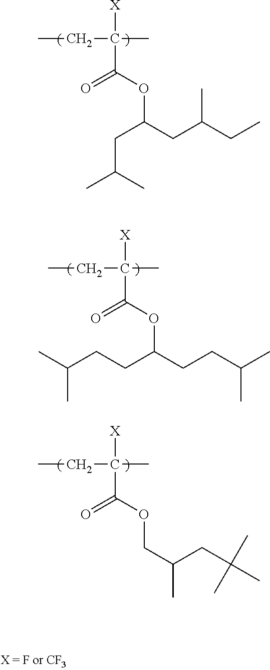

The resin (X) may further have a repeating unit represented by General Formula (III).

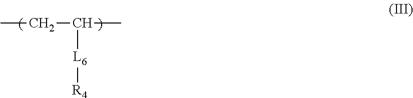

In General Formula (III),

R₄ represents an alkyl group, a cycloalkyl group, an alkenyl group, a cycloalkenyl group, a trialkylsilyl group, or a group having a cyclic siloxane stricture.

L₆ represents a single bond or a divalent linking group.

In General Formula (III), the alkyl group of R₄ is preferably a linear or branched alkyl group having 3 to 20 carbon atoms.

The cycloalkyl group is preferably a cycloalkyl group having 3 to 20 carbon atoms.

The alkenyl group is preferably an alkenyl group having 3 to 20 carbon atoms.

The cycloalkenyl group is preferably a cycloalkenyl group having 3 to 20 carbon atoms.

The trialkylsilyl group is preferably a trialkylsilyl group having 3 to 20 carbon atoms.

The group having a cyclic siloxane structure is preferably a group containing a cyclic siloxane structure having 3 to 20 carbon atoms.

The divalent linking group of L₆ is preferably an alkylene group (preferably having 1 to 5 carbon atoms) or an oxy group.

The resin (X) may have a lactone group, an ester group, an acid anhydride, or the same group as the acid-decomposable group in the resin (A).

The resin (X) may further have a repeating unit represented by General Formula (VIII).

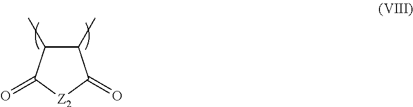

In General Formula (VIII),

Z₂ represents —O— or —N(R₄₁)—. R₄₁ represents a hydrogen atom, a hydroxyl group, an alkyl group, or —OSO₂—R₄₂. R₄₂ represents an alkyl group, a cycloalkyl group, or a camphor residue. The alkyl group of each of R₄₁ and R₄₂ may further be substituted with a halogen atom (preferably a fluorine atom) or the like.

Examples of the repeating unit represented by General Formula (VIII) include the following specific examples, but the present invention is not limited thereto.

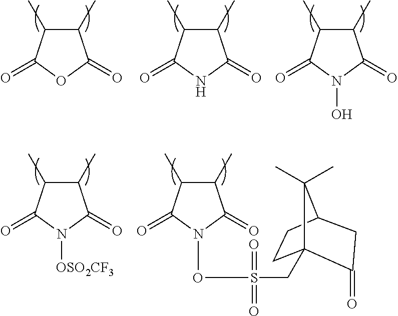

The resin (X) may contain a repeating unit (d) derived from a monomer having an alkali-soluble group. Thus, the solubility in immersion water and the solubility in a coating solvent can be controlled in some cases. Examples of the alkali-soluble group include a phenolic hydroxyl group, a carboxylic acid group, a fluorinated alcohol group, a sulfonic acid group, a sulfonamido group, a sulfonylimido group, an (alkylsulfonyl)(alkylcarbonyl)methylene group, an (alkyisulfonyl)(alkylcarbonyl)pimido group, a bis(alkylcarbonyl)methylene group, a bis(alkylcarbonyl)imido group, a bis(alkylsulfonyl)methylene group, a bis(alkylsulfonyl)imido group, a tris(alkylcarbonyl)methylene group, and a group having a tris(alkylsulfonyl)methylene group.

As the monomer having an alkali-soluble group, a monomer having an acid dissociation constant pKa of 4 or more is preferable, a monomer having a pKa of 4 to 13 is more preferable, and a monomer having a pKa of 8 to 13 is the most preferable. By incorporation of a monomer having a pKa of 4 or more, swelling upon development of a negative tone and a positive tone is suppressed, and thus, not only good developability for an organic developer but also good developability in a case of using an alkali developer are obtained.

The acid dissociation constant pKa is described in Chemical Handbook (II) (Revised 4^{th} Edition, 1993, compiled by the Chemical Society of Japan, Maruzen Inc.), and the pKa value of a monomer having an alkali-soluble group can be measured, for example, at 25° C. using an infinite-dilution solvent.

The monomer having a pKa of 4 or more is not particularly limited, and examples thereof include a monomer containing an acid group (alkali-soluble group) such as a phenolic hydroxyl group, a sulfonamido group, —COCH₂CO—, a fluoroalcohol group, and a carboxylic acid group. A monomer containing a fluoroalcohol group is particularly preferable. The fluoroalcohol group is a fluoroalkyl group substituted with at least one hydroxyl group, preferably having 1 to 10 carbon atoms, and more preferably 1 to 5 carbon atoms. Specific examples of the fluoroalcohol group include —CF₂OH, —CH₂CF₂OH, —CH₂CF₂CF₂OH, —C(CF₃)₂OH, —CF₂CF(CF₃)OH, and —CH₂C(CF₃)₂OH. As a fluoroalcohol group, a hexafluoroisopropanol group is particularly preferable.

The total amount of the repeating unit derived from a monomer having an alkali-soluble group in the resin (X) is preferably 0% to 70% by mole, more preferably 0% to 60% by mole, and still more preferably 0% to 50% by mole, with respect to all the repeating units constituting the resin (X).

The monomer having an alkali-soluble group may contain only one or two or more acid groups. The repeating unit derived from the monomer preferably has 2 or more acid groups, more preferably 2 to 5 acid groups, and particularly preferably 2 or 3 acid groups, per one repeating unit.

Specific examples of the repeating unit derived from a monomer having an alkali-soluble group include, but not limited to, those described in paragraphs [0278] to [0287] of JP2008-309878A.

In one of the preferred aspects, the resin (X) may be any resin selected from (X-1) to (X-8) described in paragraph [0288] of JP2008-309878A.

The repeating units which can be contained in the resin (X), and the like have been described above, but in the present invention, the resin (X) has a repeating unit (a) with a ClogP value of 2.85 or more.

The ClogP value of the repeating unit (a) is preferably 2.90 or more, more preferably 3.00 or more, and still more preferably 3.50 or more. The ClogP value of the repeating unit (a) is usually 7.00 or less.

Here, the ClogP value is a ClogP value of a monomer (compound having an unsaturated double bond group) corresponding to a repeating unit, and is a value calculated for the compound using Chem DrawUltra ver. 12.0.2.1076 (manufactured by Cambridge Corporation).

Specific examples of the repeating unit (a) with a ClogP value of 2.85 or more include the repeating units satisfying the ClogP value of the monomer corresponding to the repeating unit of 2.85 or more, among the specific examples of the repeating unit which can be contained in the above-mentioned resin (X), but suitable examples thereof include the following repeating units.

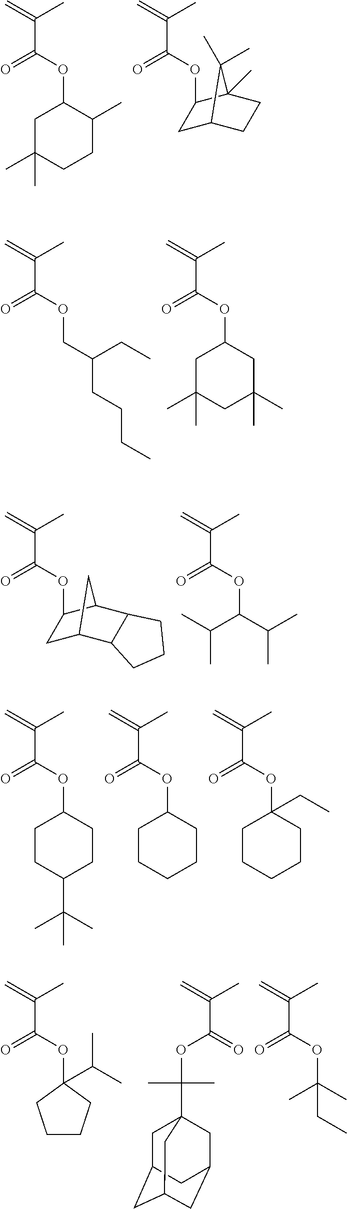

The content of the repeating unit (a) with a ClogP value of 2.85 or more is preferably 50% to 100% by mole, more preferably 60% to 100% by mole, and still more preferably 70% to 100% by mole, with respect to all the repeating units of the resin (X).

The resin (X) is preferably solid at normal temperature (25° C.). Further, the glass transition temperature (Tg) is preferably 50° C. to 200° C., and more preferably 80° C. to 160° C.

The resin being solid at 25° C. means that the melting point is 25° C. or higher.

The glass transition temperature (Tg) can be measured by a differential scanning colorimetry. For example, it can be determined by after heating a sample and then cooling, followed by analyzing the change in the specific volume when heating the sample again at 5° C./min.

It is preferable that the resin (X) is insoluble in an immersion liquid (preferably water) and is soluble in an organic developer. From the viewpoint of the possibility of peeling by development using an alkali developer, the resin (X) may be soluble in an alkali developer.

In a case where the resin (X) has silicon atoms, the content of the silicon atoms is preferably 2% to 50% by mass, and more preferably 2% to 30% by mass, with respect to the molecular weight of the resin (X). In this case, the resin (X) is preferably a resin having a repeating unit containing a silicon atom, and the amount of the repeating units containing a silicon atom is preferably 10% to 100% by mass, and more preferably 20% to 100% by mass, with respect to all the repeating units of the resin (X).

In a case where the resin (X) contains fluorine atoms, the content of fluorine atoms is preferably 5% to 80% by mass, and more preferably 10% to 80% by mass, with respect to the molecular weight of the resin (X). In this case, the resin (X) is preferably a resin having a repeating unit containing a fluorine atom, and the amount of the repeating units containing fluorine atoms is preferably 10% to 100% by mass, and more preferably 30% to 100% by mass, with respect to all the repeating units of the resin (X).

On the other hand, particularly in a case where the resin (X) includes a CH₃ partial structure in the side chain moiety, an aspect in which the resin (X) does not substantially contain a fluorine atom and a silicon atom is also preferable, and in this case, specifically, the content of the repeating unit having a fluorine atom and a silicon atom is preferably 10% by mole or less, more preferably 5% by mole or less, still more preferably 3% by mole or less, and particularly preferably 1% by mole or less, and ideally 0% by mole, that is, containing neither a fluorine atom nor a silicon atom, with respect to all the repeating units in the resin (X).

Furthermore, the resin (X) preferably consists of substantially only a repeating unit composed of only atoms selected from a carbon atom, an oxygen atom, a hydrogen atom, a nitrogen atom, and a sulfur atom. More specifically, the repeating unit composed of only atoms selected from a carbon atom, an oxygen atom, a hydrogen atom, a nitrogen atom, and a sulfur atom preferably accounts for 95% by mole or more, more preferably 97% by mole or more, still more preferably 99% by mole or more, and ideally 100% by mole, with respect to all the repeating units in the resin (X).

The resin contained in the composition for forming an upper layer film is preferably a resin having a repeating unit containing an alicyclic hydrocarbon group, and thus, EL is more excellent.

Examples of the skeleton of the alicyclic hydrocarbon in the alicyclic hydrocarbon group include the same skeletons as those of the alicyclic hydrocarbon group of R₁₂ to R₂₅ in General Formula (pI) to (pV), described with regard to the resin (A) typically contained in the actinic ray-sensitive or radiation-sensitive resin composition.

The content of the repeating unit containing an alicyclic hydrocarbon group is preferably 10% to 100% by mole, more preferably 30% to 100% by mole, and still more preferably 50% to 100% by mole, with respect to all the repeating units of the resin contained in the composition for forming an upper layer film.

Moreover, the resin contained in the composition for fowling an upper layer film may be a resin having a repeating unit containing an acid-decomposable group.

Examples of the repeating unit containing an acid-decomposable group include the same groups as those described with regard to the resin (A) typically contained in the actinic ray-sensitive or radiation-sensitive resin composition.

The content of the repeating unit containing an acid-decomposable group is preferably 1% to 30% by mole, more preferably 5% to 25% by mole, and still more preferably 10% to 20% by mole, with respect to all the repeating units of the resin contained in the composition for forming an upper layer film.

The weight-average molecular weight of the resin (X) is preferably 1,000 to 100,000, more preferably 1,000 to 50,000, still more preferably 2,000 to 15,000, and particularly preferably 3,000 to 15,000, in terms of standard polystyrene.

In the resin (X), naturally, the content of impurities such as a metal is small, but the content of residual monomers is also preferably 0% to 10% by mass, more preferably 0% to 5% by mass, and still more preferably 0% to 1% by mass, from the viewpoint of reduction in elution from a topcoat to an immersion liquid. Further, the molecular weight distribution (Mw/Mn, also referred to as dispersity) is preferably in a range of 1 to 5, more preferably in a range of 1 to 3, and still more preferably in a range of 1 to 1.5.

Various commercially available products may be used as the resin (X), or the resin may be synthesized by a conventional method (for example, radical polymerization). Examples of the general synthesis method include a batch polymerization method of dissolving monomer species and an initiator in a solvent and heating the solution, thereby carrying out the polymerization, and a dropwise-addition polymerization method of adding dropwise a solution containing monomer species and an initiator to a heated solvent for 1 to 10 hours, with the dropwise-addition polymerization method being preferable. Examples of the reaction solvent include ethers such as tetrahydrofuran, 1,4-dioxane, and diisopropyl ether; ketones such as methyl ethyl ketone and methyl isobutyl ketone; ester solvents such as ethyl acetate; amide solvents such as dimethyl formamide and dimethyl acetamide; and solvents which dissolve the resist composition of the present invention, such as propylene glycol monomethyl ether acetate, propylene glycol monomethyl ether, and cyclohexanone.

It is preferable that the polymerization reaction is carried out in an inert gas atmosphere such as nitrogen and argon. As the polymerization initiator, commercially available radical initiators (azo-based initiators, peroxides, or the like) are used to initiate the polymerization. As the radical initiator, an azo-based initiator is preferable, and the azo-based initiator having an ester group, a cyano group, or a carboxyl group is preferable. Preferable examples of the initiators include azobisisobutyronitrile, azobisdimethylvaleronitrile, and dimethyl 2,2′-azobis(2-methyl propionate). If necessary, a chain transfer agent can also be used. The concentration of the reactant is usually 5% to 50% by mass, preferably 20% to 50% by mass, and more preferably 30% to 50% by mass. The reaction temperature is usually 10° C. to 150° C., preferably 30° C. to 120° C., and more preferably 60° C. to 100° C.

After the completion of the reaction, cooling is carried out to room temperature, and purification is carried out. A usual method such as a liquid-liquid extraction method in which a residual monomer or an oligomer component is removed by washing with water or combining suitable solvents, a purification method in a solution state such as ultrafiltration which extracts and removes only substances having a specific molecular weight or less, a re-precipitation method in which a residual monomer or the like is removed by adding a resin solution dropwise to a poor solvent to coagulate the resin in the poor solvent, or a purification method in a solid state in which filtered resin slurry is washed with a poor solvent can be applied to the purification. For example, by bringing into contact with a solvent (poor solvent), which poorly dissolves or does not dissolve the resin, corresponding to 10 times or less the volume amount of the reaction solution, or preferably 5 times to 10 times the volume amount of the reaction solution, the resin is solidified and precipitated.

The solvent to be used in a case of precipitation or reprecipitation from the polymer solution (precipitation or reprecipitation solvent) may be an arbitrary one so long as it is a poor solvent to the polymer. Depending on the kind of the polymer, it may be appropriately selected from, for example, a hydrocarbon (for example, an aliphatic hydrocarbon such as pentane, hexane, heptane, and octane; an alicyclic hydrocarbon such as cyclohexane and methylcyclohexane; an aromatic hydrocarbon such as benzene, toluene, and xylene), a halogenated hydrocarbon (for example, a halogenated aliphatic hydrocarbon such as methylene chloride, chloroform, and carbon tetrachloride; a halogenated aromatic hydrocarbon such as chlorobenzene and dichlorobenzene), a nitro compound (for example, nitromethane and nitroethane), a nitrile (for example, acetonitrile and benzonitrile), an ether (for example, a chain ether such as diethyl ether, diisopropyl ether, and dimethoxyethane; and a cyclic ether such as tetrahydrofuran and dioxane), a ketone (for example, acetone, methyl ethyl ketone, and diisobutyl ketone), an ester (for example, ethyl acetate, butyl acetate), a carbonate (for example, dimethyl carbonate, diethyl carbonate, ethylene carbonate, and propylene carbonate), an alcohol (for example, methanol, ethanol, propanol, isopropyl alcohol, and butanol), a carboxylic acid (for example, acetic acid), water, and a mixed solvent containing the same. Among these, the precipitation or reprecipitation solvent is preferably a solvent containing at least an alcohol (particularly methanol or the like) or water. In such a solvent containing at least a hydrocarbon, the ratio of the alcohol (particularly, methanol or the like) to other solvents (for example, an ester such as ethyl acetate, and ethers such as tetrahydrofuran) is approximately, for example, the former/the latter (volume ratio; 25° C.) ranging from 10/90 to 99/1, preferably the former/the latter (volume ratio; 25° C.) ranging from 30/70 to 98/2, more preferably the former/the latter (volume ratio; 25° C.) ranging from 50/50 to 97/3.

The amount of the precipitation or reprecipitation solvent to be used may be appropriately selected by taking into consideration efficiency, yield, or the like. In general, it is used in an amount of from 100 to 10,000 parts by mass, preferably from 200 to 2,000 parts by mass and more preferably from 300 to 1,000 parts by mass, with respect to 100 parts by mass of the polymer solution.

In a case of feeding the polymer solution into a precipitation or reprecipitation solvent (poor solvent), the nozzle pore diameter is preferably 4 mmφ) or less (for example, 0.2 to 4 mmφ) and the feeding rate (dropwise addition rate) of the polymer solution into the poor solvent is, for example, in terms of a linear velocity, 0.1 to 10 m/sec, and preferably approximately 0.3 to 5 m/sec.

The precipitation or reprecipitation procedure is preferably carried out under stirring. Examples of the stirring blade which can be used for the stirring include a disc turbine, a fan turbine (including a paddle), a curved vane turbine, an arrow feather turbine, a Pfaudler type, a bull margin type, an angled vane fan turbine, a propeller, a multistage type, an anchor type (or horseshoe type), a gate type, a double ribbon type, and a screw type. It is preferable that the stirring is further carried out for 10 minutes or more, in particular, 20 minutes or more, after the completion of feeding of the polymer solution. In a case where the stirring time is too short, the monomer content in the polymer particles may not be sufficiently reduced in some cases. Further, the mixing and stirring of the polymer solution and the poor solvent may also be carried out by using a line mixer instead of the stirring blade.

Although the temperature in a case of the precipitation or reprecipitation can be appropriately selected by taking into consideration efficiency or performance, the temperature is usually approximately 0° C. to 50° C., preferably in the vicinity of room temperature (for example, approximately 20° C. to 35° C.). The precipitation or reprecipitation procedure may be carried out by using a commonly employed mixing vessel such as stirring tank according to a known method such as a batch system and a continuous system.

The precipitated or reprecipitated particulate polymer is usually subjected to commonly employed solid-liquid separation such as filtration and centrifugation and then dried before using. The filtration is carried out by using a solvent-resistant filter material preferably under elevated pressure. The drying is carried out under atmospheric pressure or reduced pressure (preferably under reduced pressure) at a temperature of approximately 30° C. to 100° C., and preferably approximately 30° C. to 50° C.

Furthermore, after the resin is once precipitated and separated, it may be redissolved in a solvent and then brought into contact with a solvent in which the resin is sparingly soluble or insoluble.

That is, the method may include, after the completion of a radical polymerization reaction, precipitating a resin by bringing the polymer into contact with a solvent in which the polymer is sparingly soluble or insoluble (step a), separating the resin from the solution (step b), dissolving the resin in a solvent again to prepare a resin solution A (step c), then precipitating a resin solid by bringing the resin solution A into contact with a solvent in which the resin is sparingly soluble or insoluble and which is in a volume amount of less than 10 times (preferably a volume amount of 5 times or less) the resin solution A (step d), and separating the precipitated resin (step e).

As the solvent used in a case of the preparation of the resin solution A, the same solvent as the solvent for dissolving the monomer in a case of the polymerization reaction may be used, and the solvent may be the same as or different from each other from the solvent used in a case of the polymerization reaction.

The resin (X) may be used singly or in combination of two or more kinds thereof.

The content of the resin (X) is preferably 50% to 99.9% by mass, and more preferably 60% to 99.0% by mass, with respect to the total solid content of the topcoat composition. Thus, it becomes easier to form an upper layer film having a receding contact angle with water of 70 degrees or more.

<Compound (b) with ClogP of 1.30 or less>

The topcoat composition contains a compound (b) with a ClogP of 1.30 or less.

The ClogP value of the compound (b) is preferably 1.00 or less, and more preferably 0.70 or less. The ClogP value of the compound (b) is usually −3.00 or more.

Here, the ClogP value is a value calculated for the compound using Chem DrawUltra ver. 12.0.2.1076 (Cambridge Corporation).

The compound (b) with a ClogP of 1.30 or less is preferably a compound having an ether bond, and more preferably a compound having an alkyleneoxy group.

It is preferable that the compound (b) has a ClogP of 1.30 or less, and is at least one of a basic compound or a base generator. When the compound (b) corresponds to at least one of a basic compound or a base generator, it acts as a quencher that traps an acid generated from the photoacid generator in the resist film, and thus, DOF is more excellent.

The compound (b) with a ClogP of 1.30 or less is more preferably an amine compound. Specific examples of the amine compound include amine compounds among the compounds which will be described later.

(Basic Compound)

As the basic compound with a ClogP of 1.30 or less, which can contain the topcoat composition, an organic basic compound is preferable, and a nitrogen-containing basic compound is more preferable. For example, the basic compounds with a ClogP of 1.30 or less among those described as the basic compound which may be contained in the resist composition of the present invention can be used, and specific suitable examples thereof include the compounds having the structures represented by Formulae (A) to (E) described above.

In addition, for example, the compounds which are classified into the following (1) to (7) can be used.

(1) Compound Represented by General Formula (BS-1)

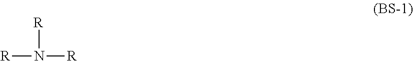

In General Formula (BS-1),

R's each independently represent a hydrogen atom or an organic group. Here, at least one of three R's is an organic group.

This organic group is selected such that the ClogP of the compound is 1.30 or less, and examples thereof include a linear or branched alkyl group, a monocyclic or polycyclic cycloalkyl group, an aryl group, or an aralkyl group, which has a heteroatom in the chain or as a ring member, or has a polar group as a substituent.

The number of carbon atoms in the alkyl group as R is not particularly limited, but is normally 1 to 20, and preferably 1 to 12.

The number of carbon atoms in the cycloalkyl group as R is not particularly limited, but is normally 3 to 20, and preferably 5 to 15.

The number of carbon atoms in the aryl group as R is not particularly limited, but is normally 6 to 20, and preferably 6 to 10. Specific examples thereof include a phenyl group and a naphthyl group.

The number of carbon atoms in the aralkyl group as R is not particularly limited, but is normally 7 to 20, and preferably 7 to 11. Specifically, examples thereof include a benzyl group.

Examples of the polar group as the substituent contained in the alkyl group, the cycloalkyl group, the aryl group, and the aralkyl group as R include a hydroxy group, a carboxy group, an alkoxy group, an aryloxy group, an alkylcarbonyloxy group, and an alkyloxycarbonyl group.

Furthermore, it is preferable that at least two of R's in the compound represented by General Formula (BS-1) are organic groups.

Specific suitable examples of the compound represented by General Formula (BS-1) include the compounds in which at least one R is an alkyl group substituted with a hydroxyl group. Specific examples thereof include triethanolamine and N,N-dihydroxyethylaniline.

Moreover, the alkyl group as R preferably has an oxygen atom in the alkyl chain. That is, an oxyalkylene chain is preferably formed. As the oxyalkylene chain, —CH₂CH₂O— is preferable. Specific examples thereof include tris(methoxyethoxyethyl)amine and a compound disclosed after line 60 of column 3 in the specification of U.S. Pat. No. 6,040,112A.

Examples of the basic compound represented by General Formula (BS-1) include the following compounds.

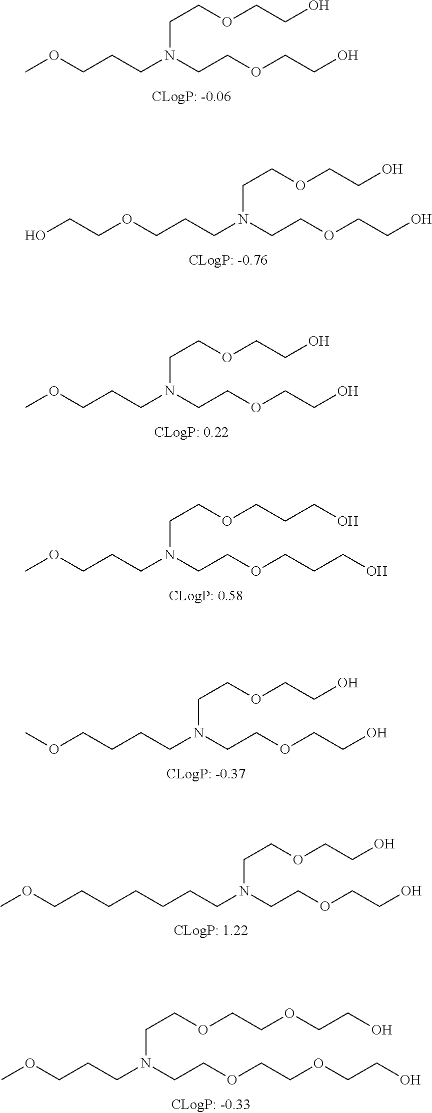

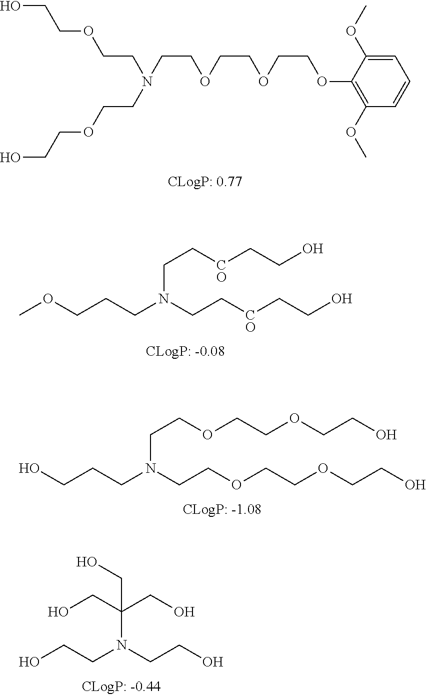

(2) Compound Having Nitrogen-Containing Heterocyclic Structure

A compound having a nitrogen-containing heterocyclic structure can also be appropriately used as the basic compound with a ClogP of 1.30 or less.

The nitrogen-containing heterocycle may have aromatic properties, or may not have aromatic properties. The nitrogen-containing heterocycle may have a plurality of nitrogen atoms. Further, the nitrogen-containing heterocycle preferably contains heteroatoms other than nitrogen. Specific examples thereof include a compound having an imidazole structure, a compound having a piperidine structure [N-hydroxyethylpiperidine (ClogP: −0.81) and the like], a compound having a pyridine structure, and a compound having an antipyrine structure [antipyrine (ClogP: −0.20), hydroxyantipyrine (ClogP: −0.16), and the like].

Furthermore, a compound having two or more ring structures is suitably used. Specific examples thereof include 1,5-diazabicyclo[4.3.0]non-5-ene (ClogP: −0.02) and 1,8-diazabicyclo[5.4.0]undec-7-ene (ClogP: 1.14).

(3) Amine Compound Having Phenoxy Group

An amine compound having a phenoxy group can also be appropriately used as the basic compound with a ClogP of 1.30 or less.

An amine compound having a phenoxy group is a compound having a phenoxy group at the terminal on the opposite side to the N atom of the alkyl group which is contained in an amine compound. The phenoxy group may have a substituent such as an alkyl group, an alkoxy group, a halogen atom, a cyano group, a nitro group, a carboxy group, a carboxylic acid ester group, a sulfonic acid ester group, an aryl group, an aralkyl group, an aryloxy group, or an aryloxy group.

This compound more preferably has at least one oxyalkylene chain between the phenoxy group and the nitrogen atom. The number of oxyalkylene chains in one molecule is preferably 3 to 9, and more preferably 4 to 6. Among the oxyalkylene chains, —CH₂CH₂O— is particularly preferable.

An amine compound having a phenoxy group is obtained by, for example, heating a mixture of a primary or secondary amine having a phenoxy group and an haloalkyl ether to be reacted, by adding an aqueous solution of a strong base such as sodium hydroxide, potassium hydroxide, or tetraalkylammonium thereto, and by extracting the resultant product with an organic solvent such as ethyl acetate and chloroform. In addition, an amine compound having a phenoxy group can also be obtained by heating a mixture of a primary or secondary amine and an haloalkyl ether having a phenoxy group at the terminal to be reacted, by adding an aqueous solution of a strong base such as sodium hydroxide, potassium hydroxide, or tetraalkylammonium thereto, and by extracting the resultant product with an organic solvent such as ethyl acetate and chloroform.

(4) Ammonium Salt

An ammonium salt can also be appropriately used as the basic compound with a ClogP of 1.30 or less. Examples of the anion of the ammonium salt include halide, sulfonate, borate, and phosphate. Among these, halide and sulfonate are particularly preferable.

As the halide, chloride, bromide, or iodide is particularly preferable.

As the sulfonate, an organic sulfonate having 1 to 20 carbon atoms is particularly preferable. Examples of the organic sulfonate include alkyl sulfonate and aryl sulfonate having 1 to 20 carbon atoms.

The alkyl group included in the alkyl sulfonate may have a substituent. Examples of the substituent include a fluorine atom, a chlorine atom, a bromine atom, an alkoxy group, an acyl group, and an aryl group. Specific examples of the alkyl sulfonate include methanesulfonate, ethanesulfonate, butanesulfonate, hexanesulfonate, octanesulfonate, benzylsulfonate, trifluoromethanesulfonate, pentafluoroethanesulfonate, and nonafluorobutanesulfonate.

Examples of the aryl group included in the aryl sulfonate include a phenyl group, a naphthyl group, and an anthryl group. These aryl groups may have a substituent. As the substituent, for example, a linear or branched alkyl group having 1 to 6 carbon atoms or a cycloalkyl group having 3 to 6 carbon atoms is preferable. Specifically, for example, a methyl group, an ethyl group, an n-propyl group, an isopropyl group, an n-butyl group, an i-butyl group, a t-butyl group, an n-hexyl group, or a cyclohexyl group is preferable. Examples of other substituents include an alkoxy group having 1 to 6 carbon atoms, a halogen atom, a cyano group, a nitro group, an acyl group, and an acyloxy group.

The ammonium salt may be a hydroxide or a carboxylate. In this case, the ammonium salt is particularly preferably tetraalkylammonium hydroxide (tetraalkylammonium hydroxide such as tetramethylammonium hydroxide, tetraethylammonium hydroxide, or tetra-(n-butyl)ammonium hydroxide) having 1 to 8 carbon atoms.

Preferred examples of the basic compound include guanidine, aminopyridine, aminoalkylpyridine, aminopyrrolidine, indazole, imidazole, pyrazole, pyrazine, pyrimidine, purine, imidazoline, pyrazoline, piperazine, aminomorpholine, and aminoalkylmorpholine. These may further have a substituent.

Preferred examples of the substituent include an amino group, an aminoalkyl group, an alkylamino group, an aminoaryl group, an arylamino group, an alkyl group, an alkoxy group, an acyl group, an acyloxy group, an aryl group, an aryloxy group, a nitro group, a hydroxyl group, and a cyano group.

Particularly preferred examples of the basic compound include guanidine (ClogP: −2.39), 1,1-dimethylguanidine (ClogP: −1.04), 1,1,3,3-tetramethylguanidine (ClogP: −0.29), imidazole (ClogP: 2-methylimidazole (ClogP: 0.24), 4-methylimidazole (ClogP: 0.24), N-methylimidazole (ClogP: −0.01), 2-aminopyridine (ClogP: 0.32), 3-aminopyridine (ClogP: 0.32), 4-aminopyridine (ClogP: 0.32), 2-(aminomethyl)pyridine (ClogP: −0.40), 2-amino-3-methylpyridine (ClogP: 0.77), 2-amino-4-methylpyridine (ClogP: 0.82), 2-amino-5-methylpyridine (ClogP: 0.82), 2-amino-6-methylpyridine (ClogP: 0.82), 3-aminoethylpyridine (ClogP: −0.06), 4-aminoethylpyridine (ClogP: −0.06), 3-aminopyrrolidine (ClogP: piperazine (ClogP: −0.24), N-(2-aminoethyl)piperazine (ClogP: −0.74), N-(2-aminoethyl)piperidine (ClogP: 0.88), 4-piperidinopiperidine (ClogP: 0.73), 2-iminopiperidine (ClogP: 0.29), 1-(2-aminoethyl)pyrrolidine (ClogP: 0.32), pyrazole (ClogP: 0.24), 3-amino-5-methylpyrazole (ClogP: 0.78), pyrazine (ClogP: −0.31), 2-(aminomethyl)-5-methylpyrazine (ClogP: −0.86), pyrimidine (ClogP: −0.31), 2,4-diaminopyrimidine (ClogP: −0.34), 4,6-dihydroxypyrimidine (ClogP: 0.93), 2-pyrazoline (ClogP: −0.57), 3-pyrazoline (ClogP: −1.54), N-aminomorpholine (ClogP: −1.22), and N-(2-aminoethyl)morpholine (ClogP: −0.33).

(5) Compound (PA) That Has Proton-Accepting Functional Group and Generates Compound in Which Proton-Acceptability Is Reduced or Lost, or Which Is Changed from Being Proton-Accepting to Be Acidic, by Being Decomposed upon Irradiation with Actinic Rays or Radiation

The composition according to the present invention may further include, as a basic compound with a ClogP of 1.30 or less, a compound [hereinafter also referred to as a compound (PA)] that has a proton-accepting functional group and decomposes upon irradiation with actinic rays or radiation to generate a compound in which proton acceptor properties are reduced or lost, or which is changed from being proton-accepting properties to be acidic.

The proton-accepting functional group refers to a functional group having a group or electron which is capable of electrostatically interacting with a proton, and for example, means a functional group with a macrocyclic structure, such as a cyclic polyether; or a functional group containing a nitrogen atom having an unshared electron pair not contributing to π-conjugation. The nitrogen atom having an unshared electron pair not contributing to π-conjugation is, for example, a nitrogen atom having a partial structure represented by the following general formula.

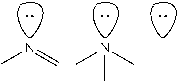

Unshared Electron Pair

Preferred examples of the partial structure of the proton-accepting functional group include crown ether, azacrown ether, primary to tertiary amines, pyridine, imidazole, and pyrazine structures.

The compound (PA) decomposes upon irradiation with actinic rays or radiation to generate a compound exhibiting deterioration in proton acceptor properties, no proton acceptor properties, or a change from the proton acceptor properties to acid properties. Here, exhibiting deterioration in proton acceptor properties, no proton acceptor properties, or a change from the proton acceptor properties to acid properties means a change of proton acceptor properties due to the proton being added to the proton-accepting functional group, and specifically a decrease in the equilibrium constant at chemical equilibrium when a proton adduct is generated from the compound (PA) having the proton-accepting functional group and the proton.

The proton acceptor properties can be confirmed by carrying out pH measurement. In the present invention, the acid dissociation constant pKa of the compound generated by the decomposition of the compound (PA) upon irradiation with actinic rays or radiation preferably satisfies pKa <−1, more preferably −13 <pKa <−1, and still more preferably −13 <pKa <−3.

In the present invention, the acid dissociation constant pKa indicates an acid dissociation constant pKa in an aqueous solution, and is described, for example, in Chemical Handbook (II) (Revised 4^{th} Edition, 1993, compiled by the Chemical Society of Japan, Manizen Inc.), and a lower value thereof indicates higher acid strength. Specifically, the pKa in an aqueous solution may be measured by using an infinite-dilution aqueous solution and measuring the acid dissociation constant at 25° C., or a value based on the Hammett substituent constants and the database of publicly known literature data can also be obtained by computation using the following software package 1. All the values of pKa described in the present specification indicate values determined by computation using this software package.

Software package 1: Advanced Chemistry Development (ACD/Labs) Software V 8.14 for Solaris (1994-2007 ACD/Labs)

The compound (PA) generates a compound represented by General Formula (PA-1), for example, as the proton adduct generated by decomposition upon irradiation with actinic rays or radiation. The compound represented by General Formula (PA-1) is a compound exhibiting deterioration in proton acceptor properties, no proton acceptor properties, or a change from the proton acceptor properties to acid properties since the compound has a proton-accepting functional group as well as an acidic group, as compared with the compound (PA).

Q-A-(X)ₙ-B-R (PA-1)

In General Formula (PA-1),

Q represents —SO₃H, —CO₂H, or —X₁NHX₂Rf, in which Rf represents an alkyl group, a cycloalkyl group, or an aryl group, and X₁ and X₂ each independently represent —SO₂— or —CO—.

A represents a single bond or a divalent linking group.

X represents —SO₂— or —CO—.

n is 0 or 1.

B represents a single bond, an oxygen atom, or —N(Rx)Ry-, in which Rx represents a hydrogen atom or a monovalent organic group, and Ry represents a single bond or a divalent organic group, provided that Rx may be bonded to Ry to form a ring or may be bonded to R to form a ring.

R represents a monovalent organic group having a proton-accepting functional group.

General Formula (PA-1) will be described in more detail.

The divalent linking group in A is preferably a divalent linking group having 2 to 12 carbon atoms, such as and examples thereof include an alkylene group and a phenylene group. The divalent linking group is more preferably an alkylene group having at least one fluorine atom, preferably having 2 to 6 carbon atoms, and more preferably having 2 to 4 carbon atoms. The alkylene chain may contain a linking group such as an oxygen atom and a sulfur atom. In particular, the alkylene group is preferably an alkylene group in which 30% to 100% by number of the hydrogen atoms are substituted with fluorine atoms, and more preferably the carbon atom bonded to the Q site has a fluorine atom. The alkylene group is still more preferably a perfluoroalkylene group, and even still more preferably a perfluoroethylene group, a perfluoropropylene group, or a perfluorobutylene group.

The monovalent organic group in Rx is preferably an organic group having 1 to 30 carbon atoms, and examples thereof include an alkyl group, a cycloalkyl group, an aryl group, an aralkyl group, and an alkenyl group. These groups may further have a substituent.

The alkyl group in Rx may have a substituent, is preferably a linear and branched alkyl group having 1 to 20 carbon atoms, and may have an oxygen atom, a sulfur atom, or a nitrogen atom in the alkyl chain.

Preferred examples of the divalent organic group in Ry include an alkylene group.

Other examples include a ring structure which may be formed by the mutual bonding of Rx and Ry include 5- to 10-membered rings, and particularly preferably 6-membered rings, each of which contains a nitrogen atom.

Furthermore, examples of the alkyl group having a substituent include a group formed by substituting a cycloalkyl group on a linear or branched alkyl group (for example, an adamantylmethyl group, an adamantylethyl group, a cyclohexylethyl group, and a camphor residue).

The cycloalkyl group in Rx may have a substituent, is preferably a cycloalkyl group having 3 to 20 carbon atoms, and may have an oxygen atom in the ring.

The aryl group in Rx may have a substituent, is preferably an aryl group having 6 to 14 carbon atoms.

The aralkyl group in Rx may have a substituent, is preferably an aralkyl group having 7 to 20 carbon atoms.

The alkenyl group in Rx may have a substituent and examples of the alkenyl group include a group having a double bond at an arbitrary position of the alkyl group mentioned as Rx.

The proton-accepting functional group in R is the same as described above, and examples thereof include groups having nitrogen-containing heterocyclic aromatic structures or the like, such as azacrown ether, primary to tertiary amines, pyridine, and imidazole.

As the organic group having such a structure, ones having 4 to 30 carbon atoms are preferable, and examples thereof include an alkyl group, a cycloalkyl group, an aryl group, an aralkyl group, and an alkenyl group.

The alkyl group, the cycloalkyl group, the aryl group, the aralkyl group, and the alkenyl group in the alkyl group, the cycloalkyl group, the aryl group, the aralkyl group, and the alkenyl group, each including a proton-accepting functional group or an ammonium group in R are the same as the alkyl group, the cycloalkyl group, the aryl group, the aralkyl group, and the alkenyl group, respectively, mentioned as Rx.

Examples of the substituent which may be contained in each of the groups include a halogen atom, a hydroxyl group, a nitro group, a cyano group, a carboxy group, a carbonyl group, a cycloalkyl group (preferably having 3 to 10 carbon atoms), an aryl group (preferably having 6 to 14 carbon atoms), an alkoxy group (preferably having 1 to 10 carbon atoms), an acyl group (preferably having 2 to 20 carbon atoms), an acyloxy group (preferably having 2 to 10 carbon atoms), an alkoxycarbonyl group (preferably having 2 to 20 carbon atoms), and an aminoacyl group (preferably having 2 to 20 carbon atoms). With regard to the cyclic structure and the aminoacyl group in the aryl group, the cycloalkyl group, or the like, examples of the substituent further include an alkyl group (preferably having 1 to 20 carbon atoms).

When B is —N(Rx)Ry-, it is preferable that R and Rx are bonded to each other to form a ring. The formation of a ring structure improves the stability and enhances the storage stability of a composition using the same. The number of carbon atoms which form a ring is preferably 4 to 20, the ring may be monocyclic or polycyclic, and an oxygen atom, and a sulfur atom, or a nitrogen atom may be contained in the ring.

Examples of the monocyclic structure include a 4-membered ring, a 5-membered ring, a 6-membered ring, a 7-membered ring, and a 8-membered ring, each containing a nitrogen atom, or the like. Examples of the polycyclic structure include structures formed by a combination of two or three, or more monocyclic structures. The monocyclic structure or the polycyclic structure may have a substituent, and as the substituent, for example, a halogen atom, a hydroxyl group, a cyano group, a carboxy group, a carbonyl group, a cycloalkyl group (preferably having 3 to 10 carbon atoms), an aryl group (preferably having 6 to 14 carbon atoms), an alkoxy group (preferably having 1 to 10 carbon atoms), an acyl group (preferably having 2 to 15 carbon atoms), an acyloxy group (preferably having 2 to 15 carbon atoms), an alkoxycarbonyl group (preferably having 2 to 15 carbon atoms), an aminoacyl group (preferably having 2 to 20 carbon atoms), or the like is preferable. With regard to the cyclic structure in the aryl group, the cycloalkyl group, or the like, examples of the substituent include an alkyl group (preferably having 1 to 15 carbon atoms). With regard to the aminoacyl group, examples of the substituent further include an alkyl group (preferably having 1 to 15 carbon atoms).

Rf in —X₁NHX₂Rf represented by Q is preferably an alkyl group having 1 to 6 carbon atoms, which may have a fluorine atom, and more preferably a perfluoroalkyl group having 1 to 6 carbon atoms. Further, it is preferable that at least one of X₁ or X₂ is —SO₂—, with a case where both X₁ and X₂ are —SO₂— being more preferable.

The compound represented by General Formula (PA-1) in which the Q site is sulfonic acid can be synthesized by a common sulfonamidation reaction. For example, the compound can be synthesized by a method in which one sulfonyl halide moiety of a bissulfonyl halide compound is selectively reacted with an amine compound to form a sulfonamide bond, and then the another sulfonyl halide moiety thereof is hydrolyzed, or a method in which a cyclic sulfonic acid anhydride is reacted with an amine compound to cause ring opening.

The compound (PA) is preferably an ionic compound. The proton-accepting functional group may be contained in an anion moiety or a cation moiety, and it is preferable that the functional group is contained in an anion moiety.

Preferred examples of the compound (PA) include compounds represented by General Formulae (4) to (6).

R_{f}—X₂—N⁻-A-(X)ₙ-B-R (4)

R—SO₃⁻−[C]⁺ (5)

R—CO₂⁻[C]³⁰ (6)

In General Formulae (4) to (6), A, X, n, B, R, Rf, X₁, and X₂ each have the same definitions as in General Formula (PA-1).

C^{'} represents a counter cation.

As the counter cation, an onium cation is preferable. More specifically, in the photoacid generator, preferred examples thereof include a sulfonium cation described as S⁺(R₂₀₁)(R₂₀₂)(R₂₀₃) in General Formula (ZI) and an iodonium cation described as I⁺(R₂₀₄)(R₂₀₅) in General Formula (ZII).

Specific examples of the compound (PA) include, but not limited to, the compounds described in paragraphs [0743] to [0750] of JP2013-83966A.

Furthermore, in the present invention, compounds (PA) other than a compound that generates the compound represented by General Formula (PA-1) can also be appropriately selected. For example, a compound containing a proton acceptor moiety at its cationic moiety may be used as an ionic compound. More specific examples thereof include a compound represented by General Formula (7).

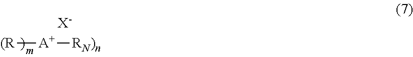

In the formula, A represents a sulfur atom or an iodine atom.

m represents 1 or 2 and n represents 1 or 2, provided that in n=3 in a case where A is a sulfur atom and that in+n=2 in a case where A is an iodine atom.

R represents an aryl group.

R_{N} represents an aryl group substituted with the proton-accepting functional group.

X⁻ represents a counter anion.

Specific examples of X⁻ include the same ones as X⁻ in General Formula (ZI) as described above.

Specific preferred examples of the aryl group of R and R_{N} include a phenyl group.

Specific examples of the proton-accepting functional group, contained in R_{N}, are the same as the proton-accepting functional groups described above in Formula (PA-1).

In the composition of the present invention, the blend ratio of the compound (PA) in the entire composition is preferably 0.1% to 10% by mass, and more preferably 1% to 8% by mass in the total solid content.

(6) Guanidine Compound

The composition of the present invention may further contain a guanidine compound having a structure represented by the following formula as the basic compound with a ClogP of 1.30 or less.

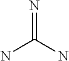

The guanidine compound exhibits strong basicity since the positive charge of the conjugate acid is dispersed and stabilized by the three nitrogen atoms.

For the basicity of the guanidine compound (A) of the present invention, the pKa of a conjugate acid is preferably 6.0 or more, more preferably 7.0 to 20.0 since neutralization reactivity with an acid is high and the roughness properties are excellent, and still more preferably 8.0 to 16.0.

Due to such strong basicity, the diffusibility of an acid is suppressed, and the strong basicity can contribute to formation of an excellent pattern shape.

Moreover, it is preferable that the guanidine compound (A) in the present invention does not have a nitrogen atom, in addition to the guanidine structure.

Specific examples of the guanidine compound are shown below, but the present invention is not limited thereto.

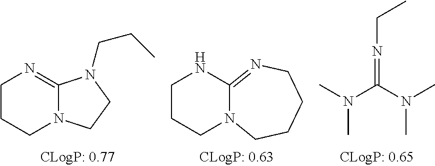

(7) Low Molecular Compound Having Nitrogen Atom and Group That Leaves by Action of Acid

The composition of the present invention can include a low molecular compound (hereinafter referred to as a “low molecular compound (D)” or a “compound (D)”) which has a basic compound with a ClogP of 1.30 or less, a nitrogen atom, and a group that leaves by the action of an acid. The low molecular compound (D) preferably has basicity after the group that leaves by the action of an acid leaves therefrom.

The group that leaves by the action of an acid is not particularly limited, but an acetal group, a carbonate group, a carbamate group, a tertiary ester group, a tertiary hydroxyl group, or a hemiaminal ether group is preferable, and a carbamate group or a hemiaminal ether group is particularly preferable.

The molecular weight of the low molecular compound (D) having a group that leaves by the action of an acid is preferably 100 to 1,000, more preferably 100 to 700, and particularly preferably 100 to 500.

As the compound (D), an amine derivative having a group that leaves by the action of an acid on a nitrogen atom is preferable.

The compound (D) may also have a carbamate group having a protecting group on a nitrogen atom. The protecting group constituting the carbamate group can be represented by General Formula (d-1).

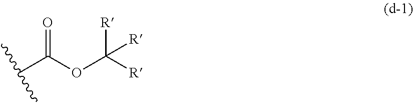

In General Formula (d-1),

R″s each independently represent a hydrogen atom, linear or branched alkyl group, a cycloalkyl group, an aryl group, an aralkyl group, or an alkoxyalkyl group. R″s may be bonded to each other to form a ring.

R′ is preferably a linear or branched alkyl group, a cycloalkyl group, or an aryl group, and more preferably a linear or branched alkyl group or a cycloalkyl group.

Specific structures of such a group are shown below.

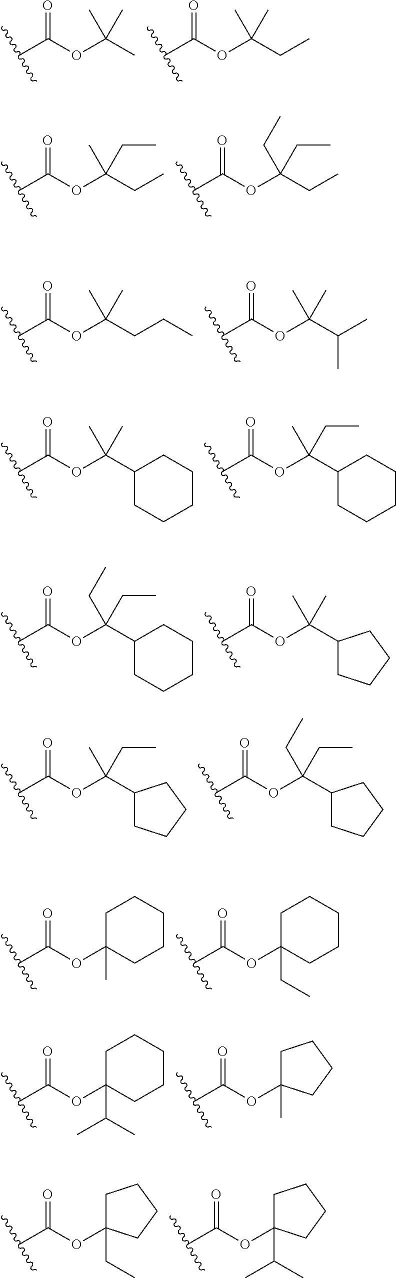

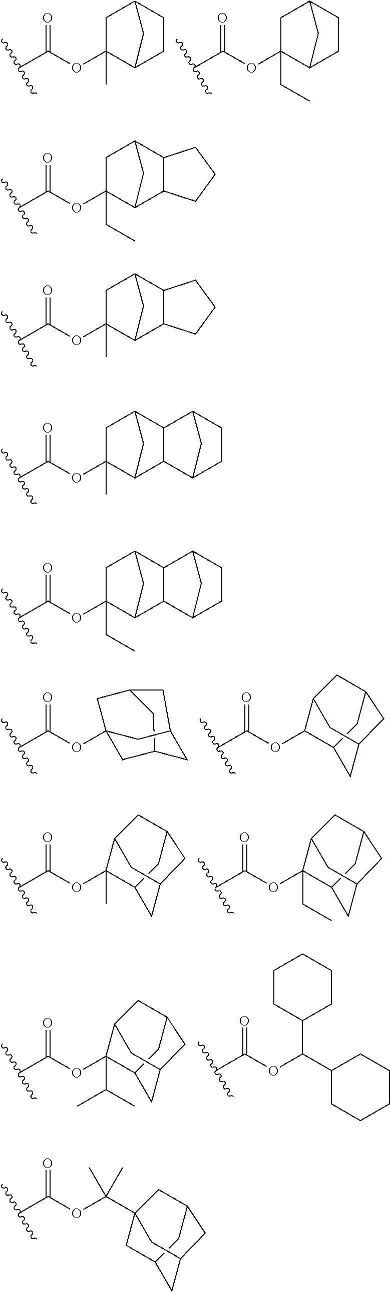

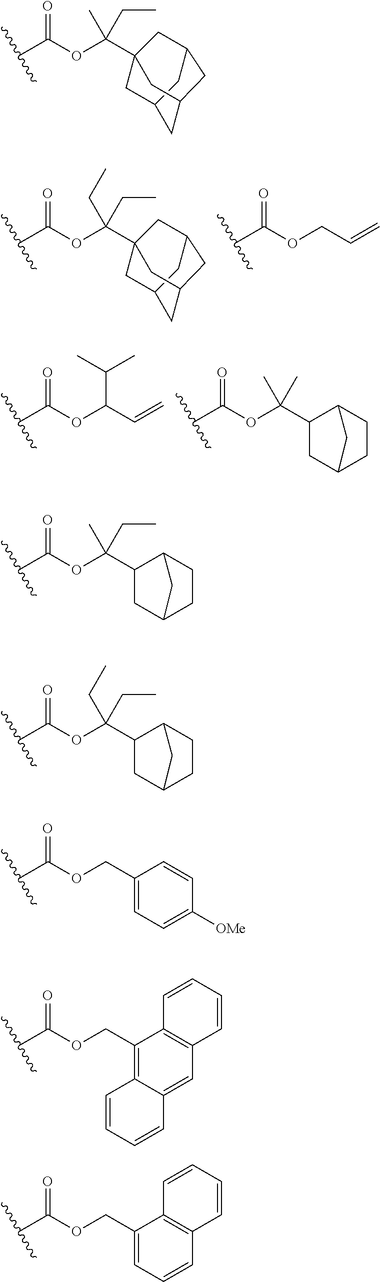

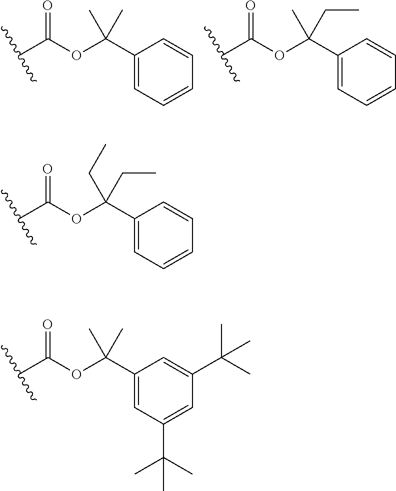

The compound (D) may also be constituted by arbitrarily combining various basic compounds which will be described later with the structure represented by General Formula (d1 1).

The compound (D) is particularly preferably a compound having a structure represented by General Formula (A).

Incidentally, the compound (D) may be a compound corresponding to various basic compounds described above as long as it is a low molecular compound having a group that leaves by the action of an acid.

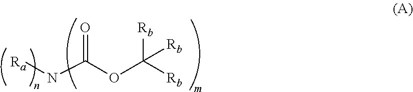

In General Formula (A), Ra represents a hydrogen atom, an alkyl group, a cycloalkyl group, an aryl group, or an aralkyl group. Further, with n=2, two Ra's may be the same as or different from each other, and two Ra's may be bonded to each other to form a divalent heterocyclic hydrocarbon group (preferably having 20 or less carbon atoms) or a derivative thereof.

Rb's each independently represent a hydrogen atom, an alkyl group, a cycloalkyl group, an aryl group, an aralkyl group, or an alkoxyalkyl group, provided that when one or more Rb in -C(Rb)(Rb)(Rb) are hydrogen atoms, at least one of the remaining Rb's is a cyclopropyl group, a 1-alkoxyalkyl group, or an aryl group.

At least two Rb's may be bonded to each other to form an alicyclic hydrocarbon group, an aromatic hydrocarbon group, a heterocyclic hydrocarbon group, or a derivative thereof.

n represents an integer of 0 to 2, m represents an integer of 1 to 3, and n+m=3.

In General Formula (A), the alkyl group, the cycloalkyl group, the aryl group, and the aralkyl group represented by Ra and Rb may be substituted with a functional group such as a hydroxyl group, a cyano group, an amino group, a pyrrolidino group, a piperidino group, a morpholino group, and an oxo group, an alkoxy group, or a halogen atom. The same applies to the alkoxyalkyl group represented by Rb.

Examples of the alkyl group, the cycloalkyl group, the aryl group, and the aralkyl group (each of the alkyl group, the cycloalkyl group, the aryl group, and the aralkyl group may be substituted with the functional group, an alkoxy group, or a halogen atom) of Ra and/or Rb include:

a group derived from a linear or branched alkane, such as methane, ethane, propane, butane, pentane, hexane, heptane, octane, nonane, decane, undecane, and dodecane, or a group in which the group derived from an alkane is substituted with one or more kinds of or one or more groups of cycloalkyl groups such as a cyclobutyl group, a cyclopentyl group, and a cyclohexyl group;

a group derived from a cycloalkane, such as cyclobutane, cyclopentane, cyclohexane, cycloheptane, cyclooctane, norbomane, adamantane, and noradamantane, or a group in which the group derived from a cycloalkane is substituted with one or more kinds of or one or more groups of linear or branched alkyl groups such as a methyl group, an ethyl group, an n-propyl group, an i-propyl group, an n-butyl group, a 2-methylpropyl group, a 1-methylpropyl group, and a t-butyl group;

a group derived from an aromatic compound, such as benzene, naphthalene, and anthracene, or a group in which the group derived from an aromatic compound is substituted with one or more kinds of or one or more groups of linear or branched alkyl groups such as a methyl group, an ethyl group, an n-propyl group, an i-propyl group, an n-butyl group, a 2-methylpropyl group, a 1-methylpropyl group, and a t-butyl group;

a group derived from a heterocyclic compound, such as pyrrolidine, piperidine, morpholine, tetrahydrofuran, tetrahydropyran, indole, indoline, quinoline, perhydroquinoline, indazole, and benzimidazole, or a group in which the group derived from a heterocyclic compound is substituted with one or more kinds of or one or more groups of linear or branched alkyl groups or aromatic compound-derived groups; a group in which the group derived from a linear or branched alkane or the group derived from a cycloalkane is substituted with one or more kinds of or one or more groups of aromatic compound-derived groups such as a phenyl group, a naphthyl group, and an anthracenyl group; and a group in which the substituent above is substituted with a functional group such as a hydroxyl group, a cyano group, an amino group, a pyrrolidino group, a piperidino group, a morpholino group, and an oxo group.

Examples of the divalent heterocyclic hydrocarbon group (preferably having 1 to 20 carbon atoms) formed by the mutual bonding of Ra's, or a derivative thereof include a group derived from a heterocyclic compound, such as pyrrolidine, piperidine, morpholine, 1,4,5,6-tetrahydropyrimidine, 1,2,3,4-tetrahydroquinoline, 1,2,3,6-tetrahydroppidine, homopiperazine, 4-azabenzimidazole, benzotriazole, 5-azabenzotriazole, 1H-1,2,3-triazole, 1,4,7-triazacyclononane, tetrazole, 7-azaindole, indazole, benzimidazole, imidazo[1,2-a]pyridine, (1S,4S)-(+)-2,5-diazabicyclo[2.2.1]heptane, 1,5,7-triazabicyclo[4.4.0]dec-5-ene, indole, indoline, 1,2,3,4-tetrahydroquinoxaline, perhydroquinoline and 1,5,9-triazacyclododecane, and a group in which the group derived from a heterocyclic compound is substituted with one or more kinds of or one or more groups of a linear or branched alkane-derived group, a cycloalkane-derived group, an aromatic compound-derived group, a heterocyclic compound-derived group, and a functional group such as a hydroxyl group, a cyano group, an amino group, a pyrrolidino group, a piperidino group, a morpholino group, and an oxo group.

Specific examples of the particularly preferred compound (D) in the present invention include the following compounds, but the present invention is not limited thereto.

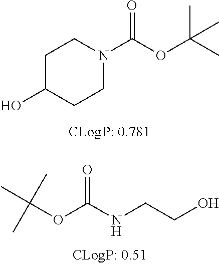

The compound represented by General Formula (A) can be synthesized, based on JP2007-298569A, JP2009-199021A, or the like.

In the present invention, the low molecular compound (D) may be used singly or as a mixture of two or more kinds thereof

Other examples of the basic compound which can be used include the compounds synthesized in Examples of JP2002-363146A and the compounds described in paragraph 0108 of JP2007-298569A.

A photosensitive basic compound may also be used as the basic compound. As the photosensitive basic compound, for example, the compounds described in JP2003-524799A, J. Photopolym. Sci. & Tech., Vol. 8, pp. 543-553 (1995), or the like can be used.

(Content of Basic Compound)

The content of the basic compound with a ClogP of 1.30 or less in the topcoat composition is preferably 0.01% to 20% by mass, more preferably 0.1% to 10% by mass, and still more preferably 1% to 5% by mass, with respect to the solid content of the topcoat composition.

(Base Generator)

Examples of the base generator (photobase generator) with a ClogP of 1.30 or less, which can contain the topcoat composition, include the compounds described in JP1992-151156A (JP-H04-151156A), JP1992-162040A (JP-H04-162040A), JP1993-197148A (JP-H05-197148A), JP1993-5995A (JP-H05-5995A), JP1994-194834A (JP-H06-194834A), JP1996-146608A (JP-H08-146608A), JP1998-83079A (JP-H10-83079A), and EP622682B.

Furthermore, the compounds described in JP2010-243773A can also be appropriately used.

Specific suitable examples of the photobase generator with a ClogP of 1.30 or less include, but not limited to, 2-nitrobenzyl carbamate.

(Content of Base Generator)

The content of the base generator with a ClogP of 1.30 or less in the topcoat composition is preferably 0.01% to 20% by mass, more preferably 0.1% to 10% by mass, and still more preferably 1% to 5% by mass, with respect to the solid content of the topcoat composition.

The compound (b) with a ClogP of 1.30 or less may be used singly or in combination of two or more kinds thereof.

The content of the compound (b) with a ClogP of 1.30 or less is preferably 20% by mass or less, more preferably 0.05% to 20% by mass, and still more preferably 0.1% to 15% by mass, with respect to the total solid content of the topcoat composition. Thus, it becomes easier to form an upper layer film having a receding contact angle with water of 70 degrees or more.

<Surfactant>

The topcoat composition of the present invention may further include a surfactant.

The surfactant is not particularly limited, and any of an anionic surfactant, a cationic surfactant, and a nonionic surfactant can be used as long as it can uniformly form a film of the topcoat composition, and also be dissolved in the solvent of the topcoat composition.

The amount of surfactant to be added is preferably 0.001% to 20% by mass, and more preferably 0.01% to 10% by mass.

The surfactant may be used singly or in combination of two or more kinds thereof.

As the surfactant, for example, one selected from an alkyl cation-based surfactant, an amide-type quaternary cation-based surfactant, an ester type quaternary cation-based surfactant, an amine oxide-based surfactant, a betaine-based surfactant, an alkoxylate-based surfactant, a fatty acid ester-based surfactant, an amide-based surfactant, an alcohol-based surfactant, an ethylenediamine-based surfactant, and a fluorine- and/or silicon-based surfactant (a fluorine-based surfactant, a silicon-based surfactant, or a surfactant having both of a fluorine atom and a silicon atom) can be appropriately used.

Specific examples of the surfactant include polyoxyethylene alkyl ethers such as polyoxyethylene lauryl ether, polyoxyethylene stearyl ether, polyoxyethylene cetyl ether, and polyoxyethylene oleyl ether; polyoxyethylene alkylallyl ethers such as polyoxyethylene octylphenol ether and polyoxyethylene nonylphenol ether; polyoxyethylene/polyoxypropylene block copolymers; sorbitan fatty acid esters such as sorbitan monolaurate, sorbitan monopalmitate, sorbitan monostearate, sorbitan monooleate, sorbitan trioleate, and sorbitan tristearate; and surfactants such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate; and commercially available surfactants mentioned later.

Examples of the commercially available surfactants that can be used include fluorine-based surfactants or silicon-based surfactants such as EFTOP EF301 and EF303 (manufactured by Shin-Akita Kasei K. K.); FLUORAD FC430, 431, and 4430 (manufactured by Sumitomo 3M Limited); MEGAFACE F171, F173, F176, F189, F113, F110, F177, F120, and R₀₈ (manufactured by DIC Corp.); SURFLON S-382, SC101, 102, 103, 104, 105, and 106 (manufactured by Asahi Glass Co., Ltd.); TROYSOL S-366 (manufactured by Troy Chemical Industries); GF-300 and GF-150 (manufactured by Toagosei Chemical Industry Co., Ltd.); SURFLON S-393 (manufactured by AGC Seimi Chemical Co., Ltd.); EFTOP EF121, EF122A, EF122B, RF122C, EF125M, EF135M, EF351, 352, EF801, EF802, and EF601 (manufactured by JEMCO Inc.); PF636, PF656, PF6320, and PF6520 (manufactured by OMNOVA Solutions Inc.); and FTX-204D, 208G, 218G, 230G, 204D, 208D, 212D, 218, and 222D (manufactured by NEOS Co., Ltd.). In addition, Polysiloxane Polymer KP-341 (manufactured by Shin-Etsu Chemical Co., Ltd.) can also be used as the silicon-based surfactant.

It is preferable that various materials (for example, a topcoat solvent, a resist solvent, a developer, a rinsing liquid, a composition for forming an antireflection film, and a composition for forming a topcoat) used in the topcoat composition of the present invention and the actinic ray-sensitive or radiation-sensitive resin composition, and the pattern forming method of the present invention include no impurities such as metals. The content of the impurities included in these materials is preferably 1 ppm or less, more preferably 100 ppt or less, and still more preferably 10 ppt or less, and particularly preferably, the impurities are not contained (no higher than the detection limit of a measurement device).

Examples of a method for removing impurities such as metals from the various materials include filtration using a filter. As for the filter pore diameter, the pore size is preferably 10 nm or less, more preferably 5 nm or less, and still more preferably 3 nm or less. With regard to the materials of a filter, a polytetrafluoroethylene-made filter, a polyethylene-made filter, and a nylon-made filter are preferable. As the filter, a filter which has been washed with an organic solvent in advance may also be used. In the step of filtration using a filter, plural kinds of filters may be connected in series or in parallel, and used. In the case of using plural kinds of filters, a combination of filters having different pore diameters and/or materials may be used. In addition, various materials may be filtered plural times, and a step of filtering plural times may be a circulatory filtration step.

Moreover, examples of the method for reducing the impurities such as metals included in the various materials include a method of selecting raw materials having a small content of metals as raw materials constituting various materials, a method of subjecting raw materials constituting various materials to filtration using a filter, and a method of carrying out distillation under the condition for suppressing the contamination as much as possible by, for example, lining the inside of a device with TEFLON. The preferred conditions for filtration using a filter, which is carried out for raw materials constituting various materials, are the same as described above.

In addition to filtration using a filter, removal of impurities by an adsorbing material may be carried out, or a combination of filtration using a filter and an adsorbing material may be used. As the adsorbing material, known adsorbing materials may be used, and for example, inorganic adsorbing materials such as silica gel and zeolite, and organic adsorbing materials such as activated carbon can be used.

<Method for Preparing Topcoat Composition>

The topcoat composition of the present invention is preferably by dissolving the above-mentioned respective components in a solvent, and filtering the solution through a filter. The filter is preferably a polytetrafluoroethylene-, polyethylene-, or nylon-made filter having a pore size of 0.1 μm or less, more preferably 0.05 μm or less, and still more preferably 0.03 μm or less. Further, two or more kinds of filters are connected in series or in parallel, and used. Incidentally, the composition may be filtered in plural times, and a step of filtering plural times may be a circulatory filtration step. Incidentally, the composition may also be subjected to a deaeration treatment or the like before and after the filtration through the filter. It is preferable that the topcoat composition of the present invention does not include impurities such as metal. The content of the metal components included in these materials is preferably 10 ppm or less, more preferably 5 ppm or less, and still more preferably 1 ppm or less, but the material substantially not having metal components (at a detection limit of a measurement device or less) is particularly preferable.

[Resist Pattern]

The present invention also relates to a resist pattern formed by the pattern forming method of the present invention as described above.

[Method for Manufacturing Electronic Device, and Electronic Device]

The present invention also relates to a method for manufacturing an electronic device, including the pattern forming method of the present invention as described above, and an electronic device manufactured by this manufacturing method.

The electronic device of the present invention is suitably mounted in electrical or electronic equipments (household electronic appliance, OA·media-related equipment, optical equipment, telecommunication equipment, and the like).

### EXAMPLES

Hereinafter, the present invention will be described in more detail with reference to Examples, but the contents of the present invention are not limited thereto.

### Synthesis Example 1

### Synthesis of Resin (1)

102.3 parts by mass of cyclohexanone was heated at 80° C. under a nitrogen stream. While stirring this liquid, a mixed solution of 22.2 parts by mass of a monomer represented by Structural Formula LM-2m, 22.8 parts by mass of a monomer represented by Structural Formula PM-1m, 6.6 parts by mass of a monomer represented by Structural Formula PM-4m, 189.9 parts by mass of cyclohexanone, and 2.40 parts by mass of dimethyl 2,2′-azobisisobutyrate [V-601, manufactured by Wako Pure Chemical Industries, Ltd.] was added dropwise to the liquid for 5 hours. After completion of the dropwise addition, the mixture was further stirred at 80° C. for 2 hours. After being left to be cooled, the reaction solution was reprecipitated with a large amount of hexane/ethyl acetate (mass ratio of 9:1) and filtered, and the obtained solid was dried in vacuum to obtain 41.1 parts by mass of a resin (1).

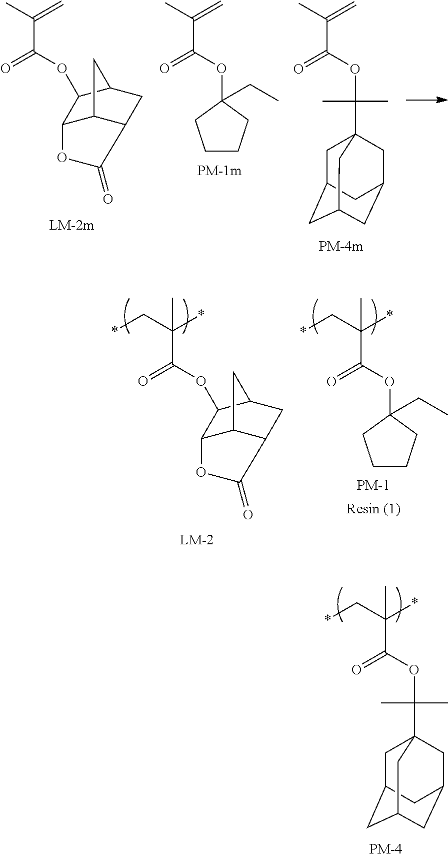

The weight-average molecular weight (Mw) of the obtained resin (1), as determined by GPC (with regard to the measurement method and the like, refer to the above description), was 9,500, and the dispersity (Mw/Mn) was 1.62. The compositional ratio measured by ¹³C-NMR (Nuclear Magnetic Resonance) was 40/50/10 in terms of a molar ratio.

### Synthesis Example 2

### Synthesis of Resins (2) to (13)

The same procedure as in Synthesis Example 1 was carried out to synthesize the resins (2) to (13) described below as an acid-decomposable resin. Hereinbelow, the compositional ratios (molar ratios; corresponding to the repeating units in order from the left side), the weight-average molecular weights (Mw), and the dispersities (Mw/Mn) of the respective repeating units in the resins (1) to (13) are summarized in Table 1. These were determined by the same methods as for the above-mentioned resin (1).

TABLE 1

| | | | | | | | | | Weight- | |
|---|---|---|---|---|---|---|---|---|---|---|
| | | | | | | | | | average | |
| | | | | | | | | | Molecular | Dispersity |
| | Repeating unit | | | | Compositional ratio (molar ratio) | | | | weight (Mw) | (Mw/Mn) |
| Resin (1) | LM-2 | PM-1 | PM-4 | — | 40 | 50 | 10 | — | 9,500 | 1.62 |
| Resin (2) | LM-2 | PM-6 | PM-7 | — | 40 | 40 | 20 | — | 17,000 | 1.70 |
| Resin (3) | LM-4 | IM-2 | PM-2 | — | 45 | 5 | 50 | — | 11,000 | 1.63 |
| Resin (4) | LM-2 | PM-5 | — | — | 40 | 60 | — | — | 15,000 | 1.66 |
| Resin (5) | LM-2 | PM-3 | PM-4 | IM-3 | 40 | 40 | 10 | 10 | 10,500 | 1.62 |
| Resin (6) | LM-1 | PM-5 | IM-4 | — | 40 | 50 | 10 | — | 15,500 | 1.68 |
| Resin (7) | LM-2 | PM-8 | — | — | 40 | 60 | — | — | 11,000 | 1.65 |
| Resin (8) | LM-3 | PM-3 | PM-5 | — | 40 | 40 | 20 | — | 10,000 | 1.64 |
| Resin (9) | LM-4 | PM-6 | PM-8 | — | 40 | 50 | 10 | — | 9,000 | 1.60 |
| Resin (10) | LM-2 | PM-7 | — | — | 40 | 60 | — | — | 8,000 | 1.63 |
| Resin (11) | LM-3 | PM-7 | IM-1 | — | 40 | 50 | 10 | — | 9,500 | 1.70 |
| Resin (12) | LM-2 | PM-6 | PM-4 | — | 40 | 50 | 10 | — | 17,000 | 1.65 |
| Resin (13) | LM-2 | PM-3 | PM-4 | — | 30 | 30 | 40 | — | 14,000 | 1.71 |

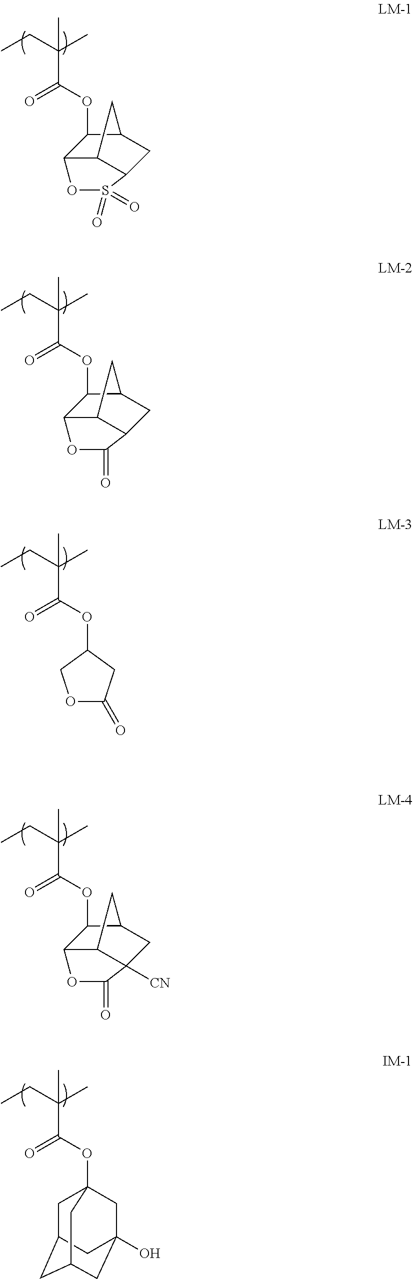

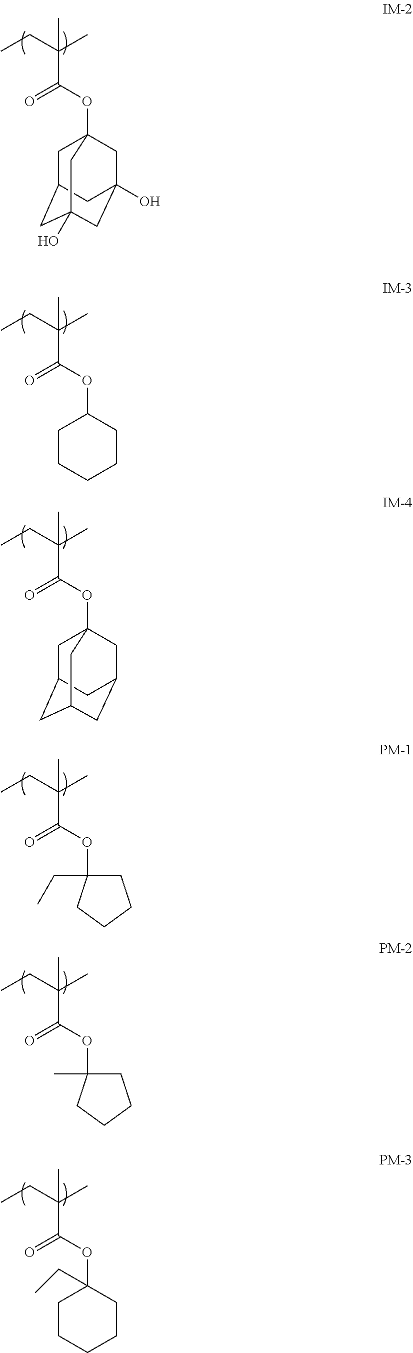

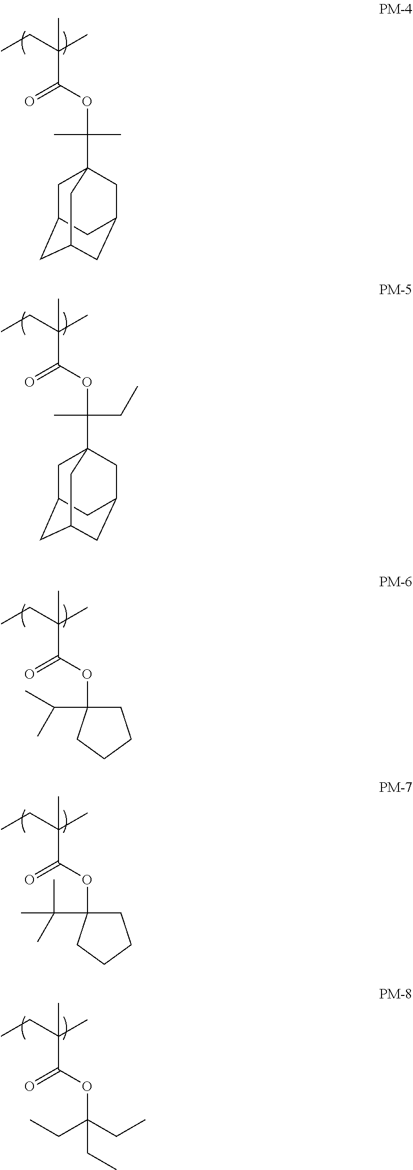

<Preparation of Resist Composition>

The components shown in Table 2 were dissolved in the solvents shown in Table 2 to prepare solutions having a concentration of the solid contents of 3.5% by mass, and the solutions were filtered through a polyethylene filter having a pore size of 0.04 μm to prepare resist compositions Re-1 to Re-16.

TABLE 2

| | | | Photo Acid | | | | | | | | | |
|---|---|---|---|---|---|---|---|---|---|---|---|---|
| | Resin | | generator | | Basic compound | | Solvent | | | | | |
| | | (parts by | | (parts by | | (parts by | | (mass | | (mass | | (mass |
| | | mass) | | mass) | | mass) | | ratio) | | ratio) | | ratio) |
| Re-1 | Resin (1) | 86.5 | A1 | 12.0 | D-1 | 1.5 | SL-1 | 70 | SL-2 | 30 | | |
| Re-2 | Resin (2) | 88.7 | A2 | 10.0 | D-1 | 1.3 | SL-1 | 95 | SL-4 | 5 | | |
| Re-3 | Resin (3) | 86.0 | A3 | 9.5 | D-1 | 4.5 | SL-1 | 60 | SL-2 | 40 | | |
| Re-4 | Resin (4) | 82.7 | A4 | 15.5 | D-3 | 1.8 | SL-1 | 60 | SL-3 | 40 | | |
| Re-5 | Resin (5) | 90.7 | A5 | 8.5 | D-4 | 0.8 | SL-1 | 90 | SL-3 | 10 | | |
| Re-6 | Resin (6) | 88.2 | A6 | 10.5 | D-5 | 1.3 | SL-2 | 100 | | | | |
| Re-7 | Resin (7) | 87.8 | A7 | 11.0 | D-6 | 1.2 | SL-1 | 90 | SL-2 | 5 | SL-4 | 5 |
| Re-8 | Resin (8) | 83.5 | A8 | 10.5 | D-2 | 6.0 | SL-1 | 80 | SL-2 | 20 | | |
| Re-9 | Resin (9) | 87.5 | A2/A5 | 4.0/5.0 | D-1 | 3.5 | SL-1 | 75 | SL-2 | 25 | | |
| Re-10 | Resin (1)/ | 43.1/40.0 | A3 | 16.0 | D-1 | 0.9 | SL-1 | 80 | SL-3 | 20 | | |
| | resin (10) | | | | | | | | | | | |
| Re-11 | Resin (1) | 88.8 | A1 | 10.0 | D-1/D-5 | 1.0/0.2 | SL-1 | 70 | SL-2 | 30 | | |
| Re-12 | Resin (10) | 86.5 | A1/A9 | 10.0/2.0 | D-3 | 1.5 | SL-1 | 70 | SL-2 | 30 | | |
| Re-13 | Resin (11) | 88.7 | A1 | 10.0 | D-3 | 1.3 | SL-1 | 95 | SL-4 | 5 | | |
| Re-14 | Resin (12) | 86.0 | A3 | 9.5 | D-1 | 4.5 | SL-1 | 60 | SL-2 | 40 | | |
| Re-15 | Resin (13) | 88.2 | A1 | 10.5 | D-5 | 1.3 | SL-2 | 100 | | | | |
| Re-16 | Resin (10) | 88.2 | A10 | 10.5 | D-3 | 1.3 | SL-1 | 60 | SL-2 | 40 | | |

The abbreviations in Table 2 are shown below.

<Photoacid Generator>

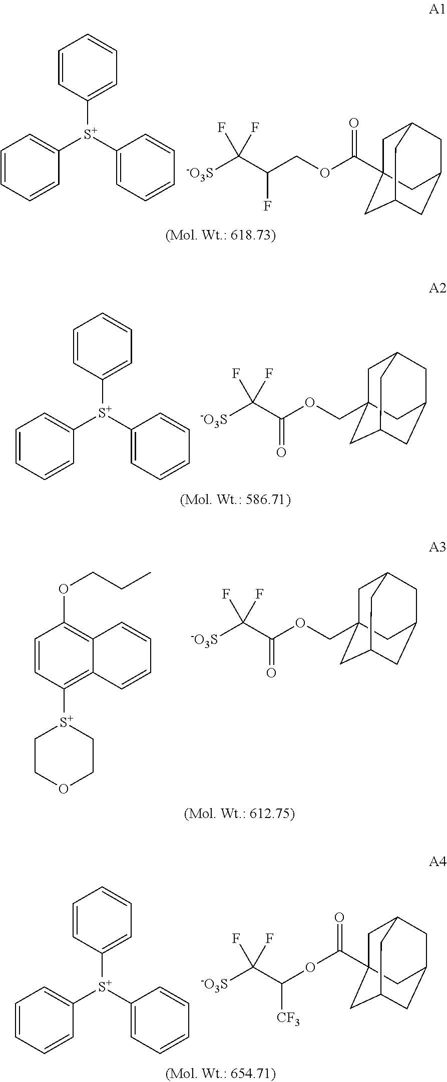

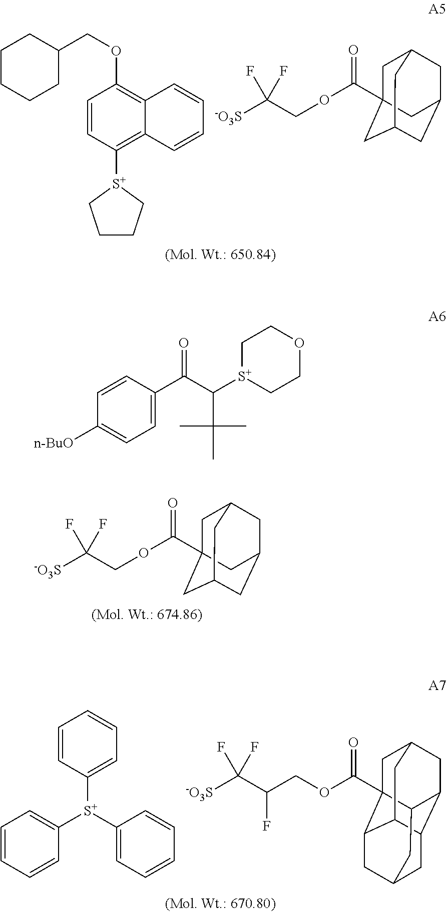

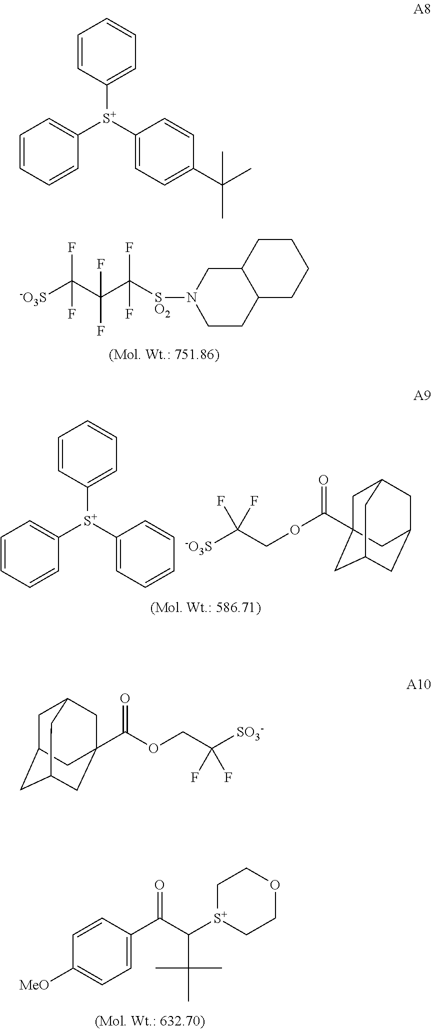

<Basic Compound>

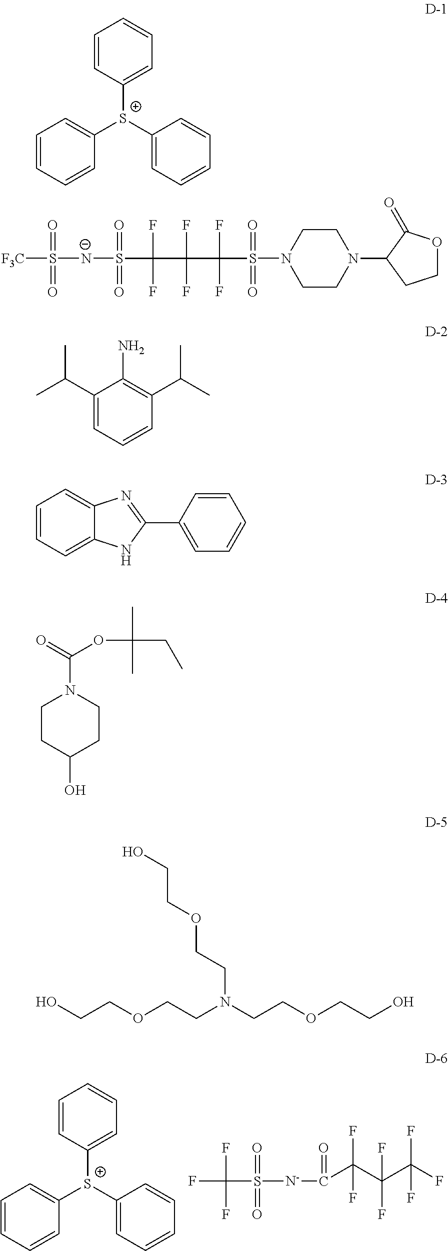

<Solvent>

SL-1: Propylene glycol monomethyl ether acetate (PGMEA)

SL-2: Cyclohexanone

SL-3: Propylene glycol monomethyl ether (PGME)

SL-4: γ-Butyrolactone

### Synthesis Example 3

### Synthesis of Resin X-1

26.1 g of cyclohexanone was put into a three-neck flask under a nitrogen stream, and heated to 85° C., to which a solution obtained by dissolving 10.67 g, 10.71 g, and 3.03 g (in the order from the left side) of the monomers corresponding to the respective repeating units of the resin X-1 described below, and a polymerization initiator V-601 (manufactured by Wako Pure Chemical Industries, Ltd., 0.553 g) in 47.6 g of cyclohexanone was added dropwise for 6 hours. After completion of the dropwise addition, the mixture was additionally reacted at 85° C. for 2 hours. After leaving the reaction solution to be cooled, the mixture was added dropwise to 1,140 g of methanol for 20 minutes, and the precipitated powder was filtered and dried to obtain a resin X-1 (20.9 g). The obtained resin X-1 had a weight-average molecular weight of 8,000 in terms of standard polystyrene and a dispersity (Mw/Mn) of 1.69. The compositional ratio measured by ¹³C-NMR was 40/30/30 in terms of a molar ratio.

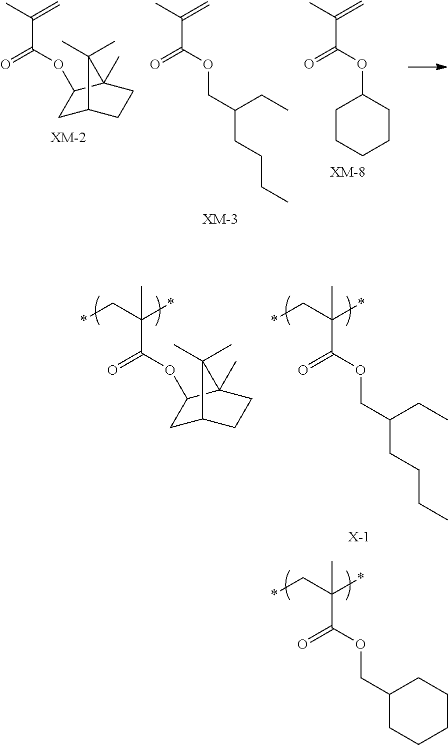

The same procedure as in Synthesis Example 2 was carried out to synthesize the resins (X-2) to (X-17), (XC-1), and (XC-2) described below, which are included in upper layer film compositions. The details of the resins (X-1) to (X-17) and (XC-1) and (XC-2) are shown in Table 3.

In Table 3, the resins (X-1) to (X-17), (XC-1), and (XC-2) are resins having the repeating units corresponding to each monomer (XM-1) to (XM-18) at the molar ratios described in Table 3.

Incidentally, the ClogP values of the monomers are values calculated using Chem DrawUltra ver. 12.0.2.1076 (Cambridge Corporation) as described above.

TABLE 3

| | 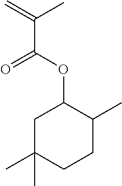 | 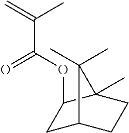 [SMILES: C=C(C)C(=O)OC1CC2CCC1(C)C2(C)C] | 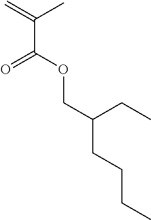 | 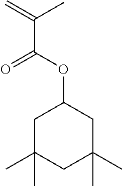 |
|---|---|---|---|---|
| | XM-1 | XM-2 | XM-3 | XM-4 |
| Monomer | 4.70 | 4.97 | 4.68 | 5.21 |
| ClogP | | | | |
| Resin | Compositional ratio (% by mole) | | | |
| X-1 | | 40 | 30 | |
| X-2 | | 89 | 9 | |
| X-3 | | | 30 | 70 |
| X-4 | | | | |
| X-5 | | | | |
| X-6 | 78 | | | |
| X-7 | | | | |
| X-8 | 50 | | | |
| X-9 | | 39 | 29 | |
| X-10 | | | | |
| X-11 | | 40 | | |
| X-12 | | 60 | | |
| X-13 | | | | |
| X-14 | | | | |
| X-15 | | | 40 | |
| X-16 | | 39 | 29 | |
| X-17 | | | 40 | |
| XC-1 | | | | |
| XC-2 | | | | |

| | 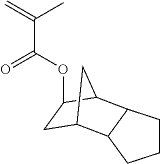 [SMILES: C=C(C)C(=O)OC1CC2CC1C1CCCC21] | 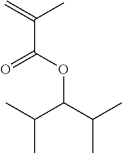 | 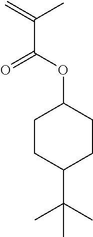 [SMILES: C=C(C)C(=O)OC1CCC(C(C)(C)C)CC1] | 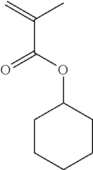 |
|---|---|---|---|---|
| | XM-5 | XM-6 | XM-7 | XM-8 |
| Monomer | 4.29 | 3.80 | 4.98 | 3.14 |
| ClogP | | | | |
| Resin | Compositional ratio (% by mole) | | | |
| X-1 | | | | 30 |
| X-2 | | | | |
| X-3 | | | | |
| X-4 | 60 | 40 | | |
| X-5 | | | 100 | |
| X-6 | | | | 20 |
| X-7 | | | 30 | 68 |
| X-8 | | | | 30 |
| X-9 | | | | 30 |
| X-10 | | 65 | | |
| X-11 | | | | 20 |
| X-12 | | | | 35 |
| X-13 | | 40 | 55 | |
| X-14 | 50 | | | 40 |
| X-15 | | 60 | | |
| X-16 | | | | 30 |
| X-17 | 50 | | | |
| XC-1 | | | | |
| XC-2 | | | | |
| | 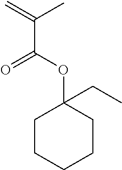 | 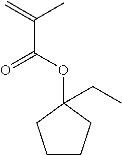 | 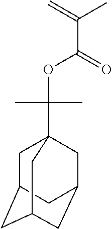 [SMILES: C=C(C)C(=O)OC(C)(C)C12CC3CC(CC(C3)C1)C2] | 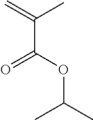 |
| | XM-9 | XM-10 | XM-11 | XM-12 |
| Monomer | 4.19 | 4.03 | 6.13 | 1.94 |
| ClogP | | | | |
| Resin | Compositional ratio (% by mole) | | | |
| X-1 | | | | |
| X-2 | | | | |
| X-3 | | | | |
| X-4 | | | | |
| X-5 | | | | |
| X-6 | | | | |
| X-7 | | | | |
| X-8 | 20 | | | |
| X-9 | | | | |
| X-10 | | | | 30 |
| X-11 | | | | |
| X-12 | 5 | | | |
| X-13 | | 5 | | |
| X-14 | | | 10 | |
| X-15 | | | | |
| X-16 | | | | |
| X-17 | | | | |
| XC-1 | | | | |
| XC-2 | 75 | | | |

| | 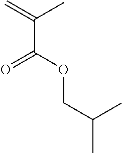 | 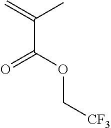 | 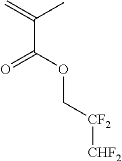 | 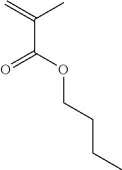 |
|---|---|---|---|---|
| | XM-13 | XM-14 | XM-15 | XM-16 |
| Monomer | 2.56 | 1.40 | 2.20 | 2.69 |
| ClogP | | | | |
| Resin | Compositional ratio (% by mole) | | | |
| X-1 | | | | |
| X-2 | | 2 | | |
| X-3 | | | | |
| X-4 | | | | |
| X-5 | | | | |
| X-6 | | | 2 | |
| X-7 | | | 2 | |
| X-8 | | | | |
| X-9 | | | 2 | |
| X-10 | | | 5 | |
| X-11 | | 40 | | |
| X-12 | | | | |
| X-13 | | | | |
| X-14 | | | | |
| X-15 | | | | |
| X-16 | | 2 | | |
| X-17 | | | | |
| XC-1 | 75 | | | 25 |
| XC-2 | | | | |

| | 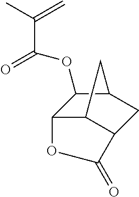 [SMILES: C=C(C)C(=O)OC1C2CC3C(=O)OC1C3C2] | 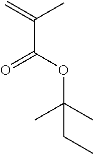 | | |
|---|---|---|---|---|
| | XM-17 | XM-18 | | |
| Monomer | 0.62 | 2.87 | | |
| ClogP | | | | |
| Resin | Compositional ratio (% by mole) | | Mw | Mw/Mn |
| X-1 | | | 8,000 | 1.69 |
| X-2 | | | 16,000 | 1.71 |
| X-3 | | | 10,000 | 1.68 |
| X-4 | | | 9,500 | 1.65 |
| X-5 | | | 12,000 | 1.68 |
| X-6 | | | 14,500 | 1.63 |
| X-7 | | | 9,000 | 1.75 |
| X-8 | | | 10,000 | 1.73 |
| X-9 | | | 8,000 | 1.63 |
| X-10 | | | 27,000 | 2.05 |
| X-11 | | | 9,600 | 1.68 |
| X-12 | | | 11,000 | 1.59 |
| X-13 | | | 9,500 | 1.70 |
| X-14 | | | 15,000 | 1.65 |
| X-15 | | | 8,500 | 1.63 |
| X-16 | | | 8,000 | 1.64 |
| X-17 | | 10 | 9,000 | 1.67 |
| XC-1 | | | 9,000 | 1.60 |
| XC-2 | 25 | | 20,000 | 1.70 |

<Preparation of Composition for Forming Upper Layer Film>

The components shown in Table 4 were dissolved in the solvents shown in Table 4 to obtain solutions each having a concentration of the solid contents of 3.0% by mass. The solutions were filtered through a polyethylene filter having a pore size of 0.04 μm to prepare compositions (T-1) to (T-48) and (TC-1) to (TC-4) for forming an upper layer film. In Table 4, the contents (% by mass) of the compound and the surfactant are based on the total solid content of the composition for forming an upper layer film.

Incidentally, the ClogP value of the compound is a value calculated using Chem DrawUltra ver. 12.0.2.1076 (Cambridge Corporation) as described above.

TABLE 4

| | | Compound | | | | | |
|---|---|---|---|---|---|---|---|
| Composition | | | Content | | Surfactant | | |
| for forming | | | [based on | | [based on | | |
| upper layer | | | solid content] | | solid content] | | Contact |
| film | Resin | Type | (% by mass) | ClogP | (% by mass) | Solvent | angle (°) |
| T-1 | X-1 | AD-1 | 2.0% | −0.06 | | 4-Methyl-2-pentanol | 82 |
| T-2 | X-2 | AD-1 | 1.4% | −0.06 | | 1-Pentanol | 85 |
| T-3 | X-3 | AD-1 | 2.0% | −0.06 | | 3-Octanol | 81 |
| T-4 | X-4 | AD-1 | 0.9% | −0.06 | W-2 (0.6%) | 3-Methyl-1-butanol | 81 |
| T-5 | X-5 | AD-1 | 2.0% | −0.06 | | 3-Methyl-1-butanol | 82 |
| T-6 | X-6 | AD-1 | 0.9% | −0.06 | | 4-Octanol | 80 |
| T-7 | X-7 | AD-1 | 2.0% | −0.06 | | 4-Methyl-1-pentanol | 83 |
| T-8 | X-8 | AD-1 | 1.8% | −0.06 | | 4-Methyl-2-pentanol | 85 |
| T-9 | X-9 | AD-1 | 2.0% | −0.06 | W-1 (0.4%) | 4-Methyl-2-pentanol | 87 |
| T-10 | X-10 | AD-1 | 2.0% | −0.06 | | 3-Methyl-1-butanol | 84 |
| T-11 | X-11 | AD-1 | 2.0% | −0.06 | | 4-Methyl-2-pentanol | 85 |
| T-12 | X-12 | AD-1 | 2.0% | −0.06 | | 4-Methyl-2-pentanol | 82 |
| T-13 | X-13 | AD-1 | 2.0% | −0.06 | | 4-Methyl-2-pentanol | 81 |
| T-14 | X-14 | AD-1 | 2.0% | −0.06 | | 4-Octanol | 84 |
| T-15 | X-15 | AD-1 | 2.0% | −0.06 | | 4-Methyl-2-pentanol | 83 |
| T-16 | X-1 | AD-3 | 2.0% | 0.65 | | 4-Methyl-2-pentanol | 84 |
| T-17 | X-1/X-11 | AD-13 | 2.0% | −0.77 | | 4-Methyl-1-pentanol | 82 |
| | (mass ratio | | | | | | |
| | of 50:50) | | | | | | |
| T-18 | X-8 | AD-1 | 0.7% | −0.06 | | 4-Methyl-2-pentanol | 80 |
| T-19 | X-10 | AD-2 | 2.0% | −1.04 | | 4-Methyl-2-pentanol | 81 |
| T-20 | X-3 | AD-3 | 0.9% | 0.65 | W-1 (0.7%) | 3-Octanol | 83 |
| T-21 | X-7 | AD-4 | 2.0% | −1.21 | | 3-Methyl-1-butanol | 84 |
| T-22 | X-8 | AD-5 | 0.8% | 0.22 | | 4-Methyl-2-pentanol | 81 |
| T-23 | X-2 | AD-6 | 2.0% | −0.86 | | 4-Methyl-2-pentanol | 85 |
| T-24 | X-13 | AD-7 | 1.6% | 0.84 | | 4-Methyl-2-pentanol | 83 |
| T-25 | X-14 | AD-8 | 0.6% | 0.42 | | 4-Methyl-2-pentanol | 84 |
| T-26 | X-5 | AD-9 | 1.8% | −1.09 | W-3 (0.5%) | 3-Methyl-1-butanol | 82 |
| T-27 | X-1 | AD-10 | 2.0% | −1.15 | | 4-Octanol | 81 |
| T-28 | X-4 | AD-11 | 0.7% | −1.26 | | 3-Methyl-1-butanol | 80 |
| T-29 | X-1 | AD-12 | 12.0% | −0.45 | | 4-Octanol | 82 |
| T-30 | X-6 | AD-13 | 9.0% | −0.77 | | 4-Methyl-2-pentanol | 82 |
| T-31 | X-1 | AD-1 | 0.7% | −0.06 | | 4-Methyl-2-pentanol | 84 |
| T-32 | X-9 | AD-1 | 0.7% | −0.06 | | 4-Methyl-2-pentanol | 88 |
| T-33 | X-1 | AD-1/AD-12 | 0.7%/12% | −0.06/−0.45 | W-1 (0.3%) | 4-Methyl-2-pentanol | 84 |
| T-34 | X-9 | AD-1/AD-12 | 0.7%/12% | −0.06/−0.45 | | 4-Methyl-2-pentanol | 83 |
| T-35 | X-12 | AD-1/AD-12 | 0.7%/12% | −0.06/−0.45 | | 4-Methyl-2-pentanol | 82 |
| T-36 | X-16 | AD-1/AD-12 | 0.7%/12% | −0.06/−0.45 | | 4-Methyl-2-pentanol | 86 |
| T-37 | X-2 | AD-1/AD-12 | 0.7%/12% | −0.06/−0.45 | W-1 (0.6%) | 1-pentanol | 84 |
| T-38 | X-6 | AD-4/AD-12 | 0.7%/12% | −1.21/−0.45 | | 4-Octanol | 81 |
| T-39 | X-7 | AD-2/AD-12 | 0.7%/12% | −1.04/−0.45 | | 4-Methyl-1-pentanol | 82 |
| T-40 | X-11 | AD-3/AD-12 | 0.7%/12% | 0.65/−0.45 | | 4-Methyl-2-pentanol | 83 |
| T-41 | X-16 | AD-1 | 2.0% | −0.06 | | 4-Methyl-2-pentanol | 87 |
| T-42 | X-17 | AD-1 | 2.0% | −0.06 | W-2 (0.5%) | 4-Methyl-2-pentanol | 82 |
| T-43 | X-9 | AD-1 | 0.7% | −0.06 | | Diisoamyl ether | 88 |
| T-44 | X-16 | AD-1/AD-12 | 0.7%/12% | −0.06/−0.45 | W-3 (0.6%) | Diisoamyl ether/ | 86 |
| | | | | | | 4-Methyl-2- pentanol | |
| | | | | | | (volume ratio of 80:20) | |
| T-45 | X-16 | AD-1 | 2.0% | −0.06 | | Isobutyl isobutyrate/ | 87 |
| | | | | | | 4-Methyl-2-pentanol | |
| | | | | | | (volume ratio of 60:40) | |
| T-46 | X-16 | AD-1/AD-12 | 0.7%/12% | −0.06/−0.45 | W-3 (0.4%) | n-Decane | 85 |
| T-47 | X-9 | AD-15 | 1.5% | −1.25 | | 4-Methyl-2-pentanol | 85 |
| T-48 | X-2 | AD-16 | 0.8% | −2.85 | | 4-Methyl-2-pentanol | 83 |
| TC-1 | XC-1 | AD-14 | 1.0% | −0.30 | | 4-Methyl-1-pentanol | 76 |
| TC-2 | XC-2 | AD-1 | 2.0% | −0.06 | | 4-Methyl-1-pentanol | 64 |
| TC-3 | X-7 | AD-17 | 2.0% | 3.40 | | 4-Methyl-1-pentanol | 81 |
| TC-4 | X-7 | AD-18 | 2.0% | 1.36 | | 4-Methyl-1-pentanol | 81 |

The abbreviations in the table are shown below.

<Compound>

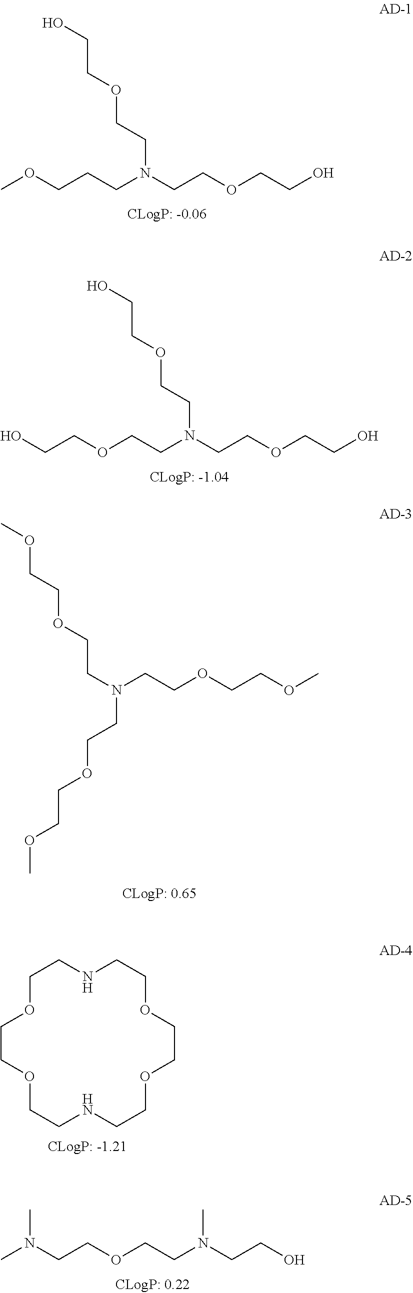

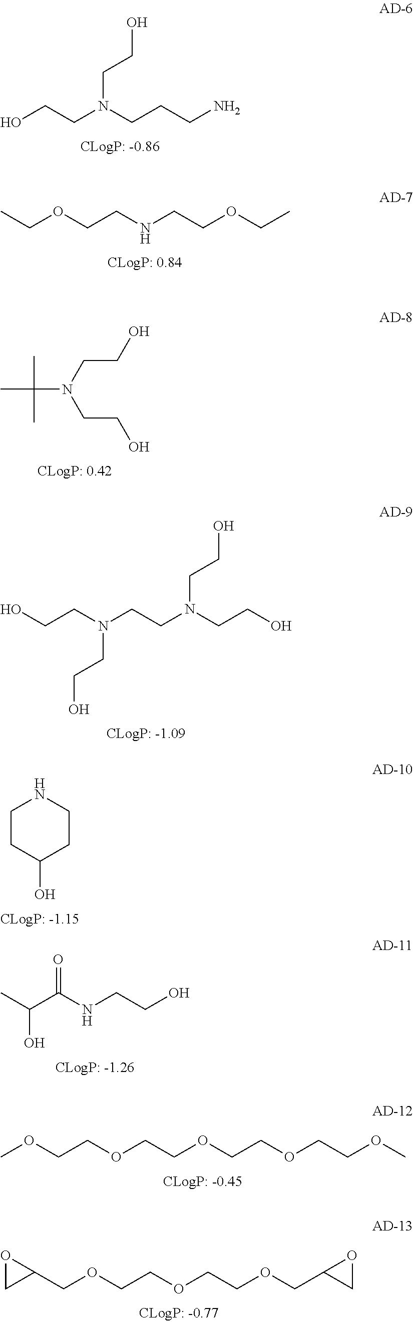

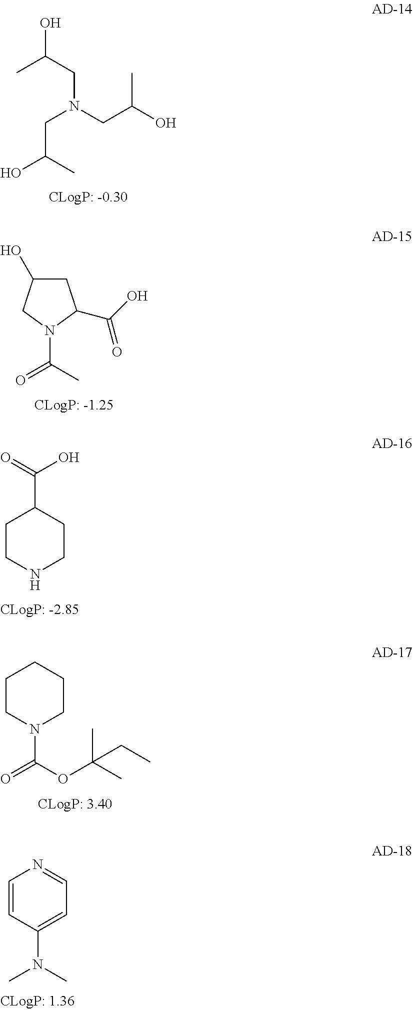

<Surfactant>

W-1: PF6320 (manufactured by OMNOVA Solutions Inc., fluorine-based)

W-2: TROYSOL S-366 (manufactured by Troy Chemical Industries)

W-3: Polysiloxane Polymer KP-341 (manufactured by Shin-Etsu Chemical Co., Ltd., silicon-based)

In Table 3 above, the receding contact angles of the upper layer film with water in a case of forming the upper layer film using the composition for forming an upper layer film were measured, based on the following method.

<Contact Angle>

Each of the compositions for forming an upper layer film was applied onto a wafer by spin coating, and dried at 100° C. for 60 seconds to form a film (film thickness of 120 nm). The receding contact angles (RCA) of water droplets were measured using a dynamic contact angle meter (manufactured by Kyowa Interface Science Co., Ltd.) by an expansion-contraction method.

The liquid droplets (with an initial liquid droplet size of 35 μL) were added dropwise onto the film, and suctioned at a rate of 6 μL/sec for 5 seconds, and the receding contact angle (RCA) when the dynamic contact angle during suction was stabilized was determined with the measurement environments of 23° C. and a relative humidity of 45%.

[Image Performance Test (Negative Type, Organic Solvent Development)]

(Formation of Trench Pattern)

An organic antireflection film, ARC29SR (manufactured by Brewer Science, Inc.), was applied onto a silicon wafer having an opening diameter of 300 nm, and baking was carried out at 205° C. for 60 seconds to form an antireflection film having a film thickness of 86 nm. An actinic ray-sensitive or radiation-sensitive resin composition was applied thereonto, and baking (PB: Prebake) was carried out at 100° C. over 60 seconds to form a resist film having a film thickness of 90 nm. Subsequently, a pre-wetting treatment for applying 4-methyl-2-heptanol onto the resist film was carried out. In addition, the composition for forming an upper layer film was applied thereonto, and baking was carried out at the PB temperature described in Table 5 over 60 seconds to form an upper layer film having the film thickness described in Table 5.

The obtained wafer was subjected to pattern exposure via a halftone mask with a width of a light shielding portion corresponding to a trench being 50 nm and a pitch between the light shielding portions being 250 nm, using an ArF excimer laser liquid immersion scanner (manufactured by ASML; XT1700i, NA1.20, C-Quad, outer sigma 0.900, inner sigma 0.790, and Y deflection). Ultrapure water was used as the immersion liquid. Thereafter, heating (PEB: Post Exposure Bake) was carried out at 90° C. for 60 seconds. Then, development was carried out by paddling for 30 seconds using the organic developer described in Table 5, and rinsing was carried out by paddling for 30 seconds using the rinsing liquid described in Table 5. Subsequently, a trench pattern with a trench width of 50 nm was obtained by rotating the wafer at a rotation speed of 2,000 rpm for 30 seconds.

(Formation of Line-and-Space Pattern)

Films were formed by applying the organic antireflection film, the resist film, and the upper layer film in this order onto a silicon wafer in the same manner as in the formation of the trench pattern.

The obtained wafer was subjected to pattern exposure via a halftone mask with a line width of 50 nm and a space width of 50 nm, using an ArF excimer laser liquid immersion scanner (manufactured by ASML; XTI700i, NA1.20, Dipole, outer sigma 0.800, inner sigma 0.564, and Y deflection). Ultrapure water was used as the immersion liquid. Thereafter, heating (PEB: Post Exposure Bake) was carried out at 105° C. for 60 seconds. Then, development was carried out by paddling for 30 seconds using the organic developer described in Table 5, and rinsing was carried out by paddling for 30 seconds using the rinsing liquid described in Table 5. Subsequently, a 1:1 line-and-space pattern with a line width of 50 nm was obtained by rotating the wafer at a rotation speed of 2,000 rpm for 30 seconds.

<Exposure Latitude (EL)>

The line-and-space pattern was observed using a critical dimension scanning electron microscope (SEM) (S-938011, Hitachi, Ltd.), and the optimal exposure dose at which a line pattern with a line width of 50 nm was resolved was defined as a sensitivity (Eₒₚₜ) (mJ/cm²) in (Formation of Line-and-Space Pattern) above. Then, the exposure dose when the line width became ±10% of 50 nm (that is, 45 nm and 55 nm) which were desired values was determined, based on the determined optimal exposure dose (Eₒₚₜ). Then, an exposure latitude (EL, unit: %) defined by the following equation was calculated. As the value of EL is higher, the change in performance due to a change in the exposure dose is smaller, which is thus good.

[EL (%)]=[(Exposure dose when line width becomes 45 nm)−(Exposure dose when line width becomes 55 nm)]/Eₒₚₜ×100

<Focus Latitude (DOF: Depth of Focus)>

Exposure and development were carried out by changing the conditions of the exposure focus at an interval of 20 nm in the focus direction in (Formation of Trench Pattern) above. The hole diameter (CD) of each of the obtained patterns was measured using a line-width critical dimension scanning electron microscope SEM (S-9380, Hitachi High-Technologies Corporation), and a focus corresponding to the minimum value or the maximum value in a curve obtained by plotting the respective CDs was defined as the best focus. In a case where the focus was changed around the center of the best focus, a variation width of the focus tolerating a trench width of 50 nm±10%, that is, the focus latitude (DOF) (nm) was calculated.

<Watermark Defect>

The number of the development defects in the trench pattern formed in (Formation of Trench Pattern) above was measured with a KLA 2360 apparatus (manufactured by KLA-Tencor Corporation). The detected development defect site was observed using a critical dimension SEM: 59380, and the development defects were classified into bubble defects and watermark defects. Thus, the number of the watermark defects was determined.

The results of the evaluations are shown in Table 5.

TABLE 5

| | | | Composition | Film thickness | PB temperature (° C.) | | | | | Watermark |
|---|---|---|---|---|---|---|---|---|---|---|
| | Resist | Film thickness | for forming | (nm) of upper | after formation of | Organic developer | Rinsing liquid | | DOF | defects |
| No. | composition | (nm) of resist | upper layer film | layer film | upper layer film | (mass ratio) | (mass ratio) | EL (%) | (nm) | (number) |
| Example 1 | Re-15 | 90 | T-1 | 90 | 90 | Butyl acetate | 4-Methyl-2-heptanol | 17.1 | 118 | 2 |
| Example 2 | Re-5 | 90 | T-2 | 60 | 90 | Butyl acetate | 4-Methyl-2-heptanol | 18.9 | 123 | 2 |
| Example 3 | Re-9 | 90 | T-3 | 70 | 90 | Butyl acetate | 4-Methyl-2-heptanol | 17.7 | 118 | 1 |
| Example 4 | Re-13 | 90 | T-4 | 30 | 100 | Butyl acetate | 4-Methyl-2-heptanol | 17.1 | 117 | 1 |
| Example 5 | Re-15 | 85 | T-5 | 60 | 90 | Butyl acetate | isobutyl ether | 17.8 | 118 | 2 |
| Example 6 | Re-11 | 90 | T-6 | 50 | 90 | Butyl acetate | 4-Methyl-2-heptanol | 19.0 | 121 | 3 |
| Example 7 | Re-15 | 70 | T-7 | 70 | 100 | Butyl acetate | 4-Methyl-2-heptanol | 18.9 | 120 | 3 |
| Example 8 | Re-12 | 90 | T-8 | 50 | 90 | Butyl acetate | 4-Methyl-2-heptanol | 18.1 | 117 | 2 |
| Example 9 | Re-6 | 90 | T-9 | 90 | 90 | Butyl acetate | 4-Methyl-2-heptanol | 19.4 | 125 | 3 |
| Example 10 | Re-1 | 90 | T-10 | 90 | 90 | Butyl acetate | 4-Methyl-2-heptanol | 15.8 | 118 | 2 |
| Example 11 | Re-5 | 85 | T-11 | 60 | 90 | Butyl acetate | 4-Methyl-2-heptanol/ | 18.9 | 120 | 1 |
| | | | | | | | Isobutyl ether (50/50) | | | |
| Example 12 | Re-13 | 90 | T-12 | 70 | 90 | 2-Heptanone | 4-Methyl-2-heptanol | 17.5 | 116 | 5 |
| Example 13 | Re-2 | 90 | T-13 | 30 | 90 | Butyl acetate | 4-Methyl-2-heptanol | 17.4 | 119 | 1 |
| Example 14 | Re-15 | 90 | T-14 | 60 | 100 | Butyl acetate | 4-Methyl-2-heptanol | 17.6 | 119 | 4 |
| Example 15 | Re-2 | 90 | T-15 | 50 | 90 | Butyl acetate | 4-Methyl-2-heptanol | 15.8 | 117 | 3 |
| Example 16 | Re-14 | 85 | T-16 | 70 | 90 | Butyl acetate | 4-Methyl-2-heptanol | 17.4 | 119 | 2 |
| Example 17 | Re-13 | 70 | T-17 | 50 | 90 | Butyl acetate | 4-Methyl-2-heptanol | 17.6 | 102 | 4 |
| Example 18 | Re-7 | 85 | T-18 | 100 | 100 | Butyl acetate | 4-Methyl-2-heptanol | 17.9 | 119 | 5 |
| Example 19 | Re-7 | 100 | T-19 | 90 | 90 | Butyl acetate | 4-Methyl-2-heptanol/ | 15.5 | 116 | 1 |
| | | | | | | | n-decane (50/50) | | | |
| Example 20 | Re-16 | 90 | T-20 | 60 | 90 | Butyl acetate | n-Decane | 17.9 | 119 | 4 |
| Example 21 | Re-3 | 90 | T-21 | 70 | 90 | Butyl acetate | 4-Methyl-2-heptanol | 18.1 | 119 | 3 |
| Example 22 | Re-15 | 90 | T-22 | 30 | 100 | Butyl acetate | 4-Methyl-2-heptanol | 17.8 | 120 | 2 |
| Example 23 | Re-1 | 90 | T-23 | 60 | 90 | Butyl propionate | 4-Methyl-2-heptanol | 19.0 | 117 | 5 |
| Example 24 | Re-8 | 90 | T-24 | 50 | 90 | Butyl acetate | 4-Methyl-2-heptanol | 17.9 | 117 | 4 |
| Example 25 | Re-11 | 90 | T-25 | 70 | 90 | Butyl acetate | 4-Methyl-2-heptanol | 18.1 | 119 | 3 |
| Example 26 | Re-4 | 90 | T-26 | 50 | 90 | Butyl acetate | n-Decane | 18.3 | 117 | 1 |
| Example 27 | Re-15 | 90 | T-27 | 90 | 100 | Butyl acetate | Butyl acetate/PGME/ | 17.8 | 120 | 4 |
| | | | | | | | PGMEA (95/3.5/1.5) | | | |
| Example 28 | Re-10 | 90 | T-28 | 90 | 90 | 2-Heptanone | 4-Methyl-2-heptanol | 17.6 | 119 | 3 |
| Example 29 | Re-14 | 90 | T-29 | 90 | 90 | Butyl acetate | 4-Methyl-2-heptanol | 17.7 | 98 | 1 |
| Example 30 | Re-9 | 90 | T-30 | 90 | 90 | Butyl acetate | 4-Methyl-2-heptanol | 17.8 | 101 | 2 |
| Example 31 | Re-15 | 90 | T-31 | 90 | 90 | Butyl acetate/ | 4-Methyl-2-heptanol | 17.4 | 119 | 3 |
| | | | | | | butyl propionate (70/30) | | | | |
| Example 32 | Re-6 | 90 | T-32 | 90 | 90 | Butyl acetate | 4-Methyl-2-heptanol | 19.3 | 124 | 2 |
| Example 33 | Re-15 | 90 | T-33 | 90 | 90 | Butyl acetate | 4-Methyl-2-heptanol | 17.9 | 118 | 4 |
| Example 34 | Re-6 | 90 | T-34 | 90 | 90 | Butyl acetate | 4-Methyl-2-heptanol | 19.1 | 124 | 2 |
| Example 35 | Re-15 | 90 | T-35 | 90 | 90 | Butyl acetate | 4-Methyl-2-heptanol | 18.1 | 116 | 3 |
| Example 36 | Re-15 | 90 | T-36 | 85 | 90 | Butyl acetate | 4-Methyl-2-heptanol | 19.5 | 124 | 1 |
| Example 37 | Re-6 | 85 | T-37 | 70 | 100 | Butyl acetate | 4-Methyl-2-heptanol | 19.1 | 120 | 3 |
| Example 38 | Re-15 | 90 | T-38 | 95 | 110 | Butyl acetate | 4-Methyl-2-heptanol/ | 19.0 | 121 | 2 |
| | | | | | | | n-decane (50/50) | | | |
| Example 39 | Re-6 | 85 | T-39 | 90 | 100 | Butyl acetate | 4-Methyl-2-heptanol | 19.1 | 120 | 1 |
| Example 40 | Re-15 | 90 | T-40 | 90 | 90 | Butyl acetate | 4-Methyl-2-heptanol | 18.9 | 120 | 1 |
| Example 41 | Re-15 | 90 | T-41 | 90 | 90 | Butyl acetate/ | 4-Methyl-2-heptanol | 19.3 | 123 | 1 |
| | | | | | | isoamyl acetate (70/30) | | | | |
| Example 42 | Re-11 | 85 | T-42 | 90 | 90 | 2-Heptanone | 4-Methyl-2-heptanol | 17.3 | 117 | 1 |
| Example 43 | Re-15 | 90 | T-43 | 90 | 100 | Butyl acetate | 4-Methyl-2-heptanol | 19.0 | 121 | 2 |
| Example 44 | Re-6 | 85 | T-44 | 85 | 110 | Butyl acetate | 4-Methyl-2-heptanol | 18.7 | 120 | 1 |
| Example 45 | Re-15 | 90 | T-45 | 70 | 100 | Butyl acetate | 4-Methyl-2-heptanol | 18.9 | 121 | 1 |
| Example 46 | Re-6 | 90 | T-46 | 95 | 90 | Butyl acetate | 4-Methyl-2-heptanol | 18.7 | 120 | 1 |
| Example 47 | Re-11 | 90 | T-47 | 100 | 90 | Butyl acetate | 4-Methyl-2-heptanol | 18.9 | 122 | 1 |
| Example 48 | Re-13 | 85 | T-48 | 90 | 100 | Butyl acetate | 4-Methyl-2-heptanol | 18.3 | 119 | 2 |
| Comparative Example 1 | Re-11 | 90 | TC-1 | 90 | 90 | Butyl acetate | 4-Methyl-2-heptanol | 11.9 | 101 | 2 |
| Comparative Example 2 | Re-8 | 90 | TC-2 | 90 | 100 | Butyl acetate | 4-Methyl-2-heptanol | 14.3 | 81 | 103 |
| Comparative Example 3 | Re-5 | 85 | TC-3 | 90 | 90 | Butyl acetate | 4-Methyl-2-heptanol | 15.9 | 59 | 3 |
| Comparative Example 4 | Re-8 | 90 | TC-4 | 90 | 100 | Butyl acetate | 4-Methyl-2-heptanol | 15.6 | 62 | 2 |

From Table 5 above, it could be seen that according to Examples 1 to 48 in which the pattern forming method according to the present invention was used, high degrees of DOF, EL, and watermark defect performance could be achieved simultaneously, as compared with Comparative Examples 1 to 4, in which such the composition was not used.

In particular, it could be seen that in Examples 1 to 9, 11 to 14, 16 to 18, and 20 to 48 in which a resin having a repeating unit containing an alicyclic hydrocarbon group was used as the resin contained in the composition for forming an upper layer film, results of more excellent EL were attained.

In addition, in Examples 1 to 16, 18 to 28, and 31 to 48 in which the compound (b) was at least one of a basic compound or a base generator, results of more excellent DOF were attained. Industrial Applicability

According to the present invention, it is possible to provide a pattern forming method capable of achieving high degrees of DOF, EL, and watermark defect performance simultaneously, a resist pattern, a method for manufacturing an electronic device, and a composition for forming an upper layer film.

While the present invention has been described in detail and with reference to specific embodiments thereof, it will be apparent to one skilled in the art that various changes and modifications can be made therein without departing from the spirit and scope of the present invention.

The present application is based on Japanese Patent Application (JP2015-066731) filed on Mar. 27, 2015, the contents of which are incorporated herein by reference.

What is claimed is:

1. A pattern forming method comprising:
a step a of applying an actinic ray-sensitive or radiation-sensitive resin composition onto a substrate to form a resist film;
a step b of forming an upper layer film on the resist film, using a composition for forming an upper layer film;
a step c of exposing the resist film having the upper layer film formed thereon; and
a step d of developing the exposed resist film using a developer including an organic solvent to form a pattern,
wherein the composition for forming an upper layer film contains a resin having a repeating unit (a) with a ClogP value of 2.85 or more and a compound (b) with a ClogP of 1.30 or less, and
the receding contact angle of the upper layer film with water is 70 degrees or more.

2. The pattern forming method according to claim 1, wherein the resin contained in the composition for forming an upper layer film is a resin having a repeating unit containing an alicyclic hydrocarbon group.

3. The pattern forming method according to claim 1, wherein the resin contained in the composition for forming an upper layer film is a resin having a repeating unit containing an acid-decomposable group.

4. The pattern forming method according to claim 1, wherein the resin contained in the composition for forming an upper layer film is a resin having a repeating unit containing a fluorine atom.

5. The pattern forming method according to claim 1, wherein the content of the compound (b) is 20% by mass or less with respect to the solid content of the composition for forming an upper layer film.

6. The pattern forming method according to claim 1, wherein the compound (b) is a compound having an ether bond.

7. The pattern forming method according to claim 1, wherein the compound (b) is at least one of a basic compound or a base generator.

8. The pattern forming method according to claim 1, wherein the compound (b) is an amine compound.

9. A resist pattern formed by the pattern forming method according to claim 1.

10. A method for manufacturing an electronic device, comprising the pattern forming method according to claim 1.

11. A composition for forming an upper layer film, comprising:
a resin having a repeating unit (a) with a ClogP value of 2.85 or more; and
a compound (b) with a ClogP of 1.30 or less,
wherein the receding contact angle of the upper layer film formed with the composition for forming an upper layer film with water is 70 degrees or more.
